(19) United States
(12) Patent Application Publication
(10) Pub. No.: US 2025/0123553 A1
(43) Pub. Date: Apr. 17, 2025

(54) SYSTEM AND METHOD FOR PATTERNED LAYER DESIGN AND FORMATION

(71) Applicant: Taiwan Semiconductor Manufacturing Company Limited, Hsin-Chu (TW)

(72) Inventors: Yu-Chen CHANG, Taoyuan City (TW); Anhao Cheng, Taichung City (TW); Yen-Liang Lin, Tainan City (TW); Ru-Shang Hsiao, Hsinchu County (TW)

(21) Appl. No.: 18/379,786

(22) Filed: Oct. 13, 2023

(51) Int. Cl. G03F 1/70; G03F 7/00

(52) U.S. Cl. CPC G03F 1/70; G03F 7/0002; G03F 7/70433; G03F 7/70633

(57) ABSTRACT

A method is provided. The method includes determining a first hotspot region of a contact structure map. The method includes enlarging, according to a first predefined enlargement profile, the first hotspot region to determine a first enlarged region of the contact structure map. The method includes determining that a first portion of the first enlarged region overlaps a functional region of a functional component. The method includes determining a cropped region, of the contact structure map, that excludes the first portion of the first enlarged region. The method includes updating a first patterned oxide layer map based upon the cropped region to generate an updated patterned oxide layer map.

### BACKGROUND

Semiconductor devices are used in a multitude of electronic devices, such as mobile phones, laptops, desktops, tablets, watches, gaming systems, and various other industrial, commercial, and consumer electronics. Semiconductor wafers generally undergo one or more processes to produce semiconductor devices thereon and/or therefrom.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1A illustrates a representation of a contact structure map indicative of an arrangement of contact structures, in accordance with some embodiments.

FIG. 1B illustrates determination of one or more hotspot regions, in accordance with some embodiments.

FIG. 1C illustrates enlarging a hotspot region to determine an enlarged region, in accordance with some embodiments.

FIG. 1D illustrates one or more first patterned layer regions of a first patterned layer map mapped to a contact structure map, in accordance with some embodiments.

FIG. 1E illustrates comparing a region of contact structure map with one or more functional regions, in accordance with some embodiments.

FIG. 1F illustrates a cropped region of a contact structure map, in accordance with some embodiments.

FIG. 1G illustrates determining a cropped region of a contact structure map, in accordance with some embodiments.

FIG. 1H illustrates comparing a region of contact structure map with one or more resistance regions, in accordance with some embodiments.

FIG. 1I illustrates a second patterned layer map, in accordance with some embodiments.

FIG. 1J illustrates a second patterned layer map, in accordance with some embodiments.

FIG. 1K illustrates a first patterned layer map, in accordance with some embodiments.

FIG. 1L illustrates a patterned layer region of a first patterned layer map, in accordance with some embodiments.

FIG. 1M illustrates a patterned layer region of a first patterned layer map, in accordance with some embodiments.

FIG. 1N illustrates a patterned layer region of a first patterned layer map, in accordance with some embodiments.

FIG. 2 illustrates a cross-sectional view of a semiconductor device at a stage of fabrication, in accordance with some embodiments.

FIG. 3 illustrates a cross-sectional view of a semiconductor device at a stage of fabrication, in accordance with some embodiments.

FIG. 4 illustrates a cross-sectional view of a semiconductor device at a stage of fabrication, in accordance with some embodiments.

FIG. 5 illustrates a cross-sectional view of a semiconductor device at a stage of fabrication, in accordance with some embodiments.

FIG. 6 illustrates a cross-sectional view of a semiconductor device at a stage of fabrication, in accordance with some embodiments.

FIG. 7 illustrates a cross-sectional view of a semiconductor device at a stage of fabrication, in accordance with some embodiments.

FIG. 8 illustrates a cross-sectional view of a semiconductor device at a stage of fabrication, in accordance with some embodiments.

FIG. 9A illustrates a cross-sectional view of a semiconductor device at a stage of fabrication, in accordance with some embodiments.

FIG. 9B illustrates a top view of a semiconductor device at a stage of fabrication, in accordance with some embodiments.

FIG. 10 illustrates a cross-sectional view of a semiconductor device at a stage of fabrication, in accordance with some embodiments.

FIG. 11A illustrates a cross-sectional view of a semiconductor device at a stage of fabrication, in accordance with some embodiments.

FIG. 11B illustrates a top view of a semiconductor device at a stage of fabrication, in accordance with some embodiments.

FIG. 12A illustrates a cross-sectional view of a semiconductor device at a stage of fabrication, in accordance with some embodiments.

FIG. 12B illustrates a top view of a semiconductor device at a stage of fabrication, in accordance with some embodiments.

FIG. 13A illustrates a cross-sectional view of a semiconductor device at a stage of fabrication, in accordance with some embodiments.

FIG. 13B illustrates a top view of a semiconductor device at a stage of fabrication, in accordance with some embodiments.

FIG. 14 illustrates a cross-sectional view of a semiconductor device at a stage of fabrication, in accordance with some embodiments.

FIG. 15A illustrates a cross-sectional view of a semiconductor device at a stage of fabrication, in accordance with some embodiments.

FIG. 15B illustrates a top view of a semiconductor device at a stage of fabrication, in accordance with some embodiments.

FIG. 16A illustrates a cross-sectional view of a semiconductor device, in accordance with some embodiments.

FIG. 16B illustrates a cross-sectional view of a semiconductor device, in accordance with some embodiments.

FIG. 17 illustrates a cross-sectional view of a semiconductor device, in accordance with some embodiments.

FIG. 18 illustrates a cross-sectional view of a semiconductor device, in accordance with some embodiments.

FIG. 19 illustrates a cross-sectional view of a semiconductor device, in accordance with some embodiments.

FIG. 20 illustrates a perspective view of a semiconductor device, in accordance with some embodiments.

FIG. 21 illustrates a perspective view of a semiconductor device, in accordance with some embodiments.

FIG. 22 illustrates a perspective view of a semiconductor device, in accordance with some embodiments.

FIG. 23 is a flow diagram illustrating a method, in accordance with some embodiments.

FIG. 24 is a flow diagram illustrating a method, in accordance with some embodiments.

FIG. 25 is a flow diagram illustrating a method, in accordance with some embodiments.

FIG. 26 illustrates an example computer-readable medium wherein processor-executable instructions configured to embody one or more of the provisions set forth herein may be comprised, according to some embodiments.

### DETAILED DESCRIPTION

The following disclosure provides several different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact. In addition, the present disclosure may repeat reference numerals or letters in the various examples. This repetition is for the purpose of simplicity and clarity and does not in itself dictate a relationship between the various embodiments or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation illustrated in the figures. The apparatus may be otherwise oriented (rotated 90 degrees or at other orientations) and the spatially relative descriptors used herein may likewise be interpreted accordingly.

The term “overlying” and/or the like may be used to describe one element or feature being vertically coincident with and at a higher elevation than another element or feature. For example, a first element overlies a second element if the first element is at a higher elevation than the second element and at least a portion of the first element is vertically coincident with at least a portion of the second element.

The term “underlying” and/or the like may be used to describe one element or feature being vertically coincident with and at a lower elevation than another element or feature. For example, a first element underlies a second element if the first element is at a lower elevation than the second element and at least a portion of the first element is vertically coincident with at least a portion of the second element.

The term “over” may be used to describe one element or feature being at a higher elevation than another element or feature. For example, a first element is over a second element if the first element is at a higher elevation than the second element.

The term “under” may be used to describe one element or feature being at a lower elevation than another element or feature. For example, a first element is under a second element if the first element is at a lower elevation than the second element.

The term “overlapping” and/or the like may be used to describe one element or feature and another element or feature that both cover a same area and/or at least partially coincide with one another in the same area and/or in a same dimension.

A system and method for determining patterned layer maps is provided. In some embodiments, a first patterned layer map defining a first patterned layer is updated to generate an updated patterned layer map defining a second patterned layer. The system identifies a hotspot region of a contact structure map. In some embodiments, the hotspot region comprises a set of contact structures. In some embodiments, at least one of the hotspot region or a second region derived from the hotspot region is compared with at least one of a functional region of a functional component or a resistance region of a resistance component. In some embodiments, the system crops a portion of at least one of the hotspot region or the second region to determine a cropped region responsive to determining the functional region overlaps at least one of the hotspot region or the second region. In some embodiments, the system discards at least one of the hotspot region or the second region responsive to determining the resistance region overlaps at least one of the hotspot region or the second region. In some embodiments, the updated patterned layer map is determined based upon the cropped region. For example, the second patterned layer defined by the updated patterned layer map comprises a portion residing in the cropped region, whereas according to some embodiments, the first patterned layer defined by the first patterned layer map does not comprise a portion residing in the cropped region. In some embodiments, the updated patterned layer map is used to fabricate a layer patterning unit, such as a photolithography mask. In accordance with some embodiments, the present disclosure provides for automatic design and/or generation of at least one of patterned layer maps or patterned layer fabrication units in a dynamic and/or flexible manner for semiconductor devices with different arrangements and/or configurations. In some embodiments, in comparison with patterning a layer of a semiconductor device according to the first patterned layer map, patterning the layer according to the updated patterned layer map provides for a reduced amount of residue, such as metal residue, remaining on the set of contact structures in the semiconductor device. In some embodiments, the reduced amount of residue provides for at least one of improved operation of the semiconductor device, reduced loss, increased yield, improved production efficiency, etc.

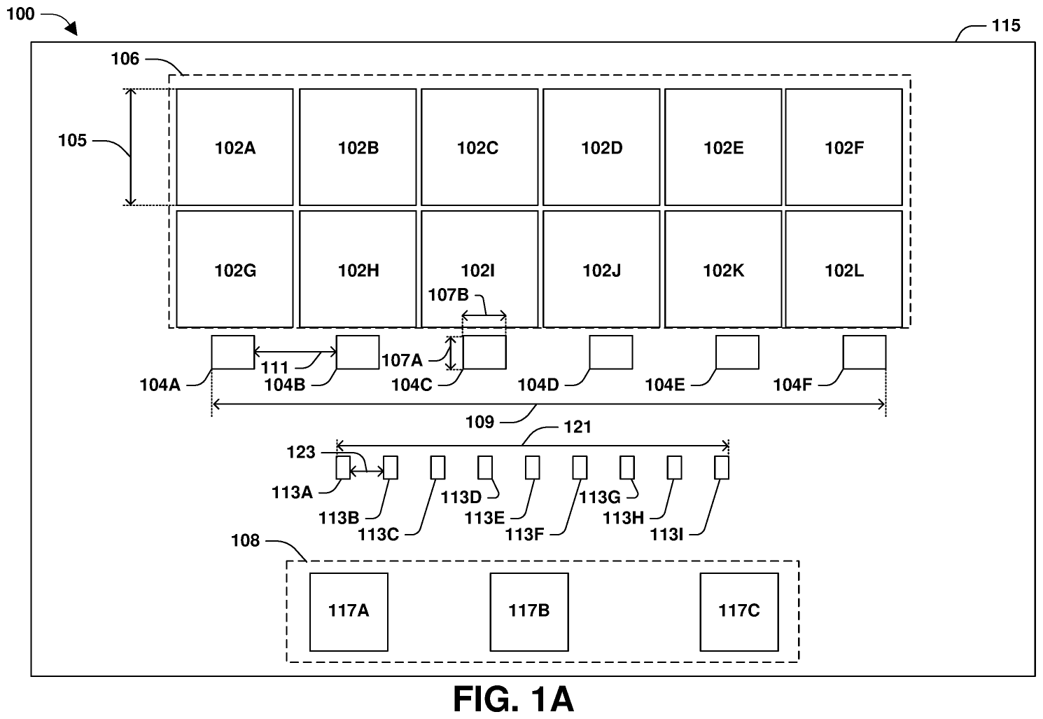

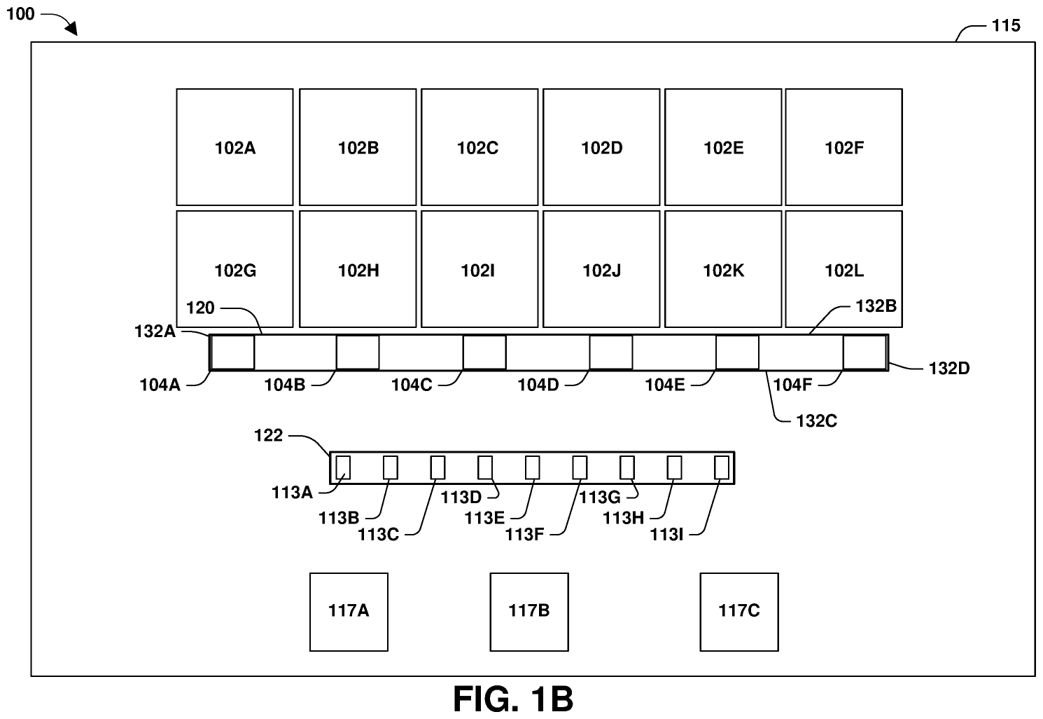

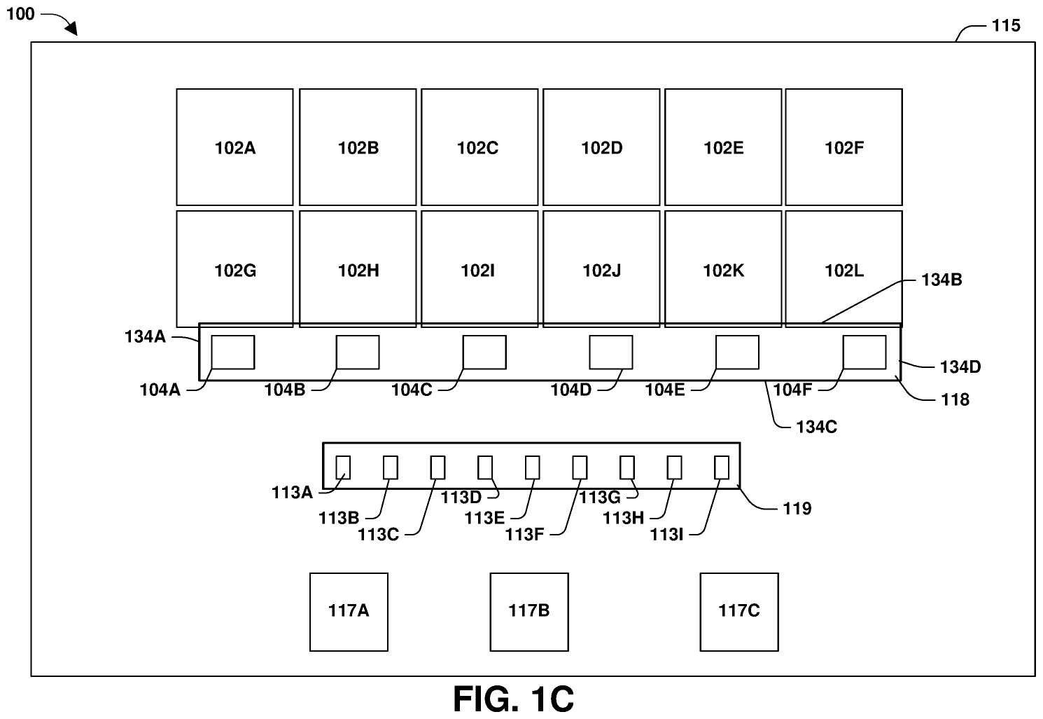

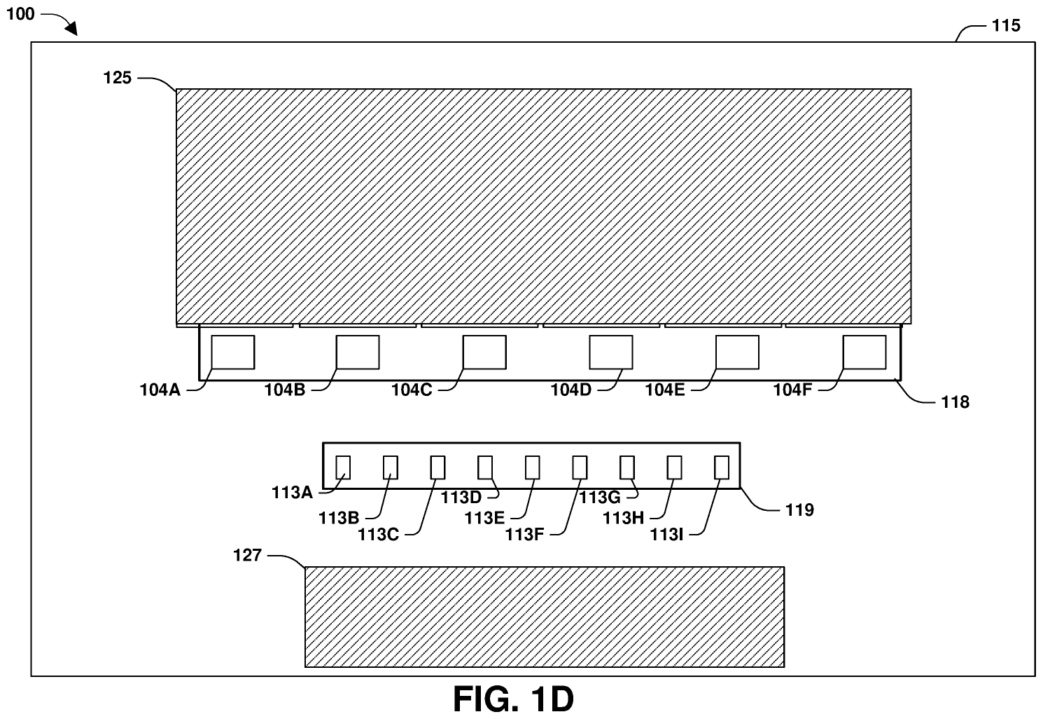

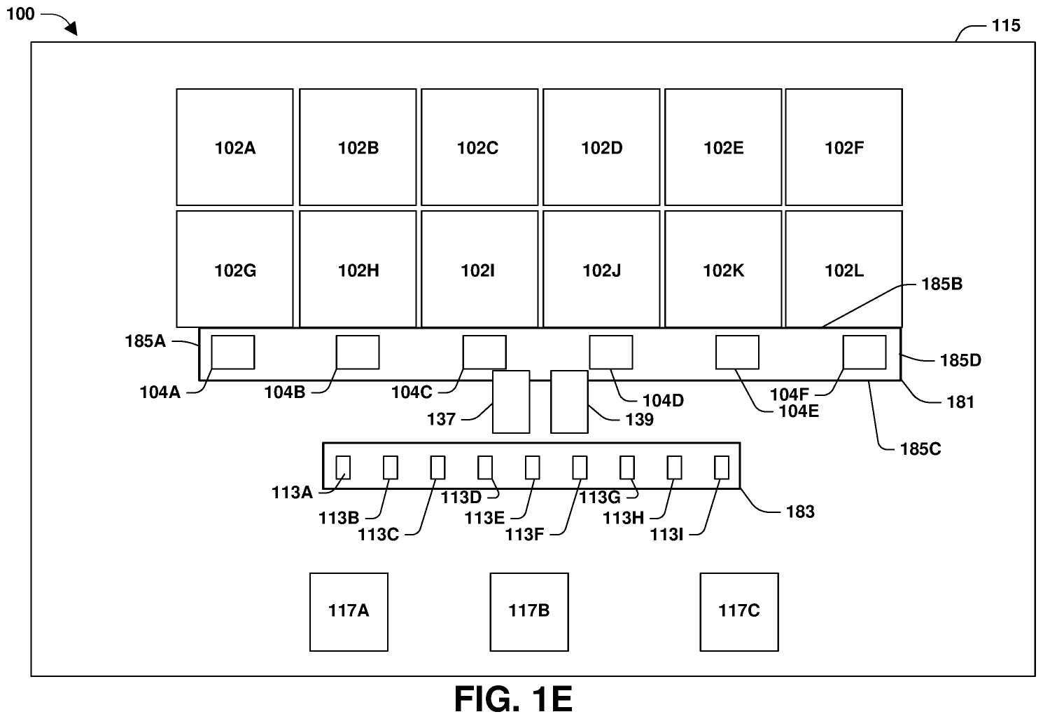

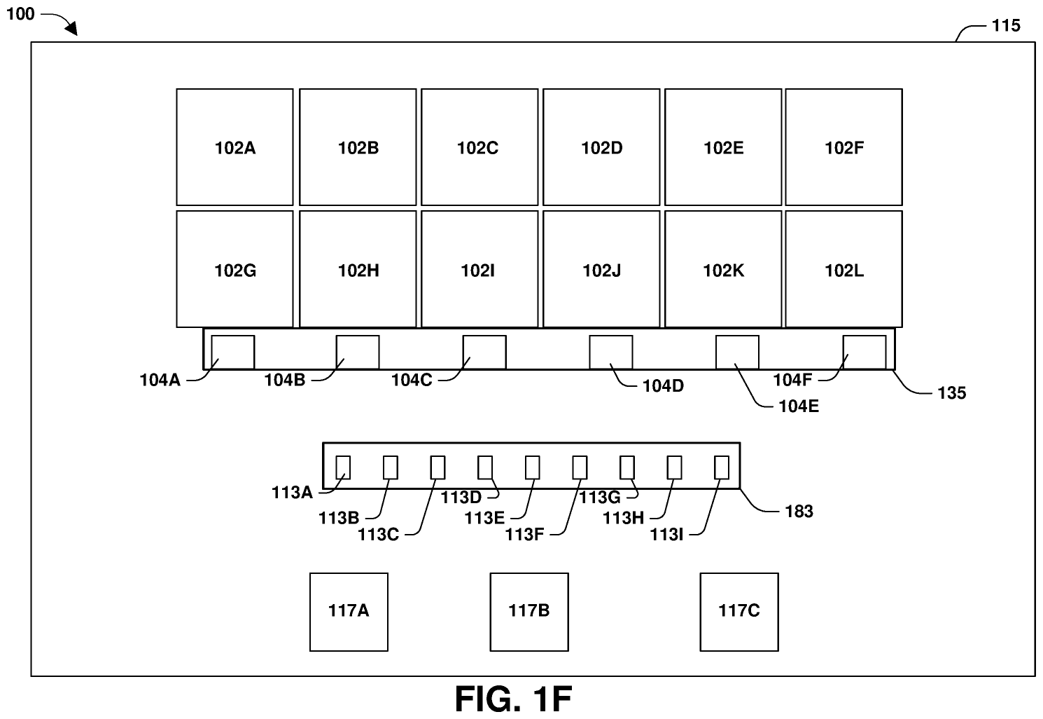

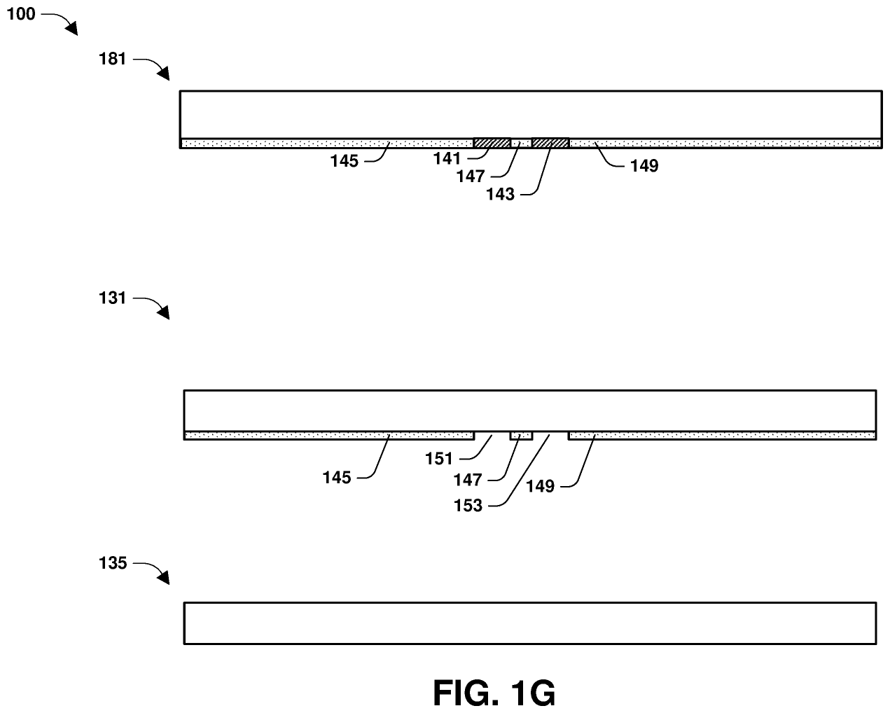

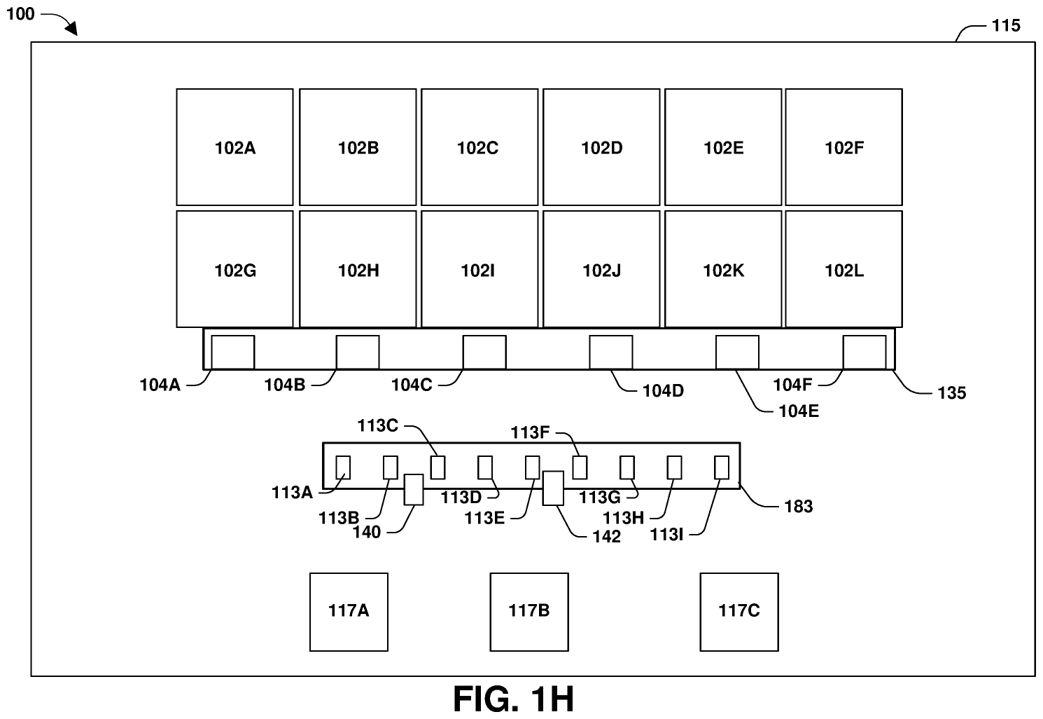

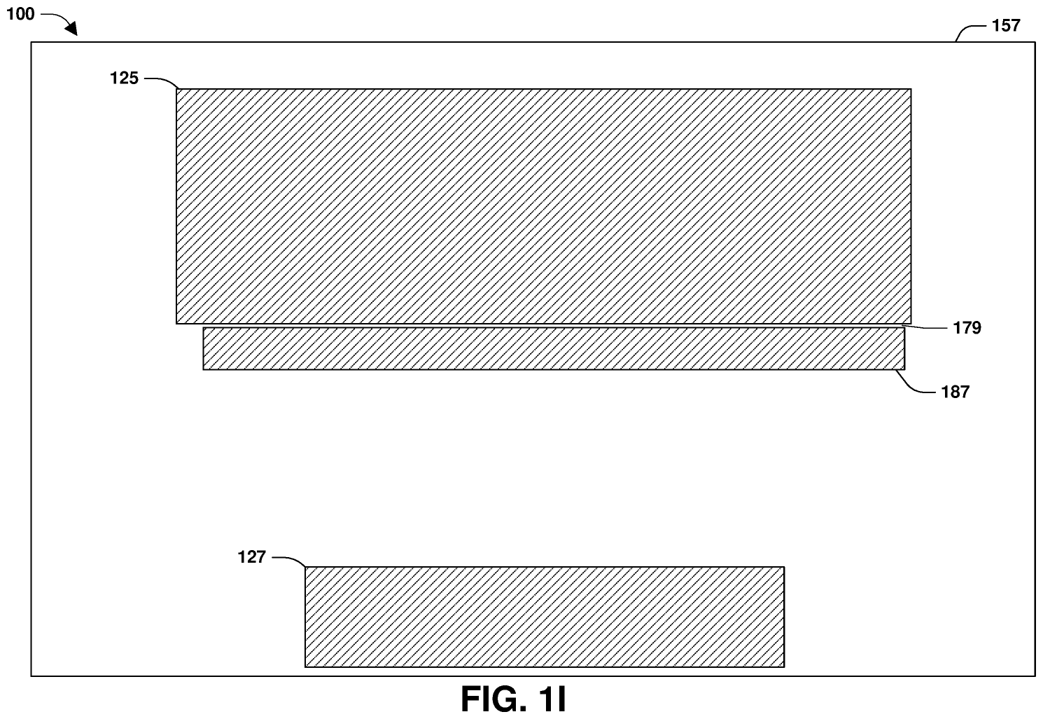

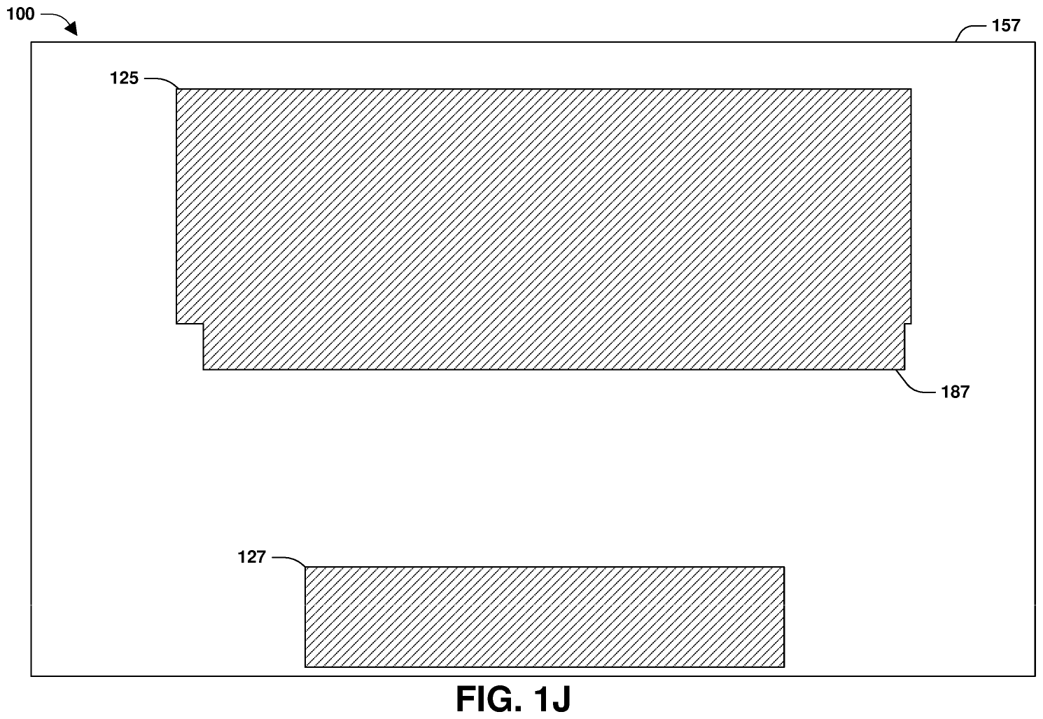

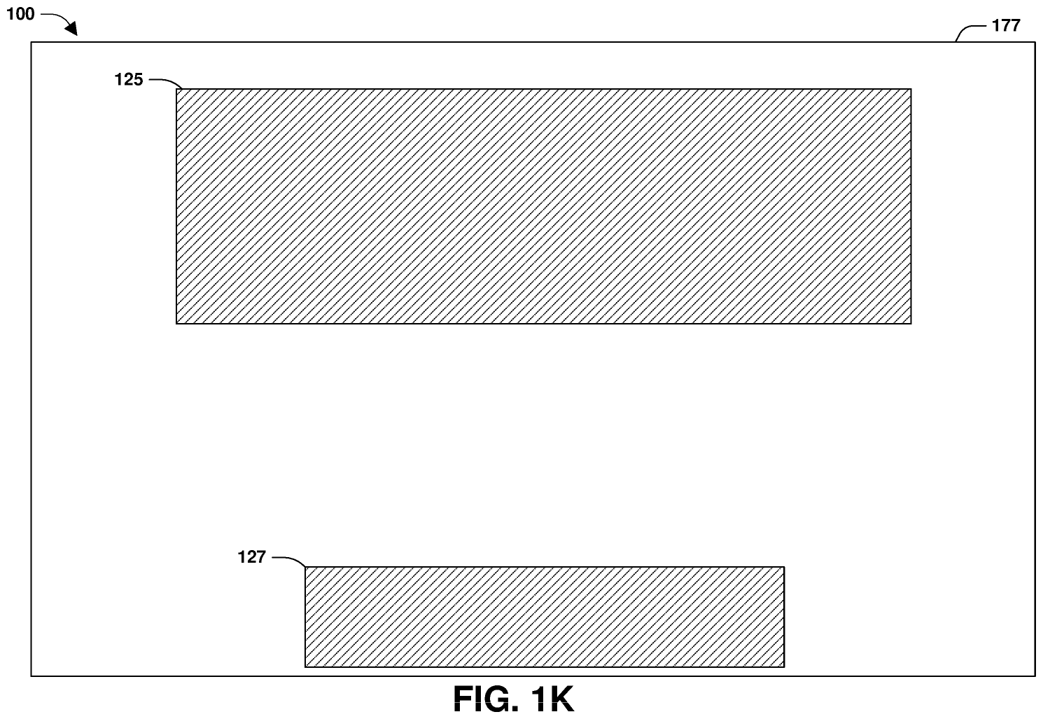

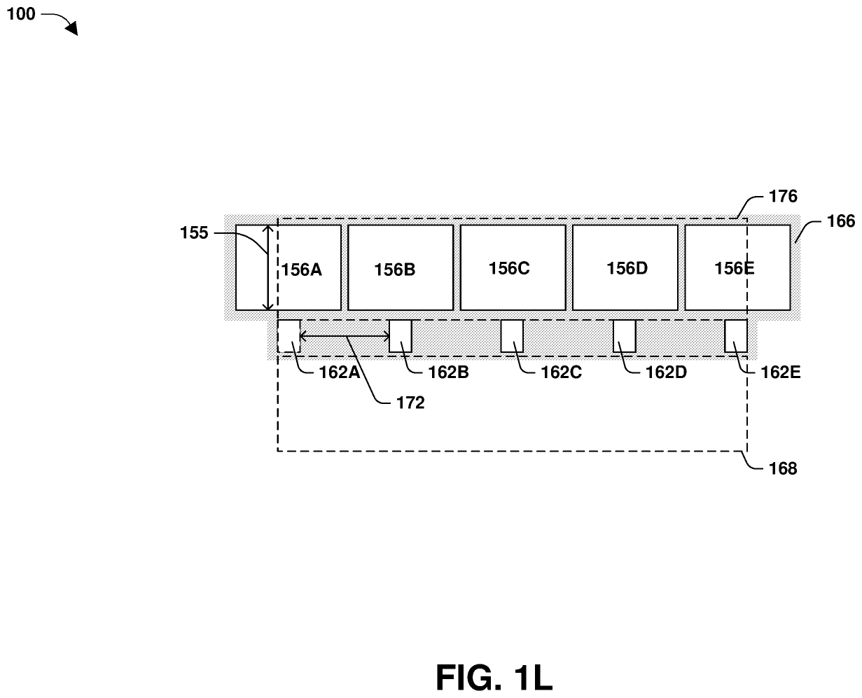

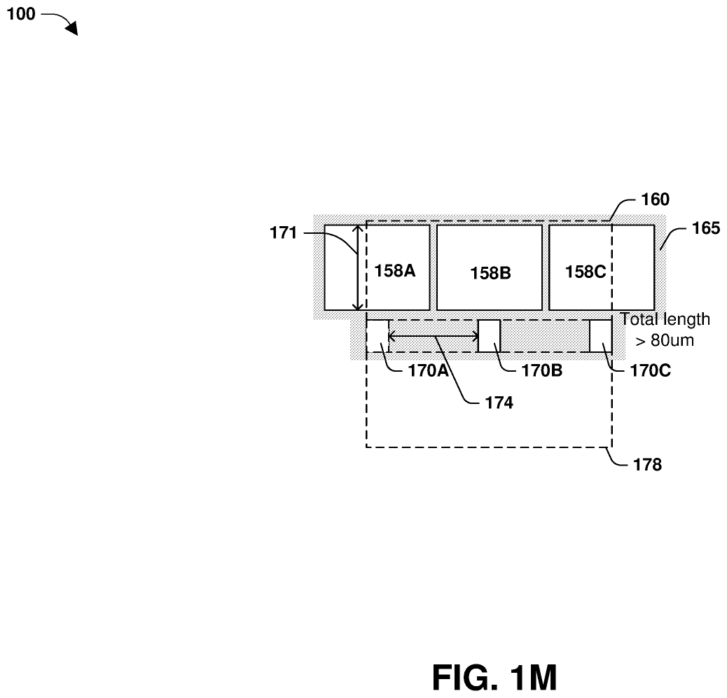

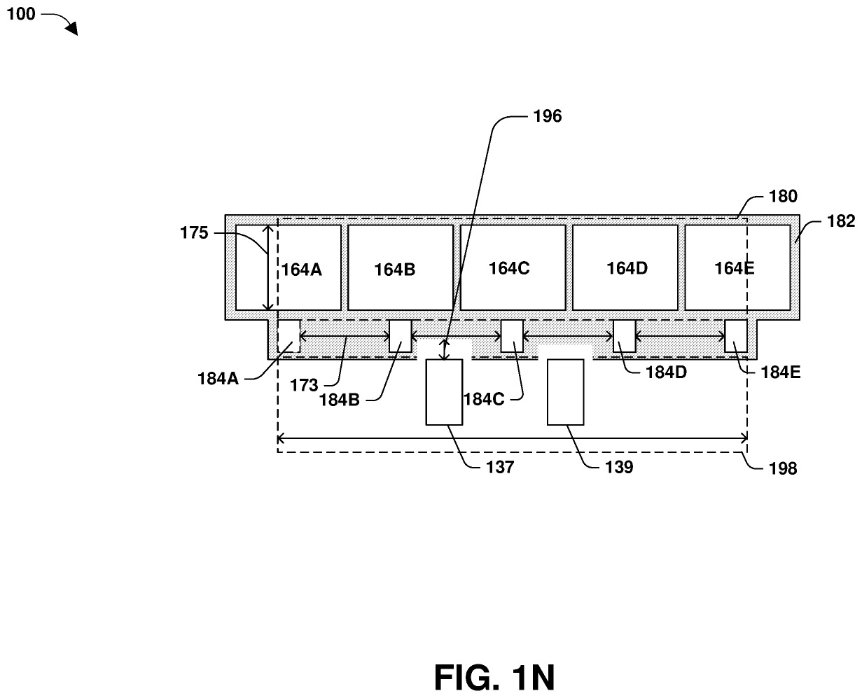

FIGS. 1A-1M illustrate a system 100 for determining patterned layer maps for use in fabricating semiconductor devices. FIG. 1A illustrates a representation of a contact structure map 115 indicative of an arrangement of contact structures, according to some embodiments. In some embodiments, the contact structures indicated by the contact structure map 115 are arranged in one or more layers of a wafer. In some embodiments, the contact structures comprise at least one of a first set of contact structures 102A-102L, a second set of contact structures 104A-104F, a third set of contact structures 113A-113I, a fourth set of contact structures 117A-117C, or one or more other contact structures. In some embodiments, the contact structure map 115 is indicative of one or more types of semiconductor device components other than contact structures are within the scope of the present disclosure. In some embodiments, the contact structure map 115 is indicative of semiconductor device components comprising at least one of resistance components, poly structures, such as doped poly structures, doped regions, or other suitable types of semiconductor components.

In some embodiments, the first set of contact structures 102A-102L are within a first region 106. Although FIG. 1A illustrates 12 contact structures of the first set of contact structures 102A-102L, any number of contact structures of the first set of contact structures 102A-102L are contemplated. In some embodiments, a first contact structure density of the first region 106 is greater than a first threshold contact structure density. The first threshold contact structure density is between about 50% and about 90%. Other values of the first threshold contact structure density are within the scope of the present disclosure. In some embodiments, the first contact structure density corresponds to a proportion of an area of the first region 106 that is occupied by the first set of contact structures 102A-102L. In some embodiments, each contact structure of one, some or all contact structures of the first set of contact structures 102A-102L comprises at least one of polysilicon, one or more metals, or one or more other suitable materials. In some embodiments, each contact structure of one, some or all contact structures of the first set of contact structures 102A-102L has at least one sidewall having a length 105 between about 1 micrometer and about 20 micrometers, such as between about 1 micrometer and about 10 micrometers. In some embodiments, each contact structure of one, some or all contact structures of the first set of contact structures 102A-102L comprises a gate electrode, such as an n-type gate electrode or a p-type gate electrode. In some embodiments, the gate electrode comprises a metal gate, such as an n-type metal gate or a p-type metal gate. In some embodiments, each contact structure of one, some or all contact structures of the first set of contact structures 102A-102L is at least one of in a transistor or is connected to a transistor. In some embodiments, each contact structure of one, some or all contact structures of the first set of contact structures 102A-102L provides a connection between a transistor and a semiconductor component, such as at least one of a metal layer, a doped region, a connection element, an interconnect structure, a contact structure, a via, a metal line, a logic component, circuitry, etc. In some embodiments, each contact structure of one, some or all contact structures of the first set of contact structures 102A-102L is at least one of in or is connected to at least one of a metal-oxide-semiconductor (MOS) structure, a metal-oxide-semiconductor field-effect transistor (MOSFET) structure, a fin field-effect transistor (FinFET) structure, or other suitable structure. In some embodiments, some or all contact structures of the first set of contact structures 102A-102L share at least one of a same material composition, a same shape, a same size, or other same feature with each other. In some embodiments, a difference in at least one of material composition, shape, size, or other feature exists between contact structures of the first set of contact structures 102A-102L.

In some embodiments, the fourth set of contact structures 117A-117C are within a second region 108. Although FIG. 1A illustrates 3 contact structures of the fourth set of contact structures 117A-117C, any number of contact structures of the fourth set of contact structures 117A-117C are contemplated. In some embodiments, a second contact structure density of the second region 108 is less than a second threshold contact structure density. The second threshold contact structure density is between about 10% and about 50%. Other values of the second threshold contact structure density are within the scope of the present disclosure. In some embodiments, the second contact structure density corresponds to a proportion of an area of the second region 108 that is occupied by the fourth set of contact structures 117A-117C. In some embodiments, each contact structure of one, some or all contact structures of the fourth set of contact structures 117A-117C comprises at least one of polysilicon, one or more metals, or one or more other suitable materials. In some embodiments, each contact structure of one, some or all contact structures of the fourth set of contact structures 117A-117C comprises a gate electrode, such as an n-type gate electrode or a p-type gate electrode. In some embodiments, the gate electrode comprises a metal gate, such as an n-type metal gate or a p-type metal gate. In some embodiments, each contact structure of one, some or all contact structures of the fourth set of contact structures 117A-117C is at least one of in a transistor or is connected to a transistor. In some embodiments, each contact structure of one, some or all contact structures of the fourth set of contact structures 117A-117C provides a connection between a transistor and a semiconductor component, such as at least one of a metal layer, a doped region, a connection element, an interconnect structure, a contact structure, a via, a metal line, a logic component, circuitry, etc. In some embodiments, each contact structure of one, some or all contact structures of the fourth set of contact structures 117A-117C is at least one of in or is connected to at least one of a MOS structure, a MOSFET structure, a FinFET structure, or other suitable structure. In some embodiments, some or all contact structures of the fourth set of contact structures 117A-117C share at least one of a same material composition, a same shape, a same size, or other same feature with each other. In some embodiments, a difference in at least one of material composition, shape, size, or other feature exists between contact structures of the fourth set of contact structures 117A-117C.

In some embodiments, the second set of contact structures 104A-104F are between the first region 106 and the second region 108. Although FIG. 1A illustrates six contact structures of the second set of contact structures 104A-104F, any number of contact structures of the second set of contact structures 104A-104F are contemplated. In some embodiments, a first quantity of contact structures of the second set of contact structures 104A-104F ranges from at least about one contact structure to at most about 150 contact structures, such as from at least about three contact structures to at most about 12 contact structures. In some embodiments, each contact structure of one, some or all contact structures of the second set of contact structures 104A-104F has a first area of at most a first threshold area. In some embodiments, the first threshold area is between about 0.5 micrometers² to about 2 micrometers². In some embodiments, the first area corresponds to a product of a first length 107A of a first sidewall of a contact structure and a length 107B of a second sidewall of the contact structure. In some embodiments, the second set of contact structures 104A-104F corresponds to a row of contact structures. In some embodiments, a distance 111 between two adjacent contact structures of the second set of contact structures 104A-104F is at most about 10 micrometers, such as at most about 5 micrometers. In some embodiments, contact structures of the second set of contact structures 104A-104F are spaced uniformly such that each pair of adjacent contact structures of the second set of contact structures 104A-104F are spaced apart by a distance about equal to the distance 111. In some embodiments, the second set of contact structures 104A-104F has a total length 109 that is greater than a first threshold total length. In some embodiments, the first threshold total length between about 500 micrometers and about 1,000 micrometers. In some embodiments, the total length 109 corresponds to a distance between outer sidewalls of two outermost contact structures 104A and 104F of the second set of contact structures 104A-104F. In some embodiments, each contact structure of one, some or all contact structures of the second set of contact structures 104A-104F comprises at least one of polysilicon, one or more metals, or one or more other suitable materials. In some embodiments, each contact structure of one, some or all contact structures of the second set of contact structures 104A-104F comprises a gate electrode, such as an n-type gate electrode or a p-type gate electrode. In some embodiments, the gate electrode comprises a metal gate, such as an n-type metal gate or a p-type metal gate. In some embodiments, each contact structure of one, some or all contact structures of the second set of contact structures 104A-104F is at least one of in a transistor or is connected to a transistor. In some embodiments, each contact structure of one, some or all contact structures of the second set of contact structures 104A-104F provides a connection between a transistor and a semiconductor component, such as at least one of a metal layer, a doped region, a connection element, an interconnect structure, a contact structure, a via, a metal line, a logic component, circuitry, etc. In some embodiments, each contact structure of one, some or all contact structures of the second set of contact structures 104A-104F is at least one of in or is connected to at least one of a MOS structure, a MOSFET structure, a FinFET structure, or other suitable structure. In some embodiments, some or all contact structures of the second set of contact structures 104A-104F share at least one of a same material composition, a same shape, a same size, or other same feature with each other. In some embodiments, a difference in at least one of material composition, shape, size, or other feature exists between contact structures of the second set of contact structures 104A-104F. In some embodiments, one, some or all contact structures of the second set of contact structures 104A-104F share at least one of a same material composition, a same shape, a same size, or other same feature with each other. In some embodiments, one, some or all contact structures of the second set of contact structures 104A-104F share at least one of a same material composition, a same shape, a same size, or other same feature with at least one of a contact structure of the first set of contact structures 102A-102L, a contact structure of the third set of contact structures 113A-113I, or a contact structure of the fourth set of contact structures 117A-117C.

In some embodiments, the third set of contact structures 113A-113I are between the first region 106 and the second region 108. Although FIG. 1A illustrates nine contact structures of the third set of contact structures 113A-113I, any number of contact structures of the third set of contact structures 113A-113I are contemplated. In some embodiments, a second quantity of contact structures of the third set of contact structures 113A-113I ranges from at least about one contact structure to at most about 150 contact structures, such as from at least about three contact structures to at most about 12 contact structures. In some embodiments, each contact structure of one, some or all contact structures of the third set of contact structures 113A-113I has an area of at most the first threshold area. In some embodiments, the third set of contact structures 113A-113I corresponds to a row of contact structures. In some embodiments, a distance 123 between two adjacent contact structures of the third set of contact structures 113A-113I is at most about 10 micrometers, such as at most about 5 micrometers. In some embodiments, contact structures of the third set of contact structures 113A-113I are spaced uniformly such that each pair of adjacent contact structures of the third set of contact structures 113A-113I are spaced apart by a distance about equal to the distance 123. In some embodiments, the third set of contact structures 113A-113I has a total length 121 that is greater than the first threshold total length. In some embodiments, the total length 121 corresponds to a distance between outer sidewalls of two outermost contact structures 113A and 113I of the third set of contact structures 113A-113I. In some embodiments, each contact structure of one, some or all contact structures of the third set of contact structures 113A-113I comprises at least one of polysilicon, one or more metals, or one or more other suitable materials. In some embodiments, each contact structure of one, some or all contact structures of the third set of contact structures 113A-113I comprises a gate electrode, such as an n-type gate electrode or a p-type gate electrode. In some embodiments, the gate electrode comprises a metal gate, such as an n-type metal gate or a p-type metal gate. In some embodiments, each contact structure of one, some or all contact structures of the third set of contact structures 113A-113I is at least one of in a transistor or is connected to a transistor. In some embodiments, each contact structure of one, some or all contact structures of the third set of contact structures 113A-113I provides a connection between a transistor and a semiconductor component, such as at least one of a metal layer, a connection element, an interconnect structure, a contact structure, a via, a doped region, a metal line, a logic component, circuitry, etc. In some embodiments, each contact structure of one, some or all contact structures of the third set of contact structures 113A-113I is at least one of in or is connected to at least one of a MOS structure, a MOSFET structure, a FinFET structure, or other suitable structure. In some embodiments, some or all contact structures of the third set of contact structures 113A-113I share at least one of a same material composition, a same shape, a same size, or other same feature with each other. In some embodiments, a difference in at least one of material composition, shape, size, or other feature exists between contact structures of the third set of contact structures 113A-113I. In some embodiments, one, some or all contact structures of the third set of contact structures 113A-113I share at least one of a same material composition, a same shape, a same size, or other same feature with at least one of a contact structure of the first set of contact structures 102A-102L, a contact structure of the second set of contact structures 104A-104F, or a contact structure of the fourth set of contact structures 117A-117C.

With respect to FIG. 1B, the system 100 determines at least one of a first hotspot region 120 of the contact structure map 115 or a second hotspot region 122 of the contact structure map 115. In some embodiments, the first hotspot region 120 comprises the second set of contact structures 104A-104F. In some embodiments, the second hotspot region 122 comprises the third set of contact structures 113A-113I.

In some embodiments, the system 100 determines the first hotspot region 120 of the contact structure map 115 based upon a first location of a first defect in a first wafer. In some embodiments, the first wafer comprises contact structures such as at least one of the first set of contact structures 102A-102L, the second set of contact structures 104A-104F, the third set of contact structures 113A-113I, or the fourth set of contact structures 117A-117C. In some embodiments, the contact structures in the first wafer are arranged in accordance with the contact structure map 115. In some embodiments, the first defect comprises first residue over one, some or all contact structures of the second set of contact structures 104A-104F disposed in the first wafer. In some embodiments, the first defect, such as the first residue, negatively impacts operation of the first wafer. In some embodiments, the first wafer having the first defect, such as the first residue, causes an increase in leakage current in the first wafer. In some embodiments, the first location of the first defect is determined via analyzing the first wafer via at least one of scanning electron microscopy (SEM), transmission electron microscopy (TEM), or other suitable techniques. In some embodiments, the first location of the first defect is determined via detecting leakage current in the first wafer. In some embodiments, the leakage current is detected by measuring a current in the first wafer when a voltage, such as a voltage applied to a semiconductor component of the first wafer, is at least one of a first defined voltage or within a first defined voltage range. In some embodiments, at least one of the first defined voltage or the first defined voltage range correspond to at least one of V_{DD} or V_{DDL}. In some embodiments, the system 100 maps the first location of the first defect in the first wafer to the first hotspot region 120.

In some embodiments, the system 100 determines the first hotspot region 120 of the contact structure map 115 based upon a determination that at least one of (i) each contact structure of one, some or all contact structures of the second set of contact structures 104A-104F has an area that is not greater than the first threshold area, (ii) the first quantity of contact structures of the second set of contact structures 104A-104F is not greater than a first threshold quantity of contact structures, such as about 150 contact structures or about 12 contact structures, (iii) the first quantity of contact structures of the second set of contact structures 104A-104F is greater than a second threshold quantity of contact structures, such as about 1 contact structure or about 3 contact structures, (iv) the total length 109 (shown in FIG. 1A) of the second set of contact structures 104A-104F is greater than the first threshold total length, (v) the total length 109 of the second set of contact structures 104A-104F is not greater than a second threshold total length, or (vi) the first hotspot region 120 is between the first region 106 having the first contact structure density greater than the first threshold contact structure density and the second region 108 having the second contact structure density less than the second threshold contact structure density.

In some embodiments, the system 100 determines the second hotspot region 122 of the contact structure map 115 using one or more of the techniques provided herein with respect to determining the first hotspot region 120. In some embodiments, the system 100 determines the second hotspot region 122 based upon a second location of a second defect in a second wafer. In some embodiments, the second wafer comprises contact structures such as at least one of the first set of contact structures 102A-102L, the second set of contact structures 104A-104F, the third set of contact structures 113A-113I, or the fourth set of contact structures 117A-117C. In some embodiments, the contact structures in the second wafer are arranged in accordance with the contact structure map 115. The second wafer is the same as the first wafer or different than the first wafer. In some embodiments, the second defect comprises second residue over one, some or all contact structures of the third set of contact structures 113A-113I disposed in the second wafer. In some embodiments, the second defect, such as the second residue, negatively impacts operation of the second wafer. In some embodiments, the system 100 maps the second location of the second defect in the second wafer to the second hotspot region 122.

In some embodiments, the system 100 determines the second hotspot region 122 of the contact structure map 115 based upon a determination that at least one of (i) each contact structure of one, some or all contact structures of the third set of contact structures 113A-113I has an area that is not greater than the first threshold area, (ii) the first quantity of contact structures of the third set of contact structures 113A-113I is not greater than the first threshold quantity of contact structures, (iii) the first quantity of contact structures of the third set of contact structures 113A-113I is greater than the second threshold quantity of contact structures, (iv) the total length 121 (shown in FIG. 1A) of the third set of contact structures 113A-113I is greater than the first threshold total length, (v) the total length 121 of the third set of contact structures 113A-113I is not greater than the second threshold total length, or (vi) the second hotspot region 122 is between the first region 106 having the first contact structure density greater than the first threshold contact structure density and the second region 108 having the second contact structure density less than the second threshold contact structure density.

In some embodiments, the system 100 scans the contact structure map 115 to identify the first set of contact structures 102A-102L. In some embodiments, the system 100 determines that the first set of contact structures 102A-102L is not in a hotspot region based upon a determination that at least one of (i) each contact structure of one, some or all contact structures of the first set of contact structures 102A-102L has an area that is greater than the first threshold area, (ii) a quantity of contact structures of the first set of contact structures 102A-102L is greater than the first threshold quantity of contact structures, (iii) the quantity of contact structures of the first set of contact structures 102A-102L is not greater than the second threshold quantity of contact structures, (iv) a total length of the first set of contact structures 102A-102L is not greater than the first threshold total length, (v) the total length of the first set of contact structures 102A-102L is greater than the second threshold total length, or (vi) the first set of contact structures 102A-102L is not between a region having a contact structure density greater than the first threshold contact structure density and a region having a contact structure density less than the second threshold contact structure density. In some embodiments, responsive to determining that the first set of contact structures 102A-102L is not in a hotspot region, the system 100 does not generate a hotspot region comprising the first set of contact structures 102A-102L.

In some embodiments, the system 100 scans the contact structure map 115 to identify the second set of contact structures 104A-104F. In some embodiments, the system 100 determines that the second set of contact structures 104A-104F is in a hotspot region based upon a determination that at least one of (i) each contact structure of one, some or all contact structures of the second set of contact structures 104A-104F has an area that is not greater than the first threshold area, (ii) the first quantity of contact structures of the second set of contact structures 104A-104F is not greater than the first threshold quantity of contact structures, (iii) the first quantity of contact structures of the second set of contact structures 104A-104F is greater than the second threshold quantity of contact structures, (iv) the total length 109 (shown in FIG. 1A) of the second set of contact structures 104A-104F is greater than the first threshold total length, (v) the total length 109 of the second set of contact structures 104A-104F is not greater than the second threshold total length, or (vi) the second set of contact structures 104A-104F is between the first region 106 having the first contact structure density greater than the first threshold contact structure density and the second region 108 having the second contact structure density less than the second threshold contact structure density. In some embodiments, responsive to determining that the second set of contact structures 104A-104F is in a hotspot region, the system 100 generates the first hotspot region 120 of the contact structure map 115.

With respect to FIG. 1C, the system 100 at least one of enlarges the first hotspot region 120 to determine a first enlarged region 118 of the contact structure map 115 or enlarges the second hotspot region 122 to determine a second enlarged region 119 of the contact structure map 115. In some embodiments, the first enlarged region 118 comprises the second set of contact structures 104A-104F. In some embodiments, the second enlarged region 119 comprises the third set of contact structures 113A-113I.

In some embodiments, the system 100 enlarges the first hotspot region 120 according to a first predefined enlargement profile to determine the first enlarged region 118. In some embodiments, the system 100 enlarges the first hotspot region 120 by increasing a length of one, some or all sides 132A-132D (shown in FIG. 1B) of the first hotspot region 120 according to the first predefined enlargement profile. In some embodiments, at least one of (i) a length of a first side 132A (shown in FIG. 1B) of the first hotspot region 120 is increased by a first enlargement value to determine a length of a first side 134A (shown in FIG. 1C) of the first enlarged region 118, (ii) a length of a second side 132B (shown in FIG. 1B) of the first hotspot region 120 is increased by a second enlargement value to determine a length of a second side 134B (shown in FIG. 1C) of the first enlarged region 118, (iii) a length of a third side 132C (shown in FIG. 1B) of the first hotspot region 120 is increased by the second enlargement value to determine a length of a third side 134C (shown in FIG. 1C) of the first enlarged region 118, or (iv) a length of a fourth side 132D (shown in FIG. 1B) of the first hotspot region 120 is increased by the first enlargement value to determine a length of a fourth side 134D (shown in FIG. 1C) of the first enlarged region 118. In some embodiments, the first enlargement value is equal to the second enlargement value. Embodiments are contemplated in which the first enlargement value is different than the second enlargement value. In some embodiments, the first predefined enlargement profile is indicative of at least one of the first enlargement value or the second enlargement value. In some embodiments, the first enlargement value corresponds to a constant value. In some embodiments, the first enlargement value is between about 0.1 micrometers to about 2 micrometers, such as between about 0.1 micrometers to about 0.5 micrometers. In some embodiments, the first enlargement value is determined based upon a first proportion indicated by the first predefined enlargement profile. In some embodiments, the first proportion is between about 0.01% and about 10%. In some embodiments, the system 100 determines the first enlargement value based upon the first proportion and the length of the first side 132A (shown in FIG. 1B) of the first hotspot region 120. In some embodiments, when the first proportion is about 0.1% and the length of the first side 132A of the first hotspot region 120 is about 500 micrometers, the system 100 determines the first enlargement value to be about 0.5 micrometers, and thus, the system 100 increases the length of the first side 132A of the first hotspot region 120 by about 0.5 micrometers to determine the length of the first side 134A (shown in FIG. 1C) of the first enlarged region 118.

In some embodiments, a distance between the first side 134A (shown in FIG. 1C) of the first enlarged region 118 and the contact structure 104A of the second set of contact structures 104A-104F is greater than a distance between the first side 132A (shown in FIG. 1B) of the first hotspot region 120 and the contact structure 104A of the second set of contact structures 104A-104F. In some embodiments, a distance between the second side 134B (shown in FIG. 1C) of the first enlarged region 118 and a contact structure of the second set of contact structures 104A-104F is greater than a distance between the second side 132B (shown in FIG. 1B) of the first hotspot region 120 and the contact structure. In some embodiments, a distance between the third side 134C (shown in FIG. 1C) of the first enlarged region 118 and a contact structure of the second set of contact structures 104A-104F is greater than a distance between the third side 132C (shown in FIG. 1B) of the first hotspot region 120 and the contact structure. In some embodiments, a distance between the fourth side 134D (shown in FIG. 1C) of the first enlarged region 118 and the contact structure 104F of the second set of contact structures 104A-104F is greater than a distance between the fourth side 132D (shown in FIG. 1B) of the first hotspot region 120 and the contact structure 104F of the second set of contact structures 104A-104F.

In some embodiments, the system 100 enlarges the second hotspot region 122 to determine the second enlarged region 119 using one or more of the techniques provided herein with respect to enlarging the first hotspot region 120 to determine the first enlarged region 118. In some embodiments, the system 100 enlarges the second hotspot region 122 to determine the second enlarged region 119 according to a second predefined enlargement profile. In some embodiments, the second predefined enlargement profile is the same as the first predefined enlargement profile. Embodiments are contemplated in which the second predefined enlargement profile is different than the first predefined enlargement profile.

In some embodiments, the system 100 compares at least one of the first enlarged region 118 or the second enlarged region 119 with one or more first patterned layer regions of a first patterned layer map defining a first patterned layer. In some embodiments, the first patterned layer map was (previously) used to form a patterned layer in at least one of the first wafer associated with the first defect or the second wafer associated with the second defect. In some embodiments, a first patterning process is performed according to the first patterned layer map to pattern a first layer to form the first patterned layer. In some embodiments, the first patterned layer map is indicative of one or more portions of the first layer that are removed in the first patterning process to form the first patterned layer. In some embodiments, the first patterned layer map is indicative of one or more portions of the first layer that are not removed in the first patterning process to form the first patterned layer. In some embodiments, a patterned layer region of the one or more first patterned layer regions corresponds to a region where the first patterned layer resides. In some embodiments, the patterned layer region comprises a portion of the first layer that is not removed in the first patterning process to form the first patterned layer.

In some embodiments, in a first scenario (not shown) where the first enlarged region 118 overlaps a patterned layer region of the one or more first patterned layer regions, the system 100 classifies the first enlarged region 118 as a disqualified region responsive to determining that the first enlarged region 118 overlaps the patterned layer region of the one or more first patterned layer regions. In some embodiments, the system 100 discards the first enlarged region 118 responsive to classifying the first enlarged region 118 as the disqualified region. In some embodiments, the system 100 ceases to consider the first enlarged region 118 as a candidate supplemental patterned layer region to add to the first patterned layer map to generate a second patterned layer map 157 (shown in FIGS. 1I-1J).

FIG. 1D illustrates the one or more first patterned layer regions of the first patterned layer map mapped to the contact structure map 115, according to some embodiments. With respect to FIG. 1D, the system 100 compares at least one of the first enlarged region 118 or the second enlarged region 119 with the one or more first patterned layer regions of the first patterned layer map, according to some embodiments. In some embodiments, the one or more first patterned layer regions comprise a first patterned layer region 125 (shown as a pattern-filled rectangle in FIG. 1D) and a second patterned layer region 127 (shown as a pattern-filled rectangle in FIG. 1D). In some embodiments, the first patterned layer overlies some or all contact structures of the contact structure map 115. In some embodiments, the first patterned layer region 125 corresponds to a first portion, of the first patterned layer, overlying the first set of contact structures 102A-102L. In some embodiments, the second patterned layer region 127 corresponds to a second portion, of the first patterned layer, overlying the fourth set of contact structures 117A-117C. In some embodiments, the first patterning process comprises (i) removing portions of the first layer that are outside the one or more first patterned layer regions, and (ii) not removing portions of the first layer in the one or more first patterned layer regions, such as not removing a portion of the first layer within the first patterned layer region 125 and not removing a portion of the first layer within the second patterned layer region 127. In some embodiments, the first enlarged region 118 not overlapping the one or more first patterned layer regions indicates that, according to the first patterned layer map, the first enlarged region 118 does not overlap the first patterned layer. In some embodiments, the second enlarged region 119 not overlapping the one or more first patterned layer regions indicates that, according to the first patterned layer map, the second enlarged region 119 does not overlap the first patterned layer.

With respect to FIG. 1E, the system 100 compares at least one of a third enlarged region 181 or a fourth enlarged region 183 with one or more functional regions of one or more first functional components. In some embodiments, the third enlarged region 181 corresponds to the first hotspot region 120. In some embodiments, the fourth enlarged region 183 corresponds to the second hotspot region 122. In some embodiments, the third enlarged region 181 comprises the second set of contact structures 104A-104F. In some embodiments, the fourth enlarged region 183 comprises the third set of contact structures 113A-113I.

In some embodiments, the system 100 enlarges the first hotspot region 120 according to a third predefined enlargement profile to determine the third enlarged region 181. In some embodiments, the system 100 enlarges the first hotspot region 120 by increasing a length of one, some or all sides 132A-132D (shown in FIG. 1B) of the first hotspot region 120 according to the third predefined enlargement profile. In some embodiments, at least one of (i) the length of the first side 132A (shown in FIG. 1B) of the first hotspot region 120 is increased by a third enlargement value to determine a length of a first side 185A (shown in FIG. 1E) of the third enlarged region 181, (ii) a length of a second side 132B (shown in FIG. 1B) of the first hotspot region 120 is increased by a fourth enlargement value to determine a length of a second side 185B (shown in FIG. 1E) of the third enlarged region 181, (iii) a length of a third side 132C (shown in FIG. 1B) of the first hotspot region 120 is increased by the fourth enlargement value to determine a length of a third side 185C (shown in FIG. 1E) of the third enlarged region 181, or (iv) a length of a fourth side 132D (shown in FIG. 1B) of the first hotspot region 120 is increased by the third enlargement value to determine a length of a fourth side 185D (shown in FIG. 1E) of the third enlarged region 181. In some embodiments, the third enlargement value is equal to the fourth enlargement value. Embodiments are contemplated in which the third enlargement value is different than the fourth enlargement value. In some embodiments, the third predefined enlargement profile is indicative of at least one of the third enlargement value or the fourth enlargement value. In some embodiments, the third enlargement value corresponds to a constant value. In some embodiments, the third enlargement value is between about 0.1 micrometers to about 2 micrometers, such as between about 0.1 micrometers to about 1 micrometer. In some embodiments, the third enlargement value is determined based upon a first proportion indicated by the third predefined enlargement profile. In some embodiments, the first proportion is between about 0.01% and about 10%. In some embodiments, the system 100 determines the third enlargement value based upon the first proportion and the length of the first side 132A (shown in FIG. 1B) of the first hotspot region 120. In some embodiments, when the first proportion is about 0.1% and the length of the first side 132A of the first hotspot region 120 is about 500 micrometers, the system 100 determines the third enlargement value to be about 0.5 micrometers, and thus, the system 100 increases the length of the first side 132A of the first hotspot region 120 by about 0.5 micrometers to determine the length of the first side 185A (shown in FIG. 1E) of the third enlarged region 181.

In some embodiments, a distance between the first side 185A (shown in FIG. 1E) of the third enlarged region 181 and the contact structure 104A of the second set of contact structures 104A-104F is greater than a distance between the first side 132A (shown in FIG. 1B) of the first hotspot region 120 and the contact structure 104A of the second set of contact structures 104A-104F. In some embodiments, a distance between the second side 185B (shown in FIG. 1E) of the third enlarged region 181 and a contact structure of the second set of contact structures 104A-104F is greater than a distance between the second side 132B (shown in FIG. 1B) of the first hotspot region 120 and the contact structure. In some embodiments, a distance between the third side 185C (shown in FIG. 1E) of the third enlarged region 181 and a contact structure of the second set of contact structures 104A-104F is greater than a distance between the third side 132C (shown in FIG. 1B) of the first hotspot region 120 and the contact structure. In some embodiments, a distance between the fourth side 185D (shown in FIG. 1E) of the third enlarged region 181 and the contact structure 104F of the second set of contact structures 104A-104F is greater than a distance between the fourth side 132D (shown in FIG. 1B) of the first hotspot region 120 and the contact structure 104F of the second set of contact structures 104A-104F.

In some embodiments, the system 100 enlarges the second hotspot region 122 to determine the fourth enlarged region 183 using one or more of the techniques provided herein with respect to enlarging the first hotspot region 120 to determine the third enlarged region 181. In some embodiments, the system 100 enlarges the second hotspot region 122 to determine the fourth enlarged region 183 according to a fourth predefined enlargement profile. In some embodiments, the fourth predefined enlargement profile is the same as the third predefined enlargement profile. Embodiments are contemplated in which the fourth predefined enlargement profile is different than the third predefined enlargement profile.

In some embodiments, the third enlarged region 181 is different than the first enlarged region 118 and the fourth enlarged region 183 is different than the second enlarged region 119. Embodiments are contemplated in which at least one of the third enlarged region 181 is the same as the first enlarged region 118 or the fourth enlarged region 183 is the same as the second enlarged region 119.

In some embodiments, the one or more functional regions of the one or more first functional components comprise at least one of a first functional region 137 of a first functional component or a second functional region 139 of a second functional component. In some embodiments, the one or more first functional components correspond to one or more semiconductor components in a wafer, such as the first wafer, that is fabricated based upon at least one of the first patterned layer map, the contact structure map 115, or a functional component map (not shown) indicative of the one or more functional regions.

In some embodiments, the first functional component comprises a first poly structure, such as a first doped poly structure. In some embodiments, the first poly structure comprises an n-doped poly structure or a p-doped poly structure. In some embodiments, the first functional component, such as the first poly structure, comprises at least one of polysilicon, a polymer, or one or more other suitable materials. In some embodiments, the second functional component comprises a second poly structure, such as a second doped poly structure. In some embodiments, the second poly structure comprises an n-doped poly structure or a p-doped poly structure. In some embodiments, the second functional component, such as the second poly structure, comprises at least one of polysilicon, a polymer, or one or more other suitable materials. In some embodiments, the contact structure map 115 is indicative of at least one of the first functional region 137 of the first functional component or the second functional region 139 of the second functional component. In some embodiments, the system 100 determines at least one of a position or a size of the first functional region 137 and/or the second functional region 139 based upon the functional component map. In some embodiments, the system 100 maps the one or more functional regions indicated by the functional component map to the first functional region 137 and/or the second functional region 139 in the contact structure map 115.

In some embodiments, the system 100 determines that at least one of (i) a first portion 141 (shown in FIG. 1G) of the third enlarged region 181 overlaps the first functional region 137, or (ii) a second portion 143 (shown in FIG. 1G) of the third enlarged region 181 overlaps the second functional region 139. In some embodiments, the first portion 141 of the third enlarged region 181 overlaps at least a portion of the first functional region 137. In some embodiments, the second portion 143 of the third enlarged region 181 overlaps at least a portion of the second functional region 139. In some embodiments, responsive to determining that at least one of the first portion 141 of the third enlarged region 181 overlaps the first functional region 137 or the second portion 143 of the third enlarged region 181 overlaps the second functional region 139, the system 100 removes at least one of the first portion 141 of the third enlarged region 181 or the second portion 143 of the third enlarged region 181 to determine a cropped region 135 (shown in FIG. 1F) of the contact structure map 115. In some embodiments, the system 100 determines that the fourth enlarged region 183 does not overlap a functional region of the one or more functional regions.

With respect to FIG. 1F, the system 100 determines the cropped region 135, of the contact structure map 115, that excludes at least one of (i) the first portion 141 of the third enlarged region 181, or (ii) the second portion 143 of the third enlarged region 181, according to some embodiments. In some embodiments, based upon a determination that the fourth enlarged region 183 does not overlap a functional region of the one or more functional regions, the system 100 does not modify the fourth enlarged region 183.

FIG. 1G illustrates one or more operations performed by the system 100 to determine the cropped region 135, according to some embodiments. In some embodiments, the third enlarged region 181 comprises at least one of (i) the first portion 141, (ii) the second portion 143, (iii) a third portion 145 adjacent the first portion 141, (iv) a fourth portion 147 between the first portion 141 and the second portion 143, or (v) a fifth portion 149 adjacent the second portion 143. In some embodiments, the system 100 removes the first portion 141 and the second portion 143 from the third enlarged region 181 to determine a region 131 of the contact structure map 115. In some embodiments, removing the first portion 141 and the second portion 143 forms a first gap 151 between the third portion 145 and the fourth portion 147 and a second gap 153 between the fourth portion 147 and the fifth portion 149. In some embodiments, the system 100 removes at least one of the third portion 145, the fourth portion 147, or the fifth portion 149 from the region 131 to determine the cropped region 135 of the contact structure map 115. In some embodiments, by removing the third portion 145, the fourth portion 147, and the fifth portion 149 from the region 131, the cropped region 135 is generated without the first gap 151 and the second gap 153.

With respect to FIG. 1H, the system 100 compares at least one of the cropped region 135 or the fourth enlarged region 183 with one or more resistance regions of one or more first resistance components. In some embodiments, the one or more resistance regions of the one or more first resistance components comprise at least one of a first resistance region 140 of a first resistance component or a second resistance region 142 of a second resistance component. In some embodiments, the one or more first resistance components correspond to one or more semiconductor components in a wafer, such as the first wafer, that is fabricated based upon at least one of the first patterned layer map, the contact structure map 115, or a resistance component map (not shown) indicative of the one or more resistance regions.

In some embodiments, the first resistance component comprises a first high resistance device. In some embodiments, the first resistance component has a first resistance higher than a threshold resistance. In some embodiments, the first resistance component comprises a p-type resistance component or an n-type resistance component. In some embodiments, the first resistance component comprises at least one of polysilicon, a polymer, an oxide material, or one or more other suitable materials. In some embodiments, the first resistance component comprises resist protective oxide (RPO). In some embodiments, the first resistance component comprises a first high resistance device. In some embodiments, the second resistance component has a second resistance higher than the threshold resistance. In some embodiments, the second resistance component comprises a p-type resistance component or an n-type resistance component. In some embodiments, the second resistance component comprises at least one of polysilicon, a polymer, an oxide material, or one or more other suitable materials. In some embodiments, the second resistance component comprises RPO. In some embodiments, the contact structure map 115 is indicative of at least one of the first resistance region 140 of the first resistance component or the second resistance region 142 of the second resistance component. In some embodiments, the system 100 determines at least one of a position or a size of the first resistance region 140 and/or the second resistance region 142 based upon the resistance component map. In some embodiments, the system 100 maps one or more resistance regions indicated by the resistance component map to the first resistance region 140 and/or the second resistance region 142 in the contact structure map 115.

In some embodiments, the system 100 determines that the cropped region 135 does not overlap a resistance region of the one or more resistance regions. In some embodiments, the system 100 determines that the fourth enlarged region 183 overlaps at least one of the first resistance region 140 or the second resistance region 142. In some embodiments, the fourth enlarged region 183 overlaps at least a portion of the first resistance region 140. In some embodiments, the fourth enlarged region 183 overlaps at least a portion of the second resistance region 142.

In some embodiments, the system 100 classifies the cropped region 135 as a qualified region responsive to determining that the cropped region 135 does not overlap a resistance region of the one or more resistance regions.

In some embodiments, the system 100 classifies the fourth enlarged region 183 as a disqualified region responsive to determining that the fourth enlarged region 183 overlaps at least one of the first resistance region 140 or the second resistance region 142 of the one or more resistance regions. In some embodiments, the system 100 discards the fourth enlarged region 183 responsive to classifying the fourth enlarged region 183 as the disqualified region. In some embodiments, the system 100 ceases to consider the fourth enlarged region 183 as a candidate supplemental patterned layer region to add to the first patterned layer map to generate the second patterned layer map 157 (shown in FIGS. 1I-1J). In a second scenario (not shown) where the fourth enlarged region 183 is determined not to overlap a resistance region of the one or more resistance regions, in some embodiments, the system 100 classifies fourth enlarged region 183 as a qualified region.

With respect to FIG. 1I, the system 100 determines the second patterned layer map 157, according to some embodiments. In some embodiments, the second patterned layer map 157 is indicative of one or more second patterned layer regions. In some embodiments, the second patterned layer map 157 is determined based upon at least one of the first patterned layer map or one or more qualified regions determined by the system 100. In some embodiments, the one or more qualified regions comprise the cropped region 135. In some embodiments, the system 100 supplements the first patterned layer map with one or more supplemental patterned layer regions to generate the second patterned layer map 157. In some embodiments, the one or more supplemental patterned layer regions are generated based upon the one or more qualified regions.

In some embodiments, the one or more second patterned layer regions indicated by the second patterned layer map 157 comprise at least one of the first patterned layer region 125, the second patterned layer region 127, or a first supplemental patterned layer region 187. In some embodiments, the first supplemental patterned layer region 187 is generated based upon the cropped region 135. In some embodiments, the first supplemental patterned layer region 187 matches the cropped region 135, such as having a same size and position as the cropped region 135. In some embodiments, the cropped region 135 is modified to generate the first supplemental patterned layer region 187, such as where the first supplemental patterned layer region 187 is a modified version of the cropped region 135. In some embodiments, based upon the fourth enlarged region 183 (shown in FIG. 1H) being classified as a disqualified region, the second patterned layer map 157 does not include a supplemental patterned layer region corresponding to the fourth enlarged region 183. In some embodiments, in the first scenario (not shown) where the first enlarged region 118 overlaps a patterned layer region of the one or more first patterned layer regions, responsive to classifying the first enlarged region 118 as a disqualified region, the second patterned layer map 157 does not include the first supplemental patterned layer region 187. In the second scenario (not shown) where the fourth enlarged region 183 is determined not to overlap a resistance region of the one or more resistance regions, in some embodiments, the second patterned layer map 157 includes a supplemental patterned layer region (not shown) responsive to classifying the fourth enlarged region 183 as a qualified region.

In some embodiments, the second patterned layer map 157 is generated without a space 179 (shown in FIG. 1I) between the first patterned layer region 125 and the first supplemental patterned layer region 187. FIG. 1J illustrates the second patterned layer map 157 without the space 179 according to some embodiments. In some embodiments, the second patterned layer map 157 corresponds to an updated version of the first patterned layer map.

FIG. 1K illustrates a representation 177 of the first patterned layer map according to some embodiments. In some embodiments, since the first patterned layer map does not comprise the first supplemental patterned layer region 187, the first patterned layer defined by the first patterned layer map does not reside in the first supplemental patterned layer region 187. In some embodiments, the first patterning process comprises removing a portion, of the first layer, residing in the first supplemental patterned layer region 187 to form the first layer.

In some embodiments, the second patterned layer map 157 defines a second patterned layer. In some embodiments, a second patterning process is performed according to the second patterned layer map to pattern a second layer to form the second patterned layer. In some embodiments, the second patterned layer map is indicative of one or more portions of the second layer that are removed in the second patterning process to form the second patterned layer. In some embodiments, the second patterned layer map is indicative of one or more portions of the second layer that are not removed in the second patterning process to form the second patterned layer. In some embodiments, a patterned layer region of the one or more second patterned layer regions corresponds to a region where the second patterned layer resides. In some embodiments, the patterned layer region comprises a portion of the second layer that is not removed in the second patterning process to form the second patterned layer.

In some embodiments, a first layer patterning unit is fabricated based upon the second patterned layer map 157. In some embodiments, the first layer patterning unit comprises a first photolithography mask, such as a photomask. In some embodiments, the first layer patterning unit is used to pattern the second layer to form the second patterned layer.

FIGS. 1L-1M illustrate embodiments of the second patterned layer map 157 in conjunction with various contact structure configurations. FIG. 1L illustrates a diagram representative of a patterned layer region 166 of the second patterned layer map 157 determined using the system 100. In some embodiments, the patterned layer region 166 comprises at least one of a set of contact structures 156A-156E or a set of contact structures 162A-162E. In some embodiments, the set of contact structures 156A-156E includes at least some of the features, characteristics, functions, interrelationships, relationships with other elements, sizes, positions, materials, etc. provided herein with respect to the first set of contact structures 102A-102L. In some embodiments, the set of contact structures 162A-162E includes at least some of the features, characteristics, functions, interrelationships, relationships with other elements, sizes, positions, materials, etc. provided herein with respect to the second set of contact structures 104A-104F. In some embodiments, at least some of the set of contact structures 156A-156E are in a region 176 having a contact structure density greater than the first threshold contact structure density. In some embodiments, the set of contact structures 162A-162E is between the region 176 and a region 168 having a contact structure density less than the second threshold contact structure density. In some embodiments, each contact structure of one, some or all contact structures of the set of contact structures 162A-162E has an area of at most the first threshold area. In some embodiments, the set of contact structures 162A-162E corresponds to a row of contact structures. In some embodiments, a distance 172 between two adjacent contact structures of the set of contact structures 162A-162E is at most about 10 micrometers, such as at most about 5 micrometers. In some embodiments, contact structures of the set of contact structures 162A-162E are spaced uniformly such that each pair of adjacent contact structures of the set of contact structures 162A-162E are spaced apart by a distance about equal to the distance 172. In some embodiments, a total length of the set of contact structures 162A-162E is greater than about 500 micrometers. In some embodiments, each contact structure of one, some or all contact structures of the set of contact structures 156A-156E has at least one sidewall having a length 155 between about 1 micrometer and about 20 micrometers, such as between about 1 micrometer and about 10 micrometers.

FIG. 1M illustrates a diagram representative of a patterned layer region 165 of the second patterned layer map 157 determined using the system 100. In some embodiments, the patterned layer region 165 comprises at least one of a set of contact structures 158A-158E or a set of contact structures 170A-170E. In some embodiments, the set of contact structures 158A-158E includes at least some of the features, characteristics, functions, interrelationships, relationships with other elements, sizes, positions, materials, etc. provided herein with respect to the first set of contact structures 102A-102L. In some embodiments, the set of contact structures 170A-170E includes at least some of the features, characteristics, functions, interrelationships, relationships with other elements, sizes, positions, materials, etc. provided herein with respect to the second set of contact structures 104A-104F. In some embodiments, at least some of the set of contact structures 158A-158E are in a region 160 having a contact structure density greater than the first threshold contact structure density. In some embodiments, the set of contact structures 170A-170E is between the region 160 and a region 178 having a contact structure density less than the second threshold contact structure density. In some embodiments, each contact structure of one, some or all contact structures of the set of contact structures 170A-170E has an area of at most the first threshold area. In some embodiments, the set of contact structures 170A-170E corresponds to a row of contact structures. In some embodiments, a distance 174 between two adjacent contact structures of the set of contact structures 170A-170E is at most about 10 micrometers, such as at most about 5 micrometers. In some embodiments, contact structures of the set of contact structures 170A-170E are spaced uniformly such that each pair of adjacent contact structures of the set of contact structures 170A-170E are spaced apart by a distance about equal to the distance 174. In some embodiments, a total length of the set of contact structures 170A-170E is greater than about 80 micrometers. In some embodiments, each contact structure of one, some or all contact structures of the set of contact structures 158A-158E has at least one sidewall having a length 171 between about 1 micrometer and about 20 micrometers, such as between about 1 micrometer and about 10 micrometers.

FIG. 1N illustrates a diagram representative of a patterned layer region 182 of the second patterned layer map 157 determined using the system 100. In some embodiments, the patterned layer region 182 comprises at least one of a set of contact structures 164A-164E or a set of contact structures 184A-184E. In some embodiments, the set of contact structures 164A-164E includes at least some of the features, characteristics, functions, interrelationships, relationships with other elements, sizes, positions, materials, etc. provided herein with respect to the first set of contact structures 102A-102L. In some embodiments, the set of contact structures 184A-184E includes at least some of the features, characteristics, functions, interrelationships, relationships with other elements, sizes, positions, materials, etc. provided herein with respect to the second set of contact structures 104A-104F. In some embodiments, at least some of the set of contact structures 164A-164E are in a region 180 having a contact structure density greater than the first threshold contact structure density. In some embodiments, the set of contact structures 184A-184E is between the region 180 and a region 198 having a contact structure density less than the second threshold contact structure density. In some embodiments, each contact structure of one, some or all contact structures of the set of contact structures 184A-184E has an area of at most the first threshold area. In some embodiments, the set of contact structures 184A-184E corresponds to a row of contact structures. In some embodiments, a distance 173 between two adjacent contact structures of the set of contact structures 184A-184E is at most about 10 micrometers, such as at most about 5 micrometers. In some embodiments, contact structures of the set of contact structures 184A-184E are spaced uniformly such that each pair of adjacent contact structures of the set of contact structures 184A-184E are spaced apart by a distance about equal to the distance 173. In some embodiments, a total length of the set of contact structures 184A-184E is greater than about 500 micrometers. In some embodiments, each contact structure of one, some or all contact structures of the set of contact structures 164A-164E has at least one sidewall having a length 175 between about 1 micrometer and about 20 micrometers, such as between about 1 micrometer and about 10 micrometers. In some embodiments, the region 198 comprise one or more functional regions of one or more functional components, such as the one or more first functional components. In some embodiments, the one or more functional regions comprise at least one of the first functional region 137 or the second functional region 139. In some embodiments, the system 100 determines the patterned layer region 182 such that there is an offset 196 of at least a threshold distance between a functional region of the one or more functional regions and the patterned layer region 182.

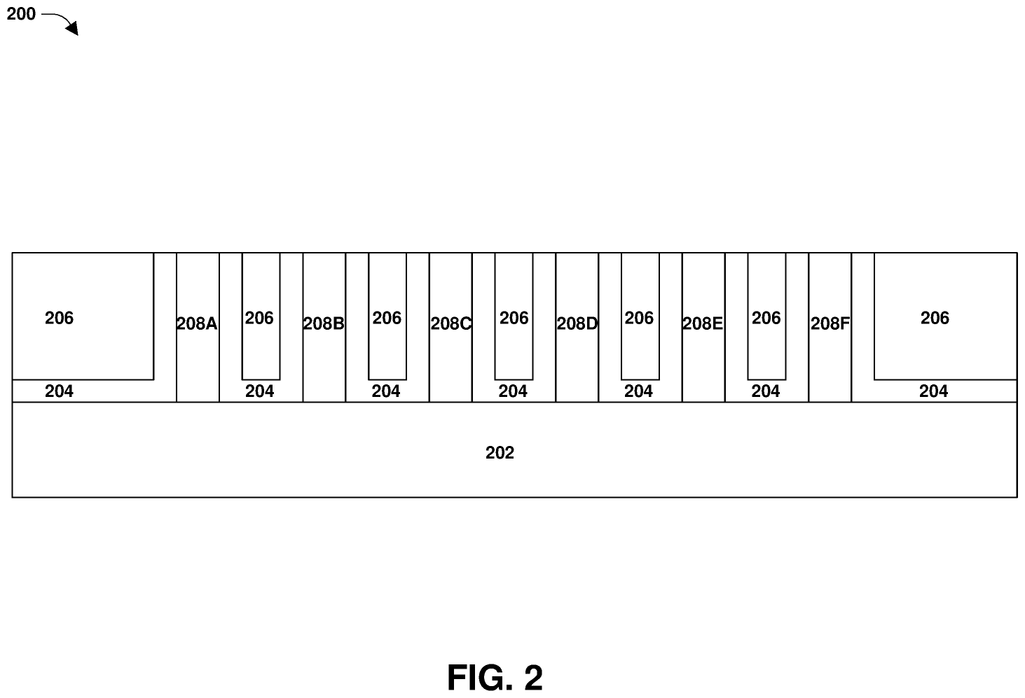

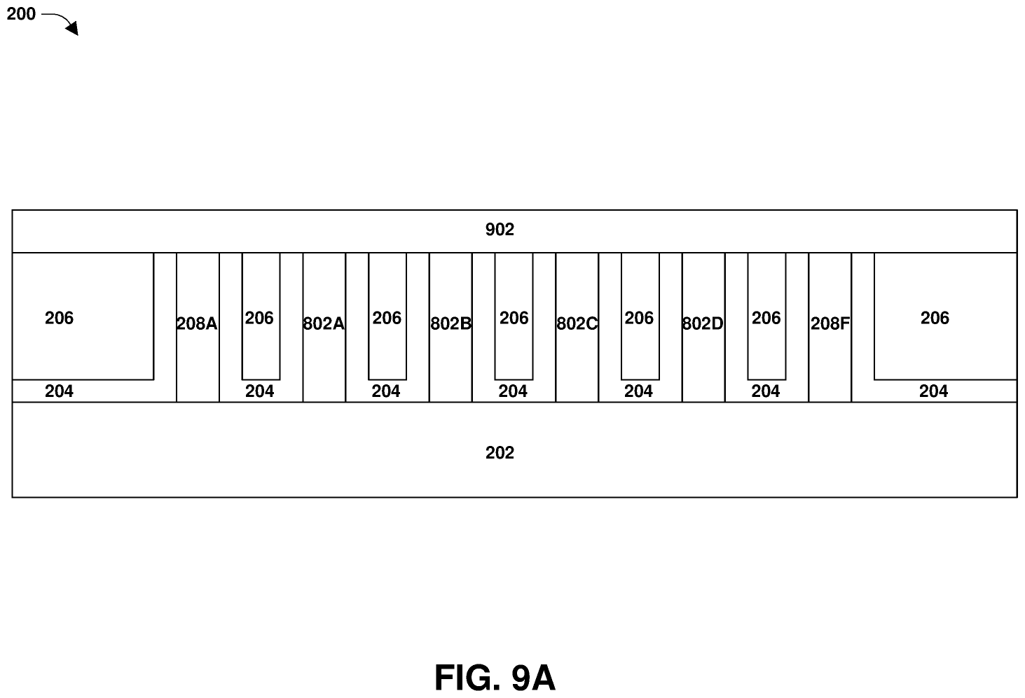

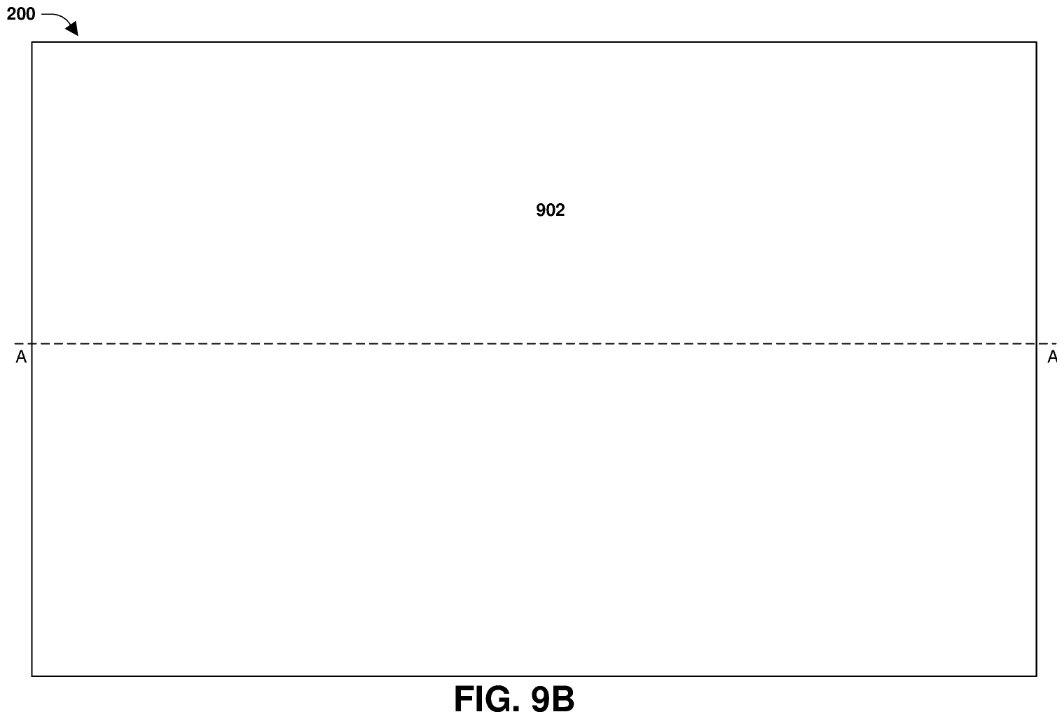

FIGS. 2-15B illustrate cross-sectional views of a semiconductor device 200 at various stages of fabrication, in accordance with some embodiments. FIGS. 2-8, 10, and 14 illustrate cross-sectional views of the semiconductor device 200. FIGS. 9B, 11B, 12B, 13B, and 15B illustrate top views of the semiconductor device 200, and FIGS. 9A, 11A, 12A, 13A, and 15A illustrate cross-sectional views of the semiconductor device 200 taken along lines A-A of FIGS. 9B, 11B, 12B, 13B, and 15B, respectively.

FIG. 2 illustrates the semiconductor device 200 according to some embodiments. In some embodiments, the semiconductor device 200 comprises at least one of a semiconductor body 202, a first dielectric layer 206 overlying the semiconductor body 202, or a first work function layer 204. In some embodiments, the semiconductor body 202 comprises at least one of a semiconductor layer, a substrate, a silicon-on-insulator (SOI) structure, an epitaxial layer, or other suitable layer. In some embodiments, the semiconductor body 202 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials. In some embodiments, the first dielectric layer 206 comprises at least one of phosphosilicate glass (PSG) or other suitable materials. In some embodiments, the first dielectric layer 206 is formed by at least one of physical vapor deposition (PVD), sputtering, chemical vapor deposition (CVD), plasma enhanced CVD (PECVD), low pressure CVD (LPCVD), atomic layer chemical vapor deposition (ALCVD), ultrahigh vacuum CVD (UHVCVD), reduced pressure CVD (RPCVD), atomic layer deposition (ALD), molecular beam epitaxy (MBE), liquid phase epitaxy (LPE), spin on, growth, or other suitable techniques. In some embodiments, the first work function layer 204 comprises at least one of a nitride material, such as silicon nitride, one or more metals, a metal nitride, such as titanium nitride, or one or more other suitable materials. In some embodiments, the first work function layer 204 is formed by at least one of PVD, sputtering, CVD, PECVD, LPCVD, ALCVD, UHVCVD, RPCVD, ALD, MBE, LPE, spin on, growth, or other suitable techniques.

In some embodiments, the semiconductor device 200 comprises structures 208A-208F. In some embodiments, the first dielectric layer 206 electrically isolates the structures 208A-208F from each other. In some embodiments, the structures 208A-208F have one or more of the features, characteristics, functions, interrelationships, relationships with other elements, sizes, positions, materials, etc. provided herein with respect to the first set of contact structures 102A-102L. In some embodiments, each structure of one, some, or all of the structures 208A-208F comprises at least one of polysilicon or one or more other suitable materials.

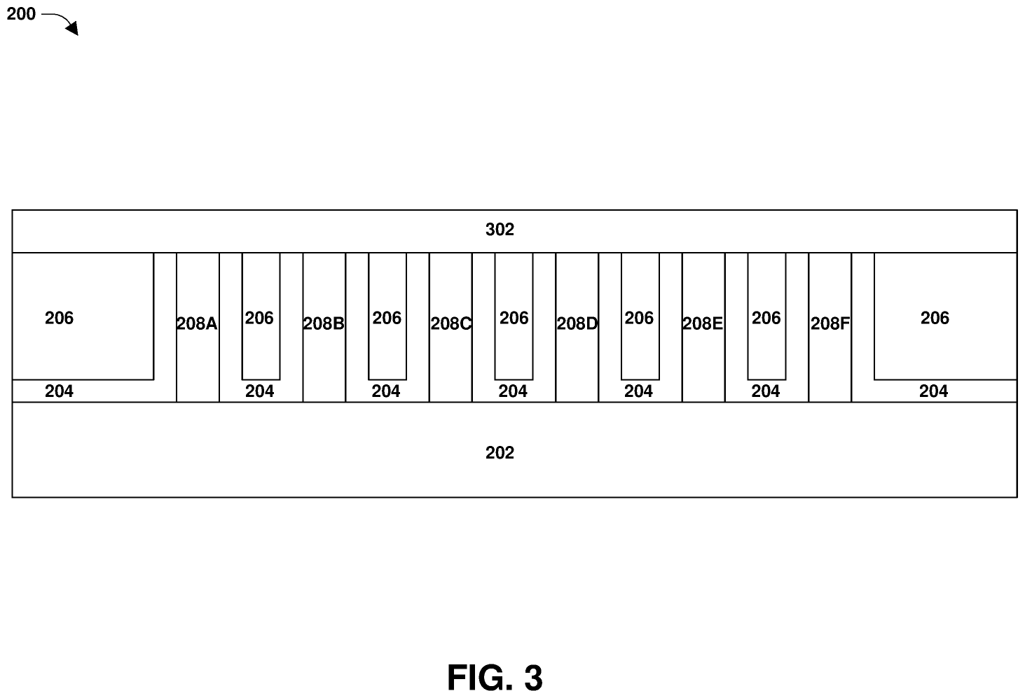

FIG. 3 illustrates forming a first oxide layer 302 over the first dielectric layer 206. The first oxide layer 302 comprises at least one of an oxide material, such as silicon oxide, or one or more other suitable materials. In some embodiments, the first oxide layer 302 comprises a first stop oxide layer or other type of oxide layer. The first oxide layer 302 at least one of overlies the first dielectric layer 206, is in direct contact with a top surface of the first dielectric layer 206, or is in indirect contact with the top surface of the first dielectric layer 206. In some embodiments, the first oxide layer 302 at least one of overlies the structures 208A-208F, is in direct contact with a top surface of a structure of the structures 208A-208F, or is in indirect contact with the top surface of the structure of the structures 208A-208F.

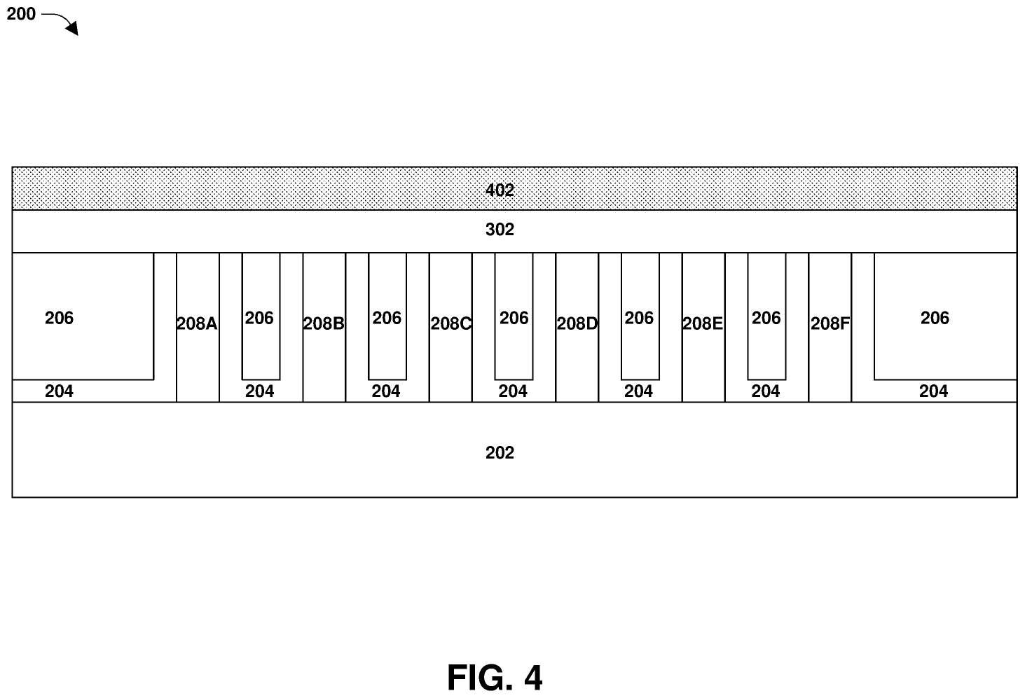

FIG. 4 illustrates forming a first photoresist 402 over the first oxide layer 302, according to some embodiments. The first photoresist 402 is formed over the first oxide layer 302 by at least one of PVD, sputtering, CVD, PECVD, LPCVD, ALCVD, UHVCVD, RPCVD, ALD, MBE, LPE, spin on, growth, or other suitable techniques. The first photoresist 402 comprises a light-sensitive material, where properties, such as solubility, of the first photoresist 402 are affected by light. In some embodiments, light is directed from a first light source through a second photolithography mask, such as a template, to the first photoresist 402 to generate a first exposed photoresist.

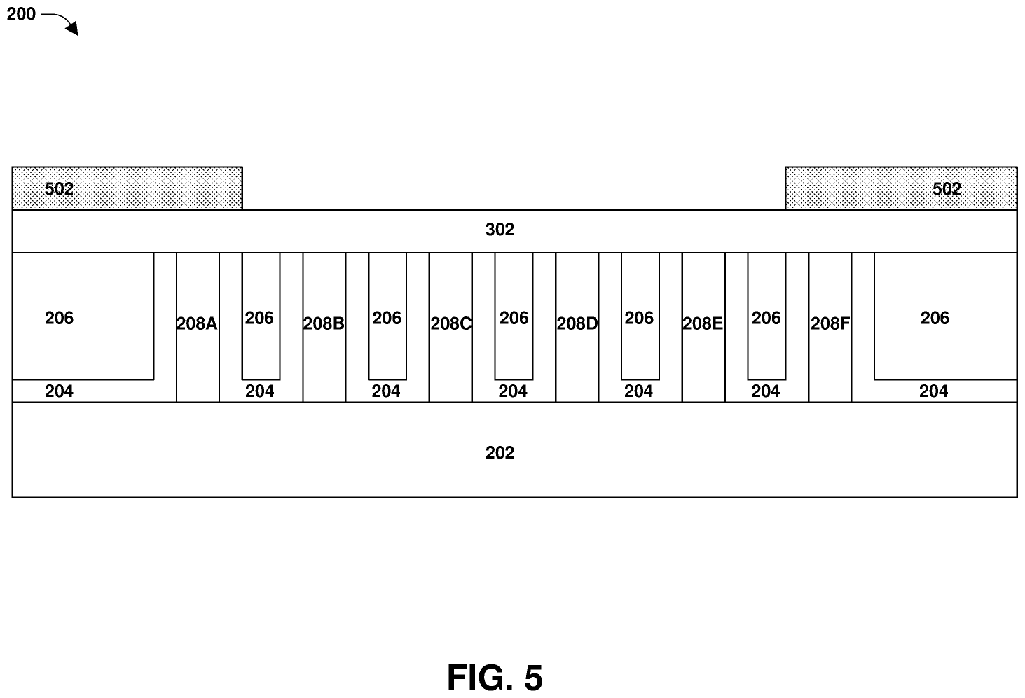

FIG. 5 illustrates forming a first patterned photoresist 502 over the first oxide layer 302, according to some embodiments. In some embodiments, a first developer, such as a solvent, is applied to the first exposed photoresist to form the first patterned photoresist 502. The first exposed photoresist is a negative photoresist or a positive photoresist. With respect to an embodiment in which the first exposed photoresist comprises a negative photoresist, regions of the first exposed photoresist become insoluble when illuminated by the first light source, such that application of the first developer to the first exposed photoresist removes non-illuminated regions of the first exposed photoresist. A pattern formed in the negative photoresist is thus a negative image of a pattern defined by opaque regions of the second photolithography mask between the first light source and the negative photoresist. In an embodiment in which the first exposed photoresist comprises a positive photoresist, illuminated regions of the first exposed photoresist become soluble and are removed via application of the first developer during development. Thus, a pattern formed in the positive photoresist is a positive image of opaque regions of the second photolithography mask between the first light source and the positive photoresist.

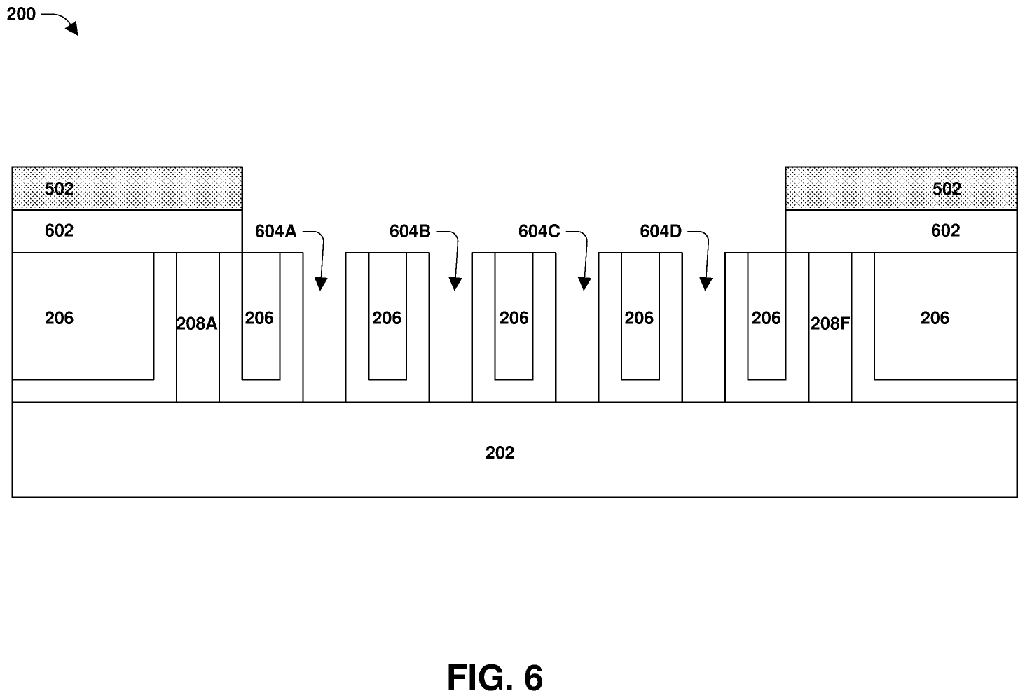

FIG. 6 illustrates use of the first patterned photoresist 502 to pattern the first oxide layer 302 to form a first patterned oxide layer 602, according to some embodiments. In some embodiments, a first etching process is performed to remove one or more portions of the first oxide layer 302 to form the first patterned oxide layer 602. In some embodiments, one or more first etchants of the first etching process have a selectivity such that the one or more first etchants remove or etch away the first oxide layer 302 exposed or not covered by the first patterned photoresist 502 at a greater rate than the one or more first etchants remove or etch away the first patterned photoresist 502. Accordingly, an opening in the first patterned photoresist 502 allows the one or more first etchants to form a corresponding opening in the first oxide layer 302 under the photoresist, and thereby transfer a pattern in the photoresist to the first oxide layer 302 under the photoresist. In some embodiments, the first etching process is at least one of a dry etching process, a wet etching process, an anisotropic etching process, an isotropic etching process, or another suitable etching process. The one or more first etchants comprise at least one of fluorine, hydrogen fluoride (HF), diluted HF, a chlorine compound such as hydrogen chloride (HCl₂), hydrogen sulfide (H₂S), or other suitable material. Other processes and/or techniques for forming the first patterned oxide layer 602 are within the scope of the present disclosure. In some embodiments, the first patterned photoresist 502 is removed, such as stripped or washed away, after forming the first patterned oxide layer 602.

In some embodiments, the first etching process removes one or more first structures, of the structures 208A-208F, that are not covered by the first patterned photoresist 502 during the first etching process. In some embodiments, the one or more first structures comprise at least one of a structure 208B, a structure 208C, a structure 208D, or a structure 208E. In some embodiments, removing the one or more first structures forms one or more first trenches comprising at least one of a trench 604A, a trench 604B, a trench 604C, or a trench 604D. In some embodiments, the first etching process does not remove one or more second structures, of the structures 208A-208F, that are covered by the first patterned photoresist 502 during the first etching process. In some embodiments, the one or more second structures comprise at least one of a structure 208A or a structure 208F.

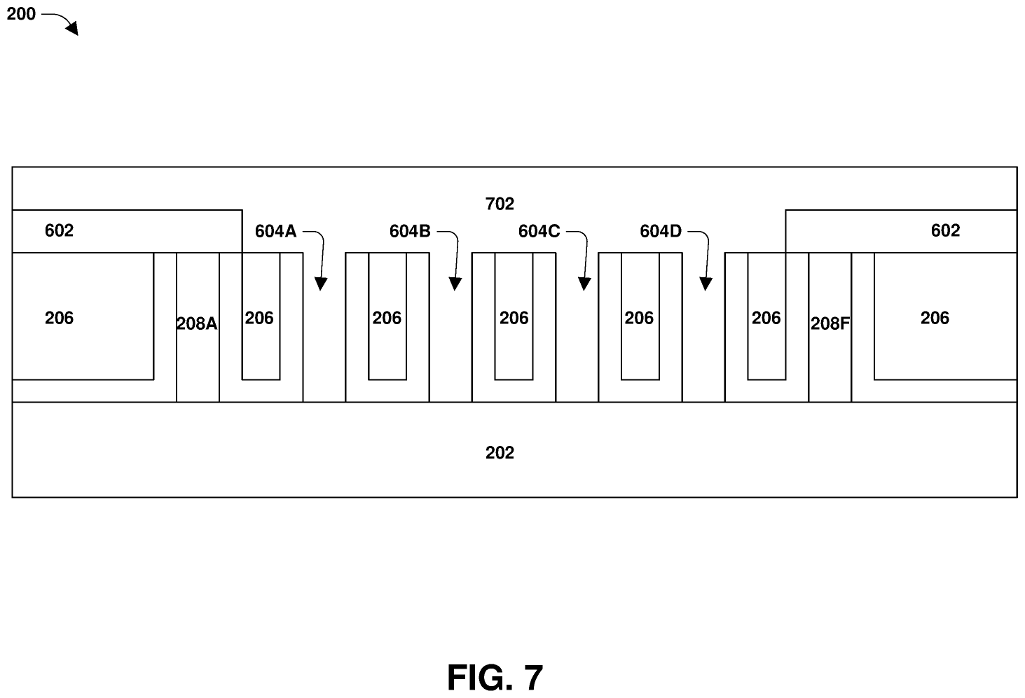

FIG. 7 illustrates forming a first metal layer 702 over at least one of the first dielectric layer 206 or the first patterned oxide layer 602, according to some embodiments. In some embodiments, the first metal layer 702 comprises at least one of one or more metals or one or more other suitable materials. The first metal layer 702 is formed by at least one of PVD, sputtering, CVD, PECVD, LPCVD, ALCVD, UHVCVD, RPCVD, ALD, MBE, LPE, spin on, growth, or other suitable techniques. In some embodiments, the first metal layer 702 fills the one or more first trenches, such as at least one of the trench 604A (shown in FIG. 6), the trench 604B, the trench 604C, or the trench 604D.

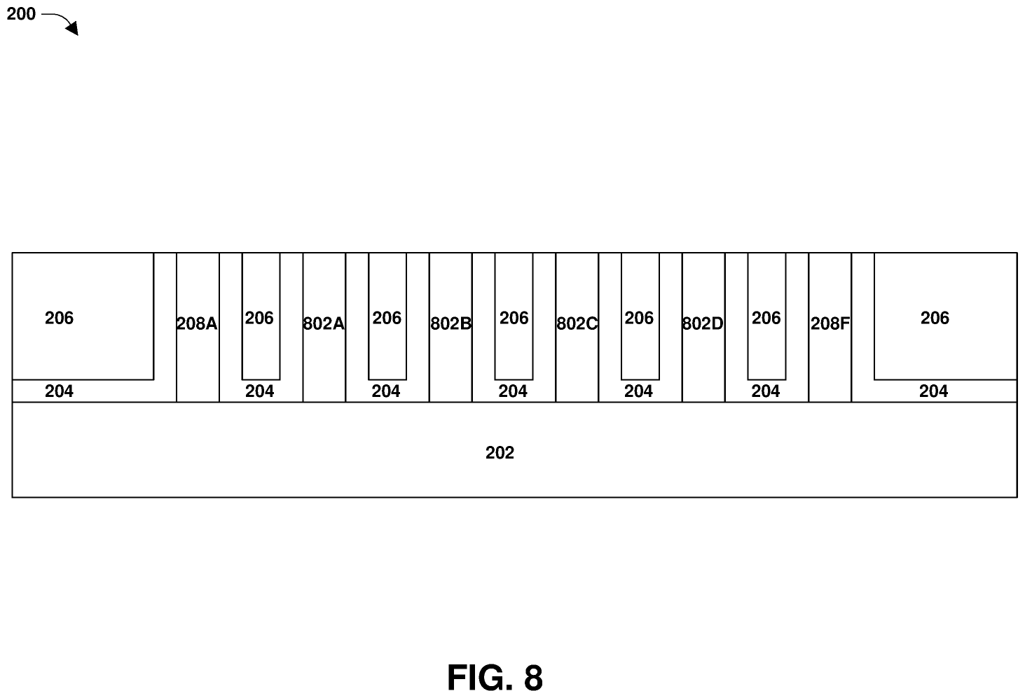

FIG. 8 illustrates removal of a first upper portion of the semiconductor device 200, according to some embodiments. In some embodiments, the first upper portion of the semiconductor device 200 comprises at least one of a top portion of the first metal layer 702, a top portion of the first dielectric layer 206, a top portion of the first work function layer 204, a top portion of the structure 208A, or a top portion of the structure 208F. In some embodiments, the first upper portion of the semiconductor device 200 is removed by a first layer removal process comprising at least one of chemical-mechanical polishing (CMP), etching, or other suitable techniques.

In some embodiments, the first metal layer 702 is deposited to form one or more third contact structures of the semiconductor device 200. In some embodiments, the one or more third contact structures comprise at least one of a contact structure 802A, a contact structure 802B, a contact structure 802C, a contact structure 802D, or one or more other contact structures formed from the first metal layer 702. In some embodiments, at least one of the first metal layer 702 or the one or more third contact structures is associated with a first conductivity type. In some embodiments, the first conductivity type is n-type or p-type. In some embodiments, a contact structure of the one or more third contact structures comprises a gate electrode, such as a gate electrode having the first conductivity type. In some embodiments, the gate electrode comprises a metal gate, such as a metal gate having the first conductivity type. In some embodiments, a contact structure of the one or more third contact structures is at least one of in a transistor or is connected to a transistor. In some embodiments, a contact structure of the one or more third contact structures provides a connection between a transistor and a semiconductor component, such as at least one of a metal layer, a connection element, an interconnect structure, a contact structure, a via, a doped region, a metal line, a logic component, circuitry, etc. In some embodiments, a contact structure of the one or more third contact structures is at least one of in or is connected to at least one of a MOS structure, a MOSFET structure, a FinFET structure, or other suitable structure. In some embodiments, a contact structure of the one or more third contact structures is connected to a doped region having the first conductivity type.

FIGS. 9A-9B illustrate forming a second oxide layer 902 over the first dielectric layer 206. The second oxide layer 902 comprises at least one of an oxide material, such as silicon oxide, or one or more other suitable materials. In some embodiments, the second oxide layer 902 comprises a second stop oxide layer or other type of oxide layer. The second oxide layer 902 at least one of overlies the first dielectric layer 206, is in direct contact with the top surface of the first dielectric layer 206, or is in indirect contact with the top surface of the first dielectric layer 206. In some embodiments, the second oxide layer 902 at least one of overlies structures 208A and 208F, is in direct contact with a top surface of a structure of the structures 208A and 208F, or is in indirect contact with the top surface of the structure of the structures 208A and 208F. In some embodiments, the second oxide layer 902 at least one of overlies contact structures 802A-802D, is in direct contact with a top surface of a structure of the contact structures 802A-802D, or is in indirect contact with the top surface of the structure of the contact structures 802A-802D.

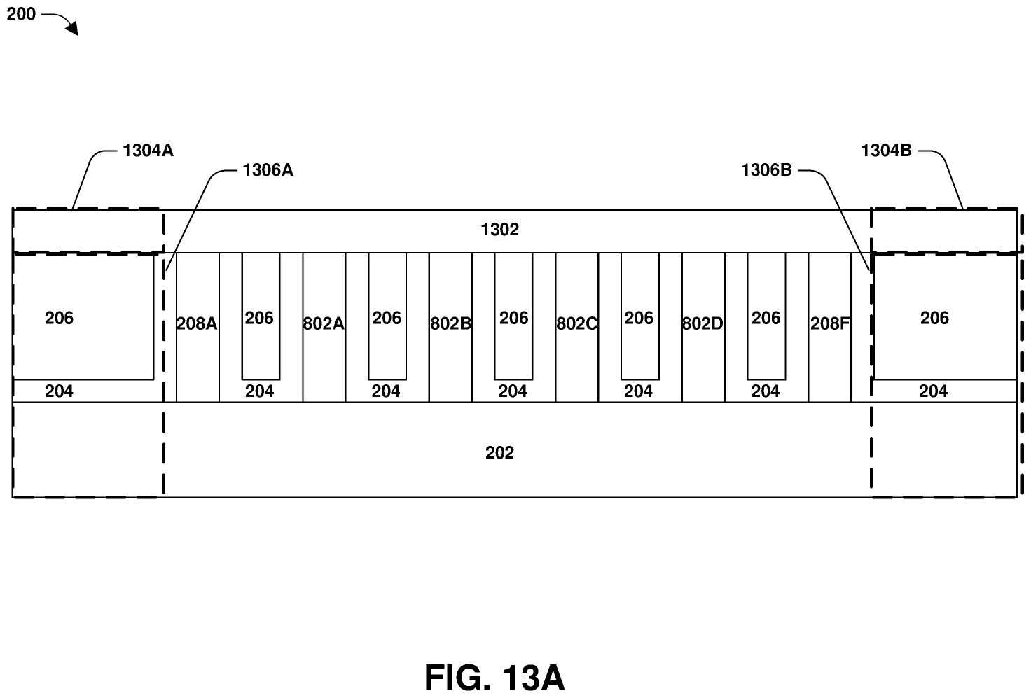

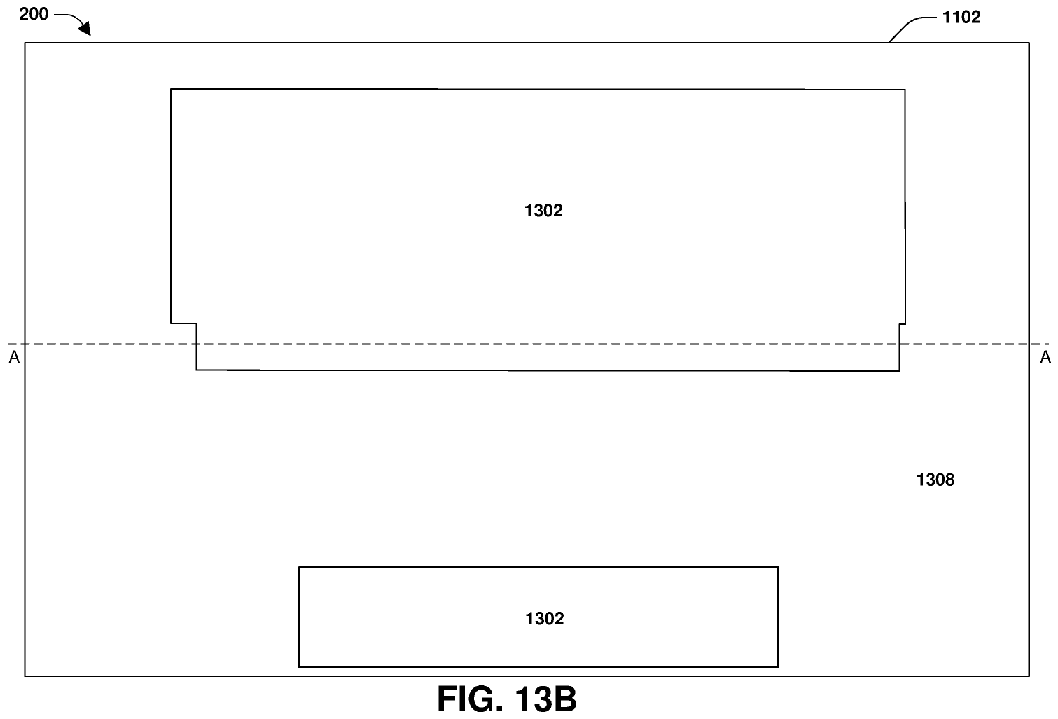

In some embodiments, the second oxide layer 902 is patterned to form a second patterned oxide layer 1302 (shown in FIGS. 13A-13B) using the first layer patterning unit fabricated based upon the second patterned layer map 157 (shown in FIGS. 1I-1J), such as the first photolithography mask.

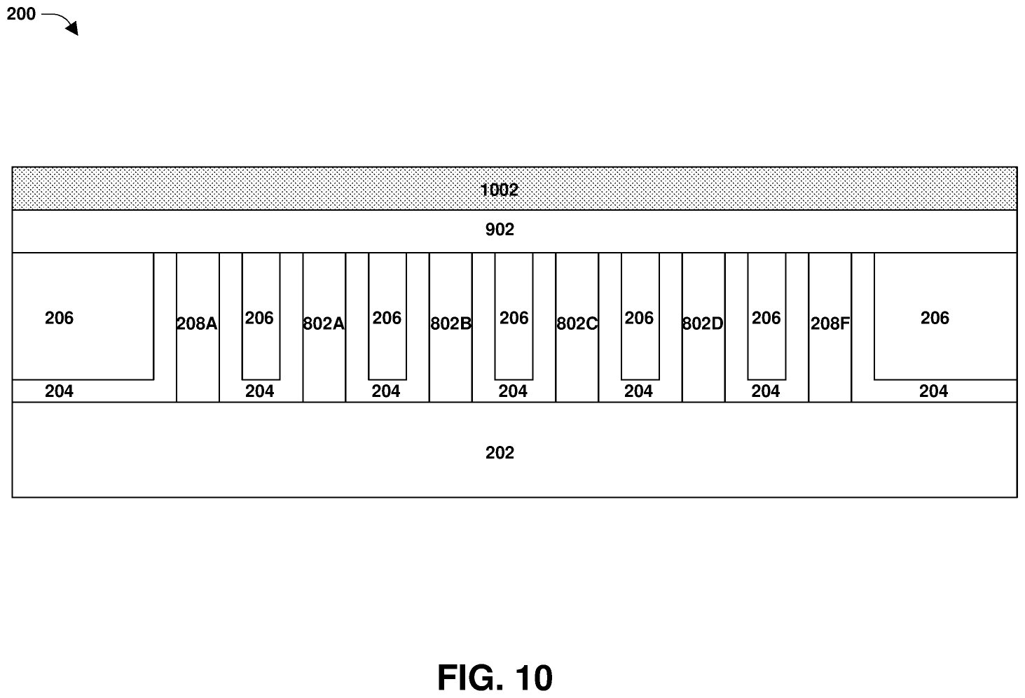

FIG. 10 illustrates forming a second photoresist 1002 over the second oxide layer 902, according to some embodiments. The second photoresist 1002 at least one of overlies the second oxide layer 902, is in direct contact with the top surface of the second oxide layer 902, or is in indirect contact with the top surface of the second oxide layer 902. The second photoresist 1002 is formed over the second oxide layer 902 by at least one of PVD, sputtering, CVD, PECVD, LPCVD, ALCVD, UHVCVD, RPCVD, ALD, MBE, LPE, spin on, growth, or other suitable techniques. The second photoresist 1002 comprises a light-sensitive material, where properties, such as solubility, of the second photoresist 1002 are affected by light. The second photoresist 1002 is a positive photoresist or a negative photoresist.

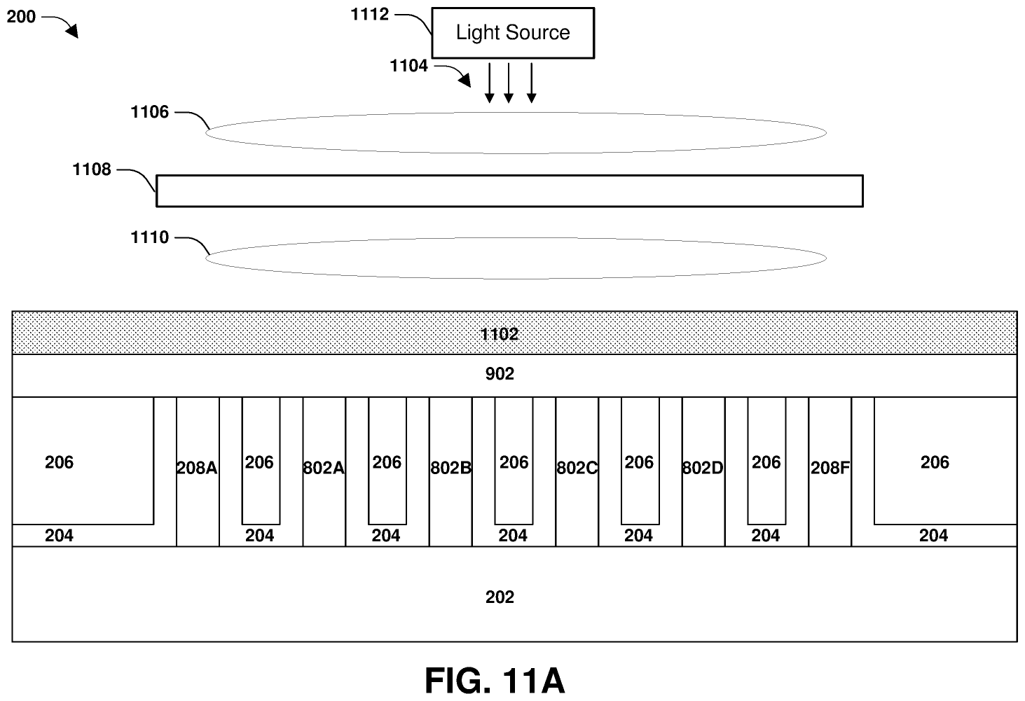

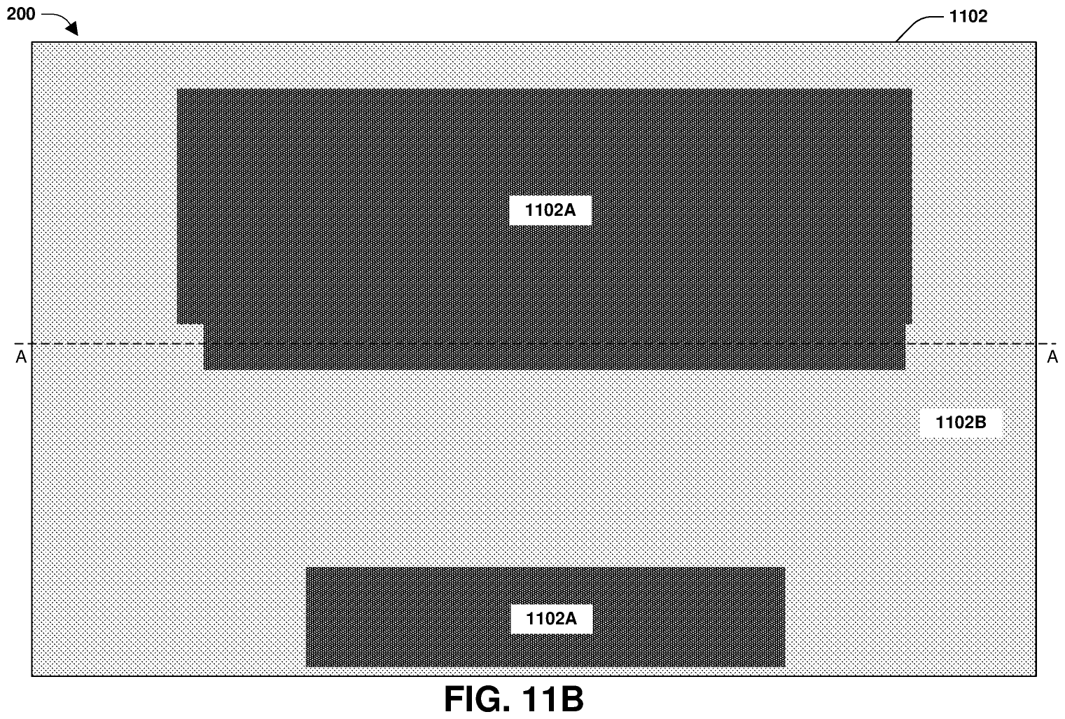

FIGS. 11A-11B illustrates use of the first photolithography mask (shown with reference number 1108) to generate a second exposed photoresist 1102, according to some embodiments. With respect to FIG. 11A, light 1104 from a second light source 1112 is directed through at least one of a first lens 1106, the first photolithography mask 1108, or a second lens 1110 to the second photoresist 1002 to generate the second exposed photoresist 1102, according to some embodiments. In some embodiments, at least one of the first lens 1106 comprises a condenser lens or the second lens 1110 comprises a projection lens. With respect to an embodiment in which the second exposed photoresist 1102 comprises a negative photoresist, regions of the second exposed photoresist 1102 that are illuminated by the second light source 1112 are insoluble. A pattern formed in the negative photoresist is thus a negative image of a pattern defined by opaque regions of the first photolithography mask 1108. In some embodiments, when the second exposed photoresist 1102 is a negative photoresist, the first photolithography mask corresponds to a negative image of the second patterned layer map 157. In an embodiment in which the second exposed photoresist 1102 comprises a positive photoresist, illuminated regions of the second exposed photoresist 1102 are soluble. Thus, a pattern formed in the positive photoresist is a positive image of opaque regions of the first photolithography mask 1108 between the second light source 1112 and the positive photoresist. In some embodiments, when the second exposed photoresist 1102 is a positive photoresist, the first photolithography mask corresponds to a positive image of the second patterned layer map 157.

In some embodiments, the second exposed photoresist 1102 comprises one or more insoluble portions 1102A and one or more soluble portions 1102B (shown in FIG. 11B).

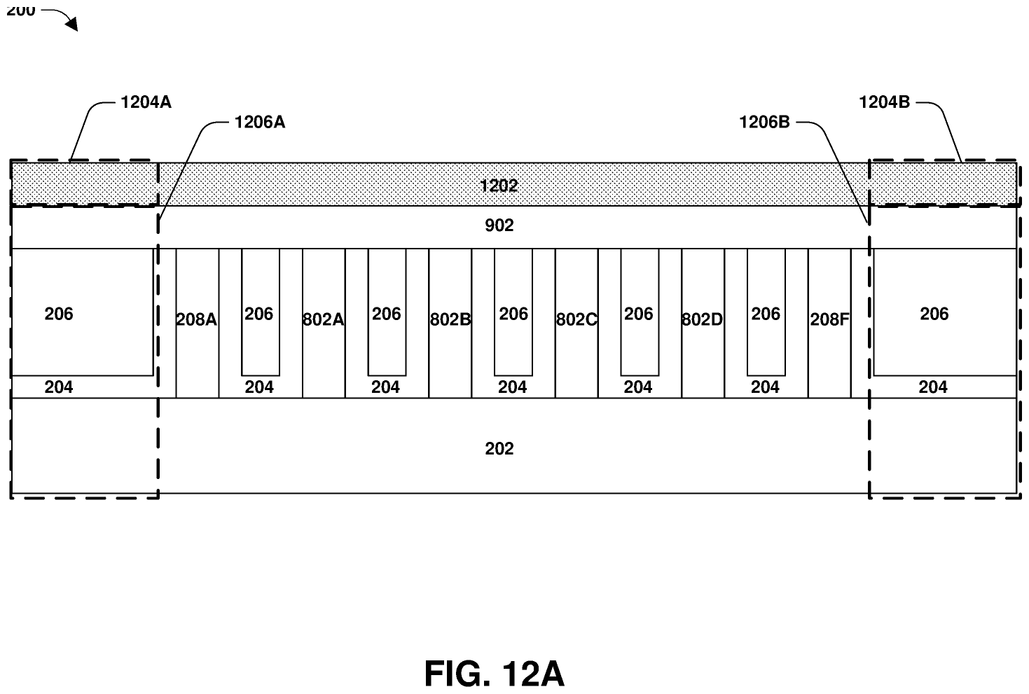

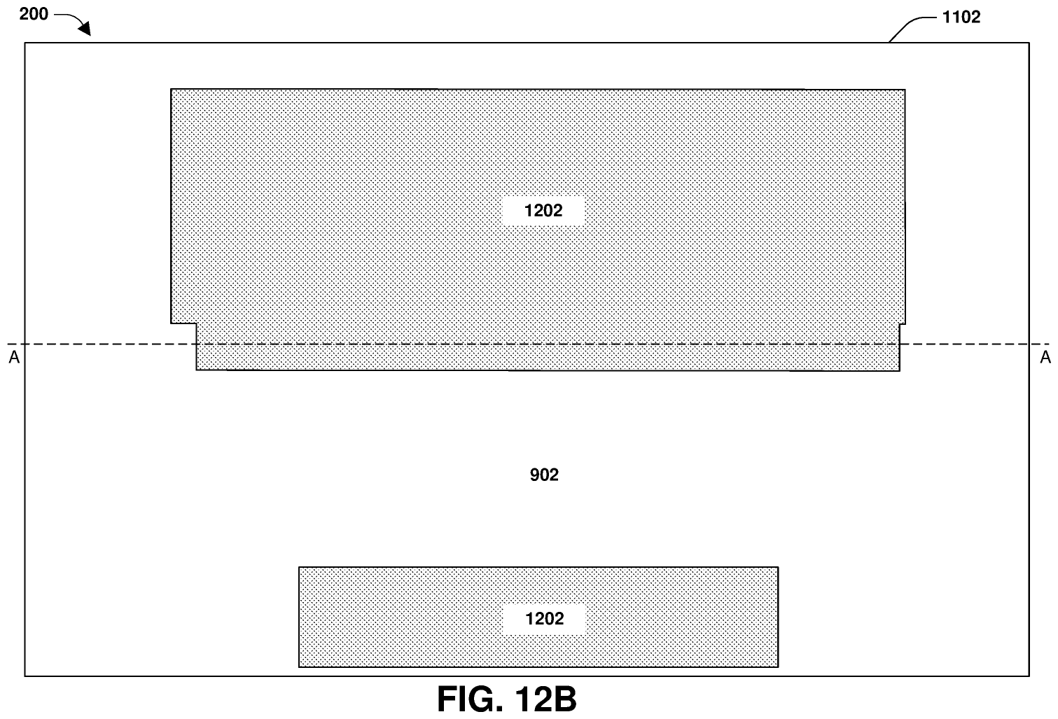

FIGS. 12A-12B illustrate forming a second patterned photoresist 1202 over the second oxide layer 902, according to some embodiments. In some embodiments, a second developer, such as a solvent, is applied to the first exposed photoresist to form the second patterned photoresist 1202. In some embodiments, applying the second developer removes the one or more soluble portions 1102B (shown in FIG. 11B) of the second exposed photoresist 1102. In some embodiments, applying the second developer does not remove the one or more insoluble portions 1102A of the second exposed photoresist 1102.

In some embodiments, the second patterned photoresist 1202 is used to pattern the second oxide layer 902 to form a second patterned oxide layer 1302 (shown in FIGS. 13A-13B), according to some embodiments. In some embodiments, a second etching process is performed to remove one or more portions of the second oxide layer 902 to form the second patterned oxide layer 1302. In some embodiments, one or more second etchants of the second etching process have a selectivity such that the one or more second etchants remove or etch away the second oxide layer 902 exposed or not covered by the second patterned photoresist 1202 at a greater rate than the one or more second etchants remove or etch away the second patterned photoresist 1202. Accordingly, an opening in the second patterned photoresist 1202 allows the one or more second etchants to form a corresponding opening in the second oxide layer 902 under the photoresist, and thereby transfer a pattern in the photoresist to the second oxide layer 902 under the photoresist. In some embodiments, the second etching process is at least one of a dry etching process, a wet etching process, an anisotropic etching process, an isotropic etching process, or another suitable etching process. The one or more second etchants comprise at least one of fluorine, HF, diluted HF, a chlorine compound such as HCl₂, H₂S, or other suitable material. Other processes and/or techniques for forming the second patterned oxide layer 1302 are within the scope of the present disclosure. In some embodiments, the second patterned photoresist 1202 is removed, such as stripped or washed away, after forming the second patterned oxide layer 1302.

In some embodiments, the second patterned photoresist 1202 does not extend over at least one of a portion 1206A (shown with a dashed-line outline in FIG. 12A) of the semiconductor device 200 or a portion 1206B (shown with a dashed-line outline in FIG. 12A) of the semiconductor device 200. In some embodiments, the second patterned photoresist 1202 does not comprise at least one of (i) a portion 1204A (shown with a dashed-line outline in FIG. 12A) overlying the portion 1206A of the semiconductor device 200 or (ii) a portion 1204B (shown with a dashed-line outline in FIG. 12A) overlying the portion 1206A of the semiconductor device 200. In some embodiments, at least one of the portion 1206A of the semiconductor device 200 or the portion 1206B of the semiconductor device 200 is exposed.

FIGS. 13A-13B illustrates the semiconductor device 200 after removal of the second patterned photoresist 1202 over the second patterned oxide layer 1302, according to some embodiments. In some embodiments, after forming the second patterned oxide layer 1302 and prior to removing the second patterned photoresist 1202, the second patterned photoresist 1202 at least one of overlies the second patterned oxide layer 1302, is in direct contact with the top surface of the second patterned oxide layer 1302, or is in indirect contact with the top surface of the second patterned oxide layer 1302. In some embodiments, the second patterned oxide layer 1302 does not cover a portion 1308 (shown in FIG. 13B) of the semiconductor device 200.

In some embodiments, the second patterned oxide layer 1302 does not extend over at least one of a portion 1306A (shown with a dashed-line outline in FIG. 13A) of the semiconductor device 200 or a portion 1306B (shown with a dashed-line outline in FIG. 13A) of the semiconductor device 200. In some embodiments, the second patterned oxide layer 1302 does not comprise at least one of (i) a portion 1304A (shown with a dashed-line outline in FIG. 13A) overlying the portion 1306A of the semiconductor device 200 or (ii) a portion 1304B (shown with a dashed-line outline in FIG. 13A) overlying the portion 1306A of the semiconductor device 200. In some embodiments, the second patterned oxide layer 1302 excludes the portion 1304A and the portion 1304B if the second patterned photoresist 1202 excludes the portion 1204A (shown in FIG. 12A) and the portion 1204B. In some embodiments, at least one of the portion 1306A of the semiconductor device 200 or the portion 1306B of the semiconductor device 200 is exposed.

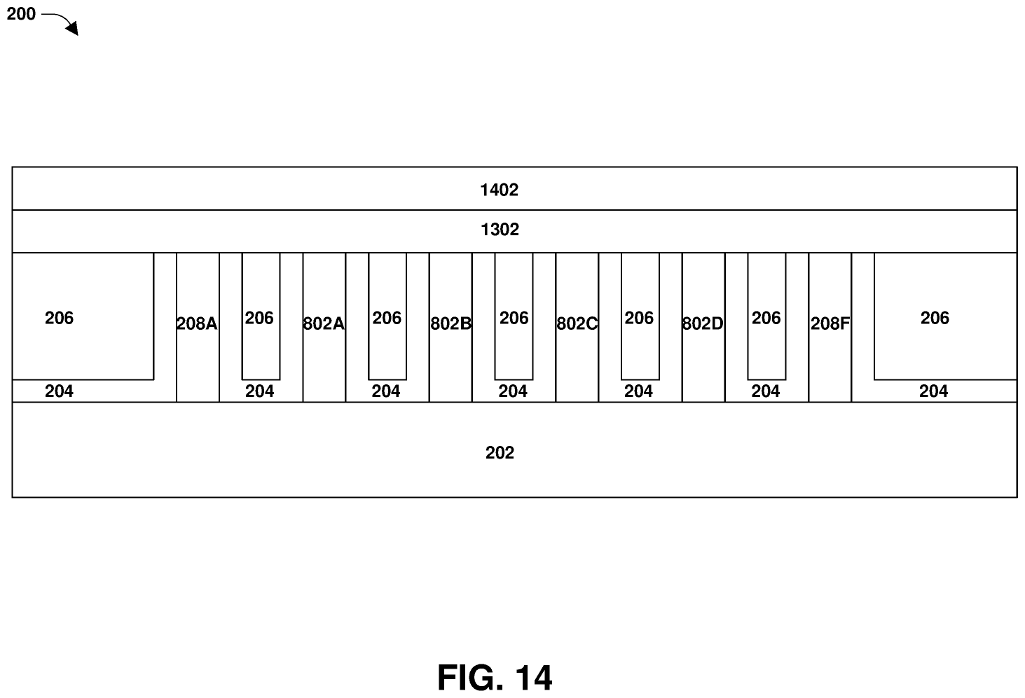

FIG. 14 illustrates forming a second metal layer 1402 over at least one of the first dielectric layer 206 or the second patterned oxide layer 1302, according to some embodiments. In some embodiments, the second metal layer 1402 comprises at least one of one or more metals or one or more other suitable materials. The second metal layer 1402 is formed by at least one of PVD, sputtering, CVD, PECVD, LPCVD, ALCVD, UHVCVD, RPCVD, ALD, MBE, LPE, spin on, growth, or other suitable techniques.

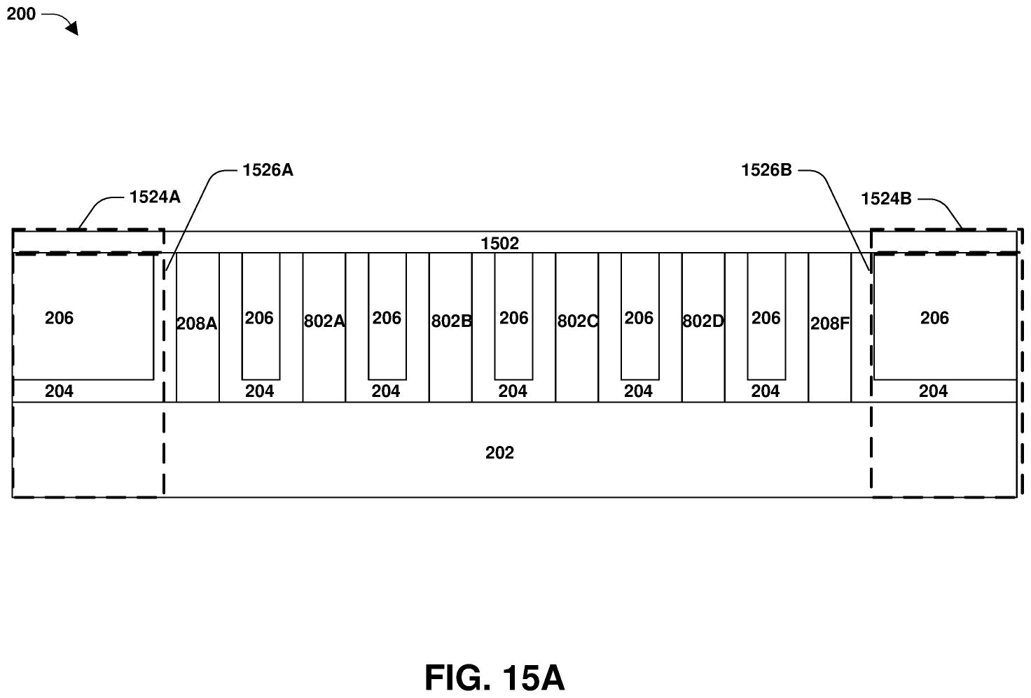

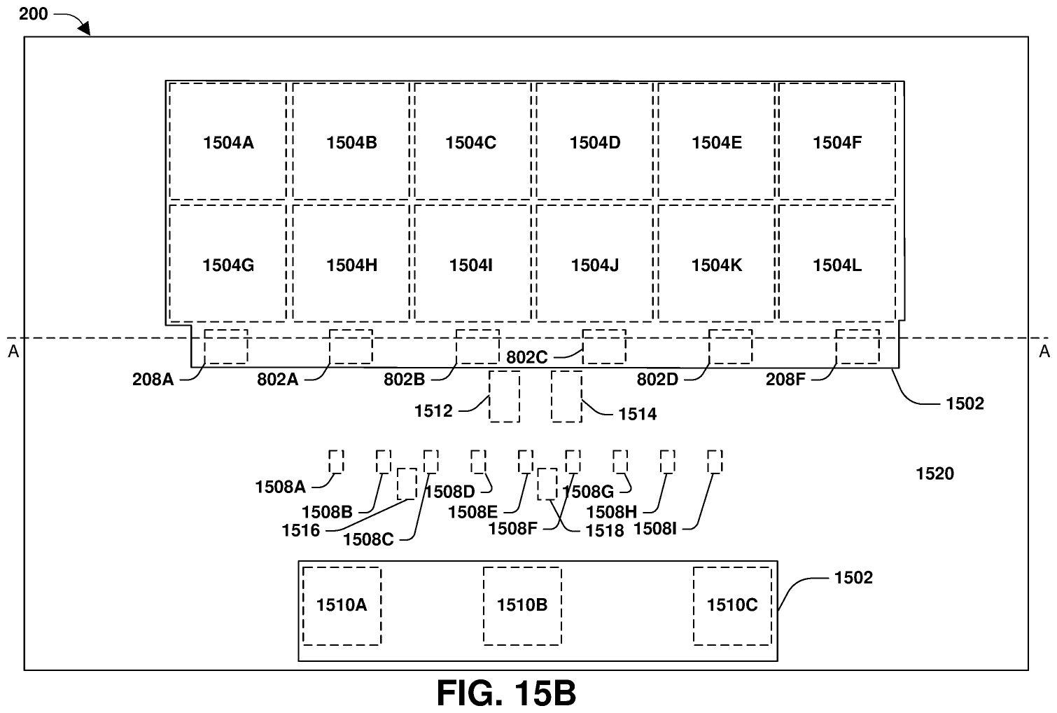

FIGS. 15A-15B illustrate removal of a second upper portion of the semiconductor device 200, according to some embodiments. In some embodiments, the second upper portion of the semiconductor device 200 comprises at least a portion of the second metal layer 1402 and at least a portion of the second patterned oxide layer 1302. In some embodiments, the second upper portion of the semiconductor device 200 is removed by a second layer removal process comprising at least one of CMP, etching, or other suitable techniques. In some embodiments, a portion 1502 of the second patterned oxide layer 1302 remains on the semiconductor device 200 after removal of the second upper portion of the semiconductor device 200, such as due, at least in part, to at least one of one or more parameters of the second layer removal process, one or more physical characteristics of the second metal layer 1402, or a top surface of the semiconductor device 200 having varying elevations. In some embodiments, the portion 1502 of the second patterned oxide layer 1302 does not cover a portion 1520 (shown in FIG. 15B) of the semiconductor device 200. In some embodiments, the portion 1520 of the semiconductor device 200 corresponds to the portion 1308 (shown in FIG. 13B) of the semiconductor device 200. In some embodiments, the varying elevations of the top surface of the semiconductor device 200 prevents a layer removal tool used in the second layer removal process, such as a CMP tool, from being able to remove the portion 1502 of the second patterned oxide layer 1302.

In some embodiments, the portion 1502 of the second patterned oxide layer 1302 does not extend over at least one of a portion 1526A (shown with a dashed-line outline in FIG. 15A) of the semiconductor device 200 or a portion 1526B (shown with a dashed-line outline in FIG. 15A) of the semiconductor device 200. In some embodiments, the portion 1502 of the second patterned oxide layer 1302 does not comprise at least one of (i) a portion 1524A (shown with a dashed-line outline in FIG. 15A) overlying the portion 1526A of the semiconductor device 200 or (ii) a portion 1524B (shown with a dashed-line outline in FIG. 15A) overlying the portion 1526A of the semiconductor device 200. In some embodiments, the portion 1502 of the second patterned oxide layer 1302 excludes the portion 1524A and the portion 1524B if the second patterned photoresist 1202 excludes the portion 1204A (shown in FIG. 12A) and the portion 1204B. In some embodiments, at least one of the portion 1526A of the semiconductor device 200 or the portion 1526B of the semiconductor device 200 is exposed.

In some embodiments, the second metal layer 1402 (shown in FIG. 14) is deposited to form one or more fourth contact structures of the semiconductor device 200. In some embodiments, at least one of the second metal layer 1402 or the one or more fourth contact structures is associated with a second conductivity type. In some embodiments, the second conductivity type is n-type or p-type. In some embodiments, the first conductivity type is p-type and the second conductivity type is n-type. Embodiments are contemplated in which the first conductivity type is n-type and the second conductivity type is p-type. In some embodiments, a contact structure of the one or more fourth contact structures comprises a gate electrode, such as a gate electrode having the second conductivity type. In some embodiments, the gate electrode comprises a metal gate, such as a metal gate having the second conductivity type. In some embodiments, a contact structure of the one or more fourth contact structures is at least one of in a transistor or is connected to a transistor. In some embodiments, a contact structure of the one or more fourth contact structures provides a connection between a transistor and a semiconductor component, such as at least one of a metal layer, a connection element, an interconnect structure, a contact structure, a via, a doped region, a metal line, a logic component, circuitry, etc. In some embodiments, a contact structure of the one or more fourth contact structures is at least one of in or is connected to at least one of a MOS structure, a MOSFET structure, a FinFET structure, or other suitable structure. In some embodiments, a contact structure of the one or more fourth contact structures is connected to a doped region having the second conductivity type.

In some embodiments, the one or more first functional components are associated with the second conductivity type. In some embodiments, the first functional component comprises at least a portion of a component having the second conductivity type, such as a transistor, a MOS structure, a MOSFET structure, a FinFET structure, or other suitable structure.

The semiconductor device 200 comprises a plurality of semiconductor components comprising at least one of a plurality of contact structures, one or more second functional components, one or more second resistance components, or one or more other components, according to some embodiments. Although at least some of the plurality of semiconductor components underlie at least one of the portion 1502 of the second patterned oxide layer 1302 or the portion 1520 of the semiconductor device and thus are not visible from the top view of FIG. 15B, FIG. 15B provides dashed-line shapes representative of positions of corresponding semiconductor components. In some embodiments, one or more of the semiconductor components that are shown with dashed-line shapes in FIG. 15B are not covered by another layer, and are thus visible from the top view of FIG. 15B.

In some embodiments, at least some of the plurality of contact structures of the semiconductor device 200 are at least one of in the first dielectric layer 206 or overlie the semiconductor body 202. In some embodiments, the first dielectric layer 206 electrically isolates contact structures of the plurality of contact structures from each other. In some embodiments, the plurality of contact structures are formed according to the contact structure map 115. In some embodiments, the plurality of contact structures comprise at least one of a fifth set of contact structures 1504A-1504L corresponding to the first set of contact structures 102A-102L, a sixth set of contact structures corresponding to the second set of contact structures 104A-104F, a seventh set of contact structures 1508A-1508I corresponding to the third set of contact structures 113A-113I, or an eighth set of contact structures 1510A-1510C corresponding to the fourth set of contact structures 117A-117C. In some embodiments, the sixth set of contact structures comprise at least one of the structure 208A, the structure 208F, or the contact structures 802A-802D.

In some embodiments, the fifth set of contact structures 1504A-1504L has one or more of the features, characteristics, functions, interrelationships, relationships with other elements, sizes, positions, materials, etc. provided herein with respect to the first set of contact structures 102A-102L. In some embodiments, the sixth set of contact structures has one or more of the features, characteristics, functions, interrelationships, relationships with other elements, sizes, positions, materials, etc. provided herein with respect to the second set of contact structures 104A-104F. In some embodiments, the seventh set of contact structures 1508A-1508I has one or more of the features, characteristics, functions, interrelationships, relationships with other elements, sizes, positions, materials, etc. provided herein with respect to the third set of contact structures 113A-113I. In some embodiments, the eighth set of contact structures 1510A-1510C has one or more of the features, characteristics, functions, interrelationships, relationships with other elements, sizes, positions, materials, etc. provided herein with respect to the fourth set of contact structures 117A-117C.

In some embodiments, the one or more third contact structures comprise at least one of (i) one or more contact structures of the fifth set of contact structures 1504A-1504L, (ii) one or more contact structures of the sixth set of contact structures, (iii) one or more contact structures of the seventh set of contact structures 1508A-1508I, (iv) one or more contact structures of the eighth set of contact structures 1510A-1510C, or (v) one or more other contact structures of the plurality of contact structures.

In some embodiments, the one or more fourth contact structures comprise at least one of (i) one or more contact structures of the fifth set of contact structures 1504A-1504L, (ii) one or more contact structures of the sixth set of contact structures, (iii) one or more contact structures of the seventh set of contact structures 1508A-1508I, (iv) one or more contact structures of the eighth set of contact structures 1510A-1510C, or (v) one or more other contact structures of the plurality of contact structures.

In some embodiments, the one or more second functional components have one or more of the features, characteristics, functions, interrelationships, relationships with other elements, sizes, positions, materials, etc. provided herein with respect to the one or more first functional components. In some embodiments, the one or more second functional components are formed according to the functional component map. In some embodiments, the one or more second functional components comprise at least one of the first functional component (shown with reference number 1512) or the second functional component (shown with reference number 1514). In some embodiments, the first functional region 137 that is compared with the third enlarged region 181 with respect to FIG. 1E is larger in size than a space occupied by the first functional component 1512. In some embodiments, the one or more second functional components are at least one of in the first dielectric layer 206 or in one or more other layers of the semiconductor device 200.

In some embodiments, the one or more second resistance components have one or more of the features, characteristics, functions, interrelationships, relationships with other elements, sizes, positions, materials, etc. provided herein with respect to the one or more first resistance components. In some embodiments, the one or more second resistance components are formed according to the resistance component map. In some embodiments, the one or more second resistance components comprise at least one of the first resistance component (shown with reference number 1516) or the second resistance component (shown with reference number 1518). In some embodiments, the first resistance region 140 that is compared with the fourth enlarged region 183 with respect to FIG. 1H is larger in size than a space occupied by the first resistance component 1516. In some embodiments, the one or more second resistance components are at least one of in the first dielectric layer 206 or in one or more other layers of the semiconductor device 200.

In some embodiments, fabricating the second patterned oxide layer 1302 according to the second patterned layer map 157 provides for at least one of improved operation or reduced defects of the semiconductor device 200 as compared to a semiconductor device implemented using the first wafer fabricated according to the first patterned layer map.

In some embodiments, fabricating the first wafer comprises (i) forming a third oxide layer, (ii) performing the first patterning process (provided herein with respect to the system 100 of FIGS. 1A-1M) to pattern the third oxide layer to form a third patterned oxide layer according to the first patterned layer map, (iii) forming a third metal layer over the third patterned oxide layer, or (iv) removing a third upper portion, of the first wafer, comprising at least some of the third metal layer. In some embodiments, the third patterned oxide layer does not overlie a ninth set of contact structures. In some embodiments, the ninth set of contact structures corresponds to at least one of the sixth set of contact structures or the second set of contact structures 104A-104F. In some embodiments, the ninth set of contact structures has one or more of the features, characteristics, functions, interrelationships, relationships with other elements, sizes, positions, materials, etc. provided herein with respect to at least one of the sixth set of contact structures or the second set of contact structures 104A-104F. In some embodiments, the third patterned oxide layer does not overlie the ninth set of contact structures since a first portion, of the third oxide layer, overlying the ninth set of contact structures is removed in the first patterning process in accordance with the first patterned layer map. In some embodiments, the first portion of the third oxide layer is within the first supplemental patterned layer region 187. In some embodiments, the third metal layer corresponds to the second metal layer 1402. In some embodiments, since the first portion of the third oxide layer is removed in the first patterning process to form the third patterned oxide layer, the ninth set of contact structures are not separated from the third metal layer by the third patterned oxide layer. In some embodiments, removing the third upper portion of the first wafer when the ninth set of contact structures are not separated from the third metal layer by the third oxide layer results in first metal residue from the third metal layer remaining on the ninth set of contact structures. In some embodiments, the first residue associated with the first defect comprises the first metal residue from the third metal layer. In some embodiments, the first metal residue remains on the ninth set of contact structures due, at least in part, to at least one of one or more parameters of a third layer removal process performed to remove the third upper portion, one or more physical characteristics of the third metal layer, or a top surface of the first wafer having varying elevations. In some embodiments, the first metal residue from the third metal layer negatively impacts operation of the first wafer. In some embodiments, the first wafer having the first metal residue from the third metal layer causes an increase in leakage current in the first wafer. In some embodiments, the first metal residue at least one of deteriorates or degrades a connection between a contact structure of the first wafer and a component. However, in accordance with some embodiments herein, by fabricating the second patterned oxide layer 1302 according to the second patterned layer map 157 rather than the first patterned layer map, the second patterned oxide layer 1302 separates the sixth set of contact structures from the second metal layer 1402. In some embodiments, removing the second upper portion of the semiconductor device 200 when the sixth set of contact structures are separated from the second metal layer 1402 by the second patterned oxide layer 1302 results in reduced amount of metal residue from the second metal layer 1402, such as little or no metal residue, remaining on the sixth set of contact structures. In some embodiments, the reduced amount of metal residue provides for improved operation of the semiconductor device 200. In some embodiments, the first wafer having the first defect, such as the first metal residue, necessitates at least one of repairing or scrapping at least one of the first wafer or a batch of wafers comprising the first wafer. Thus, reducing the amount of metal residue by at least one of generating the second patterned layer map 157 or using the second patterned layer map 157 to form the second patterned oxide layer provides for at least one of reduced loss, increased yield, improved production efficiency, etc.

In some embodiments, the portion 1502 of the second patterned oxide layer 1302 overlying the sixth set of contact structures (shown in FIGS. 15A and 15B) does not impact operation of the semiconductor device 200. In some embodiments, the portion 1502 of the second patterned oxide layer 1302 has a lesser negative impact on operation of the semiconductor device 200 than the first metal residue associated with the first defect. In some embodiments, after removing the second upper portion of the semiconductor device 200, an etching process is performed to remove at least some of the portion 1502 of the second patterned oxide layer 1302.

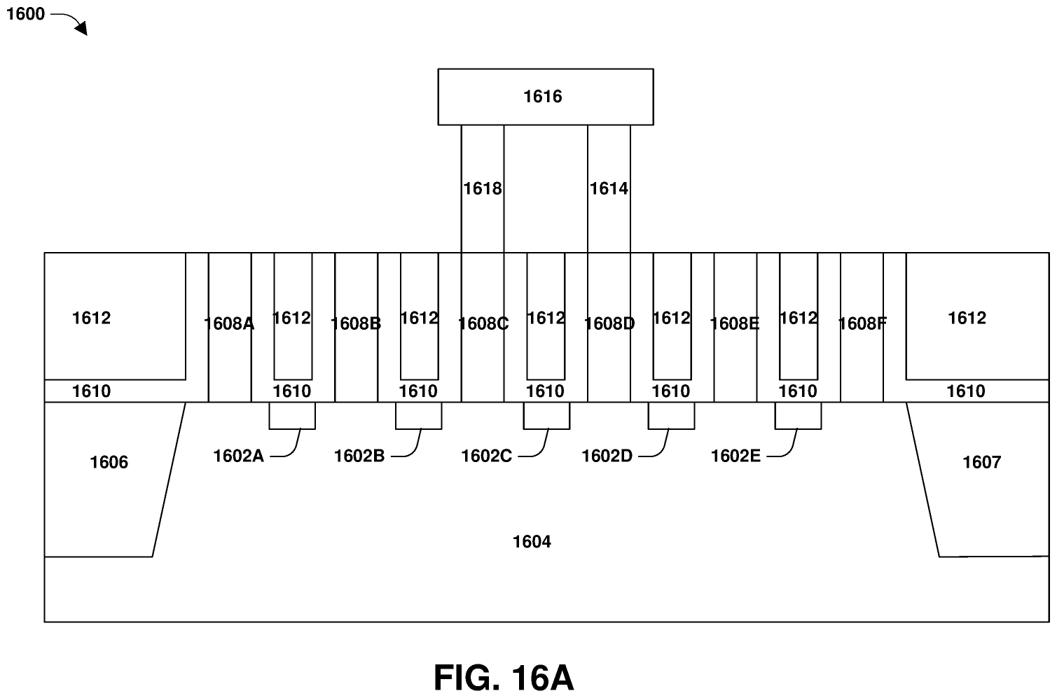

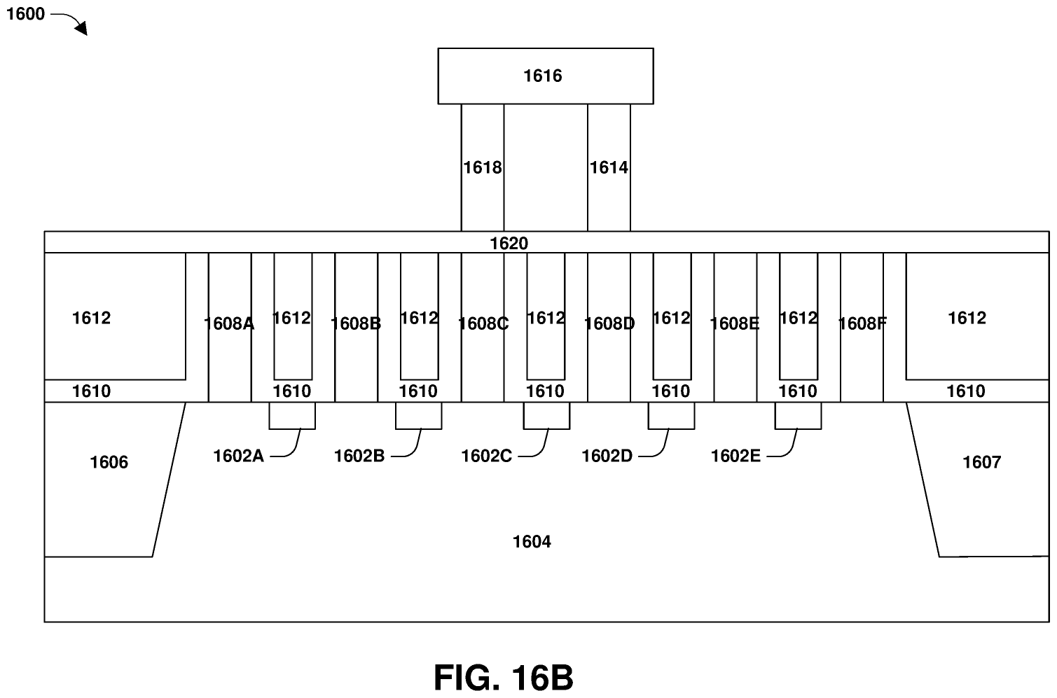

FIG. 16A illustrates a semiconductor device 1600 according to some embodiments. In some embodiments, the semiconductor device 1600 is formed using one or more of the techniques provided herein with respect to forming the semiconductor device 200 (shown in FIGS. 2-15B). In some embodiments, a component of the semiconductor device 1600 includes at least some of the features, characteristics, functions, interrelationships, relationships with other elements, sizes, positions, materials, etc. provided herein with respect to the semiconductor device 200 (shown in FIGS. 2-15B). In some embodiments, the semiconductor device 1600 is formed using the second patterned layer map 157.

In some embodiments, the semiconductor device 1600 comprises at least one of a semiconductor body 1604, a first trench isolation structure 1606, such as a first shallow trench isolation (STI) structure, a second trench isolation structure 1607, such as a second STI structure, a dielectric layer 1612, a work function layer 1610, a first structure 1618, a second structure 1614, or a third structure 1616. In some embodiments, the work function layer 1610 comprises at least one of a nitride material, such as silicon nitride, one or more metals, a metal nitride, such as titanium nitride, or one or more other suitable materials. In some embodiments, the dielectric layer 1612 comprises at least one of PSG or other suitable materials. In some embodiments, the semiconductor body 1604 comprises at least one of a substrate or an epitaxial layer. In some embodiments, the semiconductor body 1604 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials.

In some embodiments, the semiconductor device 1600 comprises a plurality of contact structures formed according to the contact structure map 115. In some embodiments, the plurality of contact structures comprises at least one of (i) a set of contact structures (not shown) corresponding to at least one of the first set of contact structures 102A-102L or the fifth set of contact structures 1504A-1504L, (ii) a set of contact structures 1608A-1608F corresponding to at least one of the second set of contact structures 104A-104F or the sixth set of contact structures, (iii) a set of contact structures (not shown) corresponding to at least one of the third set of contact structures 113A-113I or the seventh set of contact structures 1508A-1508I, or (iv) a set of contact structures (not shown) corresponding to at least one of the fourth set of contact structures 117A-117C or the eighth set of contact structures 1510A-1510C.

In some embodiments, at least one of (i) a contact structure 1608A of the set of contact structures 1608A-1608F comprises polysilicon, such as at least one of intrinsic polysilicon, non-doped polysilicon, or doped polysilicon, such as n-doped polysilicon or p-doped polysilicon, (ii) contact structures 1608B-1608E of the set of contact structures 1608A-1608F comprises metal, or (ii) a contact structure 1608F of the set of contact structures 1608A-1608F comprises polysilicon, such as at least one of intrinsic polysilicon, non-doped polysilicon, or doped polysilicon, such as n-doped polysilicon or p-doped polysilicon. In some embodiments, a contact structure comprising doped polysilicon is formed via at least one of doping, epitaxial doping, ion implantation, molecular diffusion, or other suitable techniques.

In some embodiments, the semiconductor body 1604 comprises a set of doped regions 1602A-1602E. In some embodiments, a doped region of the set of doped regions 1602A-1602E is between two adjacent contact structures of the set of contact structures 1608A-1608F. In some embodiments, a doped region of the set of doped regions 1602A-1602E has the first conductivity type or the second conductivity type. In some embodiments, the set of doped regions 1602A-1602E are in an active area of the semiconductor device 1600. In some embodiments, a doped region of the set of doped regions 1602A-1602E corresponds to at least one of a drain or a source of at least one of a transistor, a MOS structure, a MOSFET structure, a FinFET structure, or other suitable structure.

In some embodiments, at least one of the first structure 1618 or the second structure 1614 resides in a dielectric layer (not shown) of the semiconductor device 1600. In some embodiments, the third structure 1616 resides in a layer (not shown), such as a metal layer, of the semiconductor device 1600. In some embodiments, at least one of the first structure 1618 or the second structure 1614 corresponds to a connection element, an interconnect structure, a contact, a via, a metal line, etc. configured to establish an electrical connection between the third structure 1616 and one or more contact structures of the set of contact structures 1608A-1608F. In some embodiments, the third structure 1616 comprises a metal structure.

In some embodiments, forming the semiconductor device 1600 using the second patterned layer map 157, such as using one or more of the techniques provided herein with respect to forming the semiconductor device 200 using the second patterned layer map 157, provides for a reduced amount of metal residue on the set of contact structures 1608A-1608F as compared to using the first patterned layer map. In some embodiments, the reduced amount of metal residue improves the electrical connection between the third structure 1616 and one or more contact structures of the set of contact structures 1608A-1608F.

In some embodiments, the semiconductor device 1600 comprises oxide layer residue 1620 (shown in FIG. 16B) over at least some of the set of contact structures 1608A-1608F. In some embodiments, the oxide layer residue 1620 comprises at least some of the portion 1502 (shown in FIGS. 15A-15B) of the second patterned oxide layer 1302. FIG. 16B illustrates the semiconductor device 1600 according to some embodiments in which the semiconductor device 1600 comprises the oxide layer residue 1620. In some embodiments, the oxide layer residue 1620 resides between the set of contact structures 1608A-1608F and at least one of the first structure 1618 or the second structure 1614.

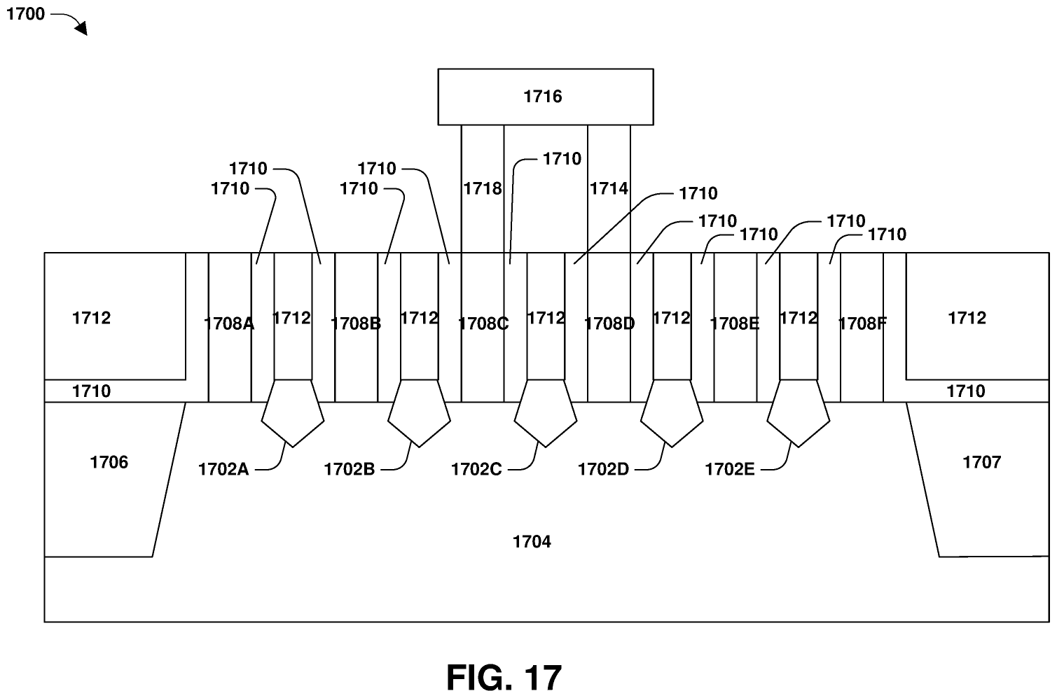

FIG. 17 illustrates a semiconductor device 1700 according to some embodiments. In some embodiments, the semiconductor device 1700 is formed using one or more of the techniques provided herein with respect to forming the semiconductor device 200 (shown in FIGS. 2-15B). In some embodiments, a component of the semiconductor device 1700 includes at least some of the features, characteristics, functions, interrelationships, relationships with other elements, sizes, positions, materials, etc. provided herein with respect to the semiconductor device 200 (shown in FIGS. 2-15B). In some embodiments, the semiconductor device 1700 is formed using the second patterned layer map 157.

In some embodiments, the semiconductor device 1700 comprises at least one of a semiconductor body 1704, a first trench isolation structure 1706, such as a first STI structure, a second trench isolation structure 1707, such as a second STI structure, a dielectric layer 1712, a work function layer 1710, a first structure 1718, a second structure 1714, or a third structure 1716. In some embodiments, the work function layer 1710 comprises at least one of a nitride material, such as silicon nitride, one or more metals, a metal nitride, such as titanium nitride, or one or more other suitable materials. In some embodiments, the dielectric layer 1712 comprises at least one of PSG or other suitable materials. In some embodiments, the semiconductor body 1704 comprises at least one of a substrate or an epitaxial layer. In some embodiments, the semiconductor body 1704 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials.

In some embodiments, the semiconductor device 1700 comprises a plurality of contact structures formed according to the contact structure map 115. In some embodiments, the plurality of contact structures comprises at least one of (i) a set of contact structures (not shown) corresponding to at least one of the first set of contact structures 102A-102L or the fifth set of contact structures 1504A-1504L, (ii) a set of contact structures 1708A-1708F corresponding to at least one of the second set of contact structures 104A-104F or the sixth set of contact structures, (iii) a set of contact structures (not shown) corresponding to at least one of the third set of contact structures 113A-113I or the seventh set of contact structures 1508A-1508I, or (iv) a set of contact structures (not shown) corresponding to at least one of the fourth set of contact structures 117A-117C or the eighth set of contact structures 1510A-1510C.

In some embodiments, at least one of (i) a contact structure 1708A of the set of contact structures 1708A-1708F comprises polysilicon, such as at least one of intrinsic polysilicon, non-doped polysilicon, or doped polysilicon, such as n-doped polysilicon or p-doped polysilicon, (ii) contact structures 1708B-1708E of the set of contact structures 1708A-1708F comprises metal, or (ii) a contact structure 1708F of the set of contact structures 1708A-1708F comprises polysilicon, such as at least one of intrinsic polysilicon, non-doped polysilicon, or doped polysilicon, such as n-doped polysilicon or p-doped polysilicon. In some embodiments, a contact structure comprising doped polysilicon is formed via at least one of doping, epitaxial doping, ion implantation, molecular diffusion, or other suitable techniques.

In some embodiments, the semiconductor body 1704 comprises a set of doped regions 1702A-1702E. In some embodiments, a doped region of the set of doped regions 1702A-1702E is between two adjacent contact structures of the set of contact structures 1708A-1708F. In some embodiments, a doped region of the set of doped regions 1702A-1702E has the first conductivity type or the second conductivity type. In some embodiments, the set of doped regions 1702A-1702E are in an active area of the semiconductor device 1700. In some embodiments, a doped region of the set of doped regions 1702A-1702E corresponds to at least one of a drain or a source of at least one of a transistor, a MOS structure, a MOSFET structure, a FinFET structure, or other suitable structure.

In some embodiments, at least one of the first structure 1718 or the second structure 1714 resides in a dielectric layer (not shown) of the semiconductor device 1700. In some embodiments, the third structure 1716 resides in a layer (not shown), such as a metal layer, of the semiconductor device 1700. In some embodiments, at least one of the first structure 1718 or the second structure 1714 corresponds to a connection element, an interconnect structure, a contact, a via, a metal line, etc. configured to establish an electrical connection between the third structure 1716 and one or more contact structures of the set of contact structures 1708A-1708F. In some embodiments, the third structure 1716 comprises a metal structure.

In some embodiments, forming the semiconductor device 1700 using the second patterned layer map 157, such as using one or more of the techniques provided herein with respect to forming the semiconductor device 200 using the second patterned layer map 157, provides for a reduced amount of metal residue on the set of contact structures 1708A-1708F as compared to using the first patterned layer map. In some embodiments, the reduced amount of metal residue improves the electrical connection between the third structure 1716 and one or more contact structures of the set of contact structures 1708A-1708F.

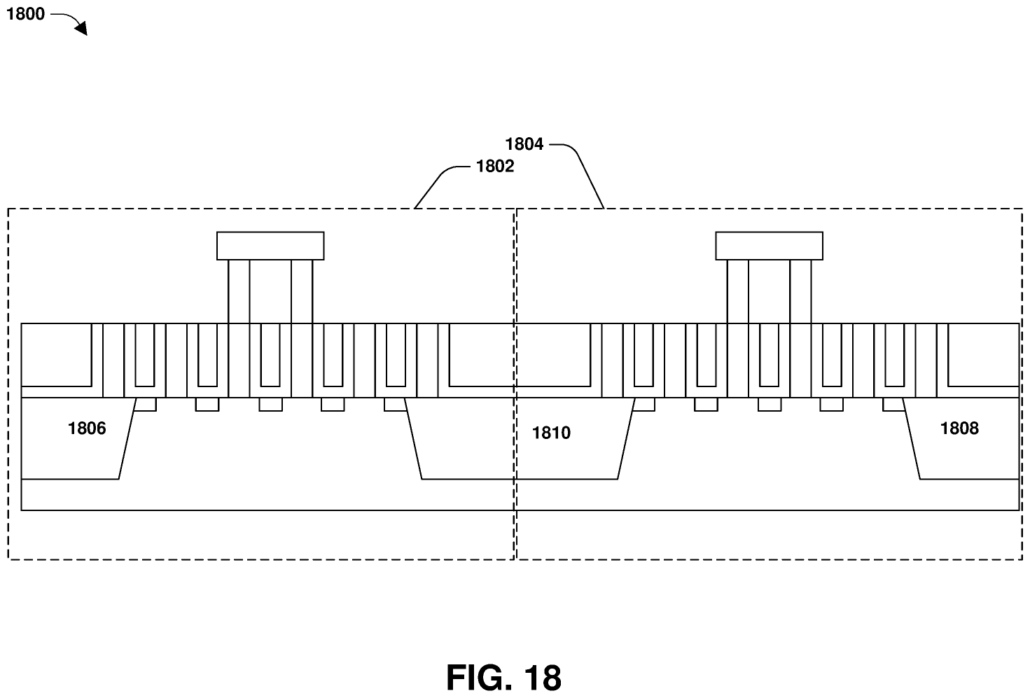

FIG. 18 illustrates a semiconductor device 1800 according to some embodiments. In some embodiments, the semiconductor device 1800 is formed using one or more of the techniques provided herein with respect to forming the semiconductor device 200 (shown in FIGS. 2-15B). In some embodiments, a component of the semiconductor device 1800 includes at least some of the features, characteristics, functions, interrelationships, relationships with other elements, sizes, positions, materials, etc. provided herein with respect to at least one of the semiconductor device 200 (shown in FIGS. 2-15B), the semiconductor device 1600 (shown in FIGS. 16A-16B), or the semiconductor device 1700 (shown in FIG. 17). In some embodiments, the semiconductor device 1800 is formed using the second patterned layer map 157. In some embodiments, the semiconductor device 1800 comprises at least one of a first section 1802 or a second section 1804. In some embodiments, each section of at least one of the first section 1802 or the second section 1804 comprises at least some of the features, characteristics, functions, interrelationships, relationships with other elements, sizes, positions, materials, etc. provided herein with respect to at least one of the semiconductor device 200 (shown in FIGS. 2-15B), the semiconductor device 1600 (shown in FIGS. 16A-16B), or the semiconductor device 1700 (shown in FIG. 17). In some embodiments, the semiconductor device 1700 comprises at least one of a first trench isolation structure 1806, such as a first STI structure, a second trench isolation structure 1808, such as a second STI structure, or a third trench isolation structure 1810, such as third STI structure. In some embodiments, the third trench isolation structure 1810 is between the first section 1802 and the second section 1804.

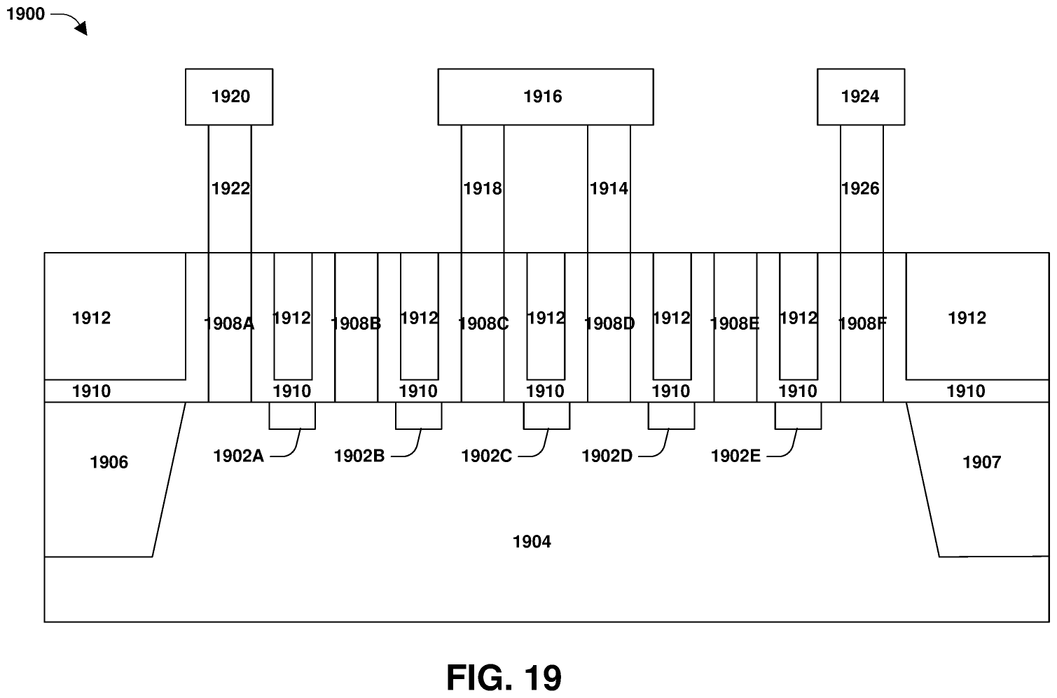

FIG. 19 illustrates a semiconductor device 1900 according to some embodiments. In some embodiments, the semiconductor device 1900 is formed using one or more of the techniques provided herein with respect to forming the semiconductor device 200 (shown in FIGS. 2-15B). In some embodiments, a component of the semiconductor device 1900 includes at least some of the features, characteristics, functions, interrelationships, relationships with other elements, sizes, positions, materials, etc. provided herein with respect to the semiconductor device 200 (shown in FIGS. 2-15B). In some embodiments, the semiconductor device 1900 is formed using the second patterned layer map 157.

In some embodiments, the semiconductor device 1900 comprises at least one of a semiconductor body 1904, a first trench isolation structure 1906, such as a first shallow trench isolation (STI) structure, a second trench isolation structure 1907, such as a second STI structure, a dielectric layer 1912, a work function layer 1910, a first structure 1918, a second structure 1914, a third structure 1916, a fourth structure 1922, a fifth structure 1920, a sixth structure 1926, or a seventh structure 1924. In some embodiments, the work function layer 1910 comprises at least one of a nitride material, such as silicon nitride, one or more metals, a metal nitride, such as titanium nitride, or one or more other suitable materials. In some embodiments, the dielectric layer 1912 comprises at least one of PSG or other suitable materials. In some embodiments, the semiconductor body 1904 comprises at least one of a substrate or an epitaxial layer. In some embodiments, the semiconductor body 1904 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials.

In some embodiments, the semiconductor device 1900 comprises a plurality of contact structures formed according to the contact structure map 115. In some embodiments, the plurality of contact structures comprises at least one of (i) a set of contact structures (not shown) corresponding to at least one of the first set of contact structures 102A-102L or the fifth set of contact structures 1504A-1504L, (ii) a set of contact structures 1908A-1908F corresponding to at least one of the second set of contact structures 104A-104F or the sixth set of contact structures, (iii) a set of contact structures (not shown) corresponding to at least one of the third set of contact structures 113A-113I or the seventh set of contact structures 1508A-1508I, or (iv) a set of contact structures (not shown) corresponding to at least one of the fourth set of contact structures 117A-117C or the eighth set of contact structures 1510A-1510C.

In some embodiments, at least one of (i) a contact structure 1908A of the set of contact structures 1908A-1908F comprises a first resistor, such as an n-type resistor or a p-type resistor, (ii) contact structures 1908B-1908E of the set of contact structures 1908A-1908F comprises metal, or (ii) a contact structure 1908F of the set of contact structures 1908A-1908F comprises a second resistor, such as an n-type resistor or a p-type resistor. In some embodiments, a contact structure comprising a doped resistor is formed via at least one of doping, epitaxial doping, ion implantation, molecular diffusion, or other suitable techniques.

In some embodiments, the semiconductor body 1904 comprises a set of doped regions 1902A-1902E. In some embodiments, a doped region of the set of doped regions 1902A-1902E is between two adjacent contact structures of the set of contact structures 1908A-1908F. In some embodiments, a doped region of the set of doped regions 1902A-1902E has the first conductivity type or the second conductivity type. In some embodiments, the set of doped regions 1902A-1902E are in an active area of the semiconductor device 1900. In some embodiments, a doped region of the set of doped regions 1902A-1902E corresponds to at least one of a drain or a source of at least one of a transistor, a MOS structure, a MOSFET structure, a FinFET structure, or other suitable structure.

In some embodiments, at least one of the first structure 1918, the second structure 1914, the fourth structure 1922, or the sixth structure 1926 resides in a dielectric layer (not shown) of the semiconductor device 1900. In some embodiments, at least one of the third structure 1916, the fifth structure 1920, or the seventh structure 1924 resides in a layer (not shown), such as a metal layer, of the semiconductor device 1900. In some embodiments, at least one of the first structure 1918 or the second structure 1914 corresponds to a connection element, an interconnect structure, a contact, a via, a metal line, etc. configured to establish an electrical connection between the third structure 1916 and one or more contact structures of the set of contact structures 1908A-1908F. In some embodiments, the third structure 1916 comprises a metal structure. In some embodiments, the fourth structure 1922 corresponds to a connection element, an interconnect structure, a contact, a via, a metal line, etc. configured to establish an electrical connection between the fifth structure 1920 and the contact structure 1908A. In some embodiments, the fifth structure 1920 comprises a metal structure. In some embodiments, the sixth structure 1926 corresponds to a connection element, an interconnect structure, a contact, a via, a metal line, etc. configured to establish an electrical connection between the seventh structure 1924 and the contact structure 1908F. In some embodiments, the seventh structure 1924 comprises a metal structure.

In some embodiments, forming the semiconductor device 1900 using the second patterned layer map 157, such as using one or more of the techniques provided herein with respect to forming the semiconductor device 200 using the second patterned layer map 157, provides for a reduced amount of metal residue on the set of contact structures 1908A-1908F as compared to using the first patterned layer map. In some embodiments, the reduced amount of metal residue improves at least one of (i) the electrical connection between the third structure 1916 and one or more contact structures of the set of contact structures 1908A-1908F, (ii) the electrical connection between the fifth structure 1920 and the contact structure 1908A, or (iii) the electrical connection between the seventh structure 1924 and the contact structure 1908F.

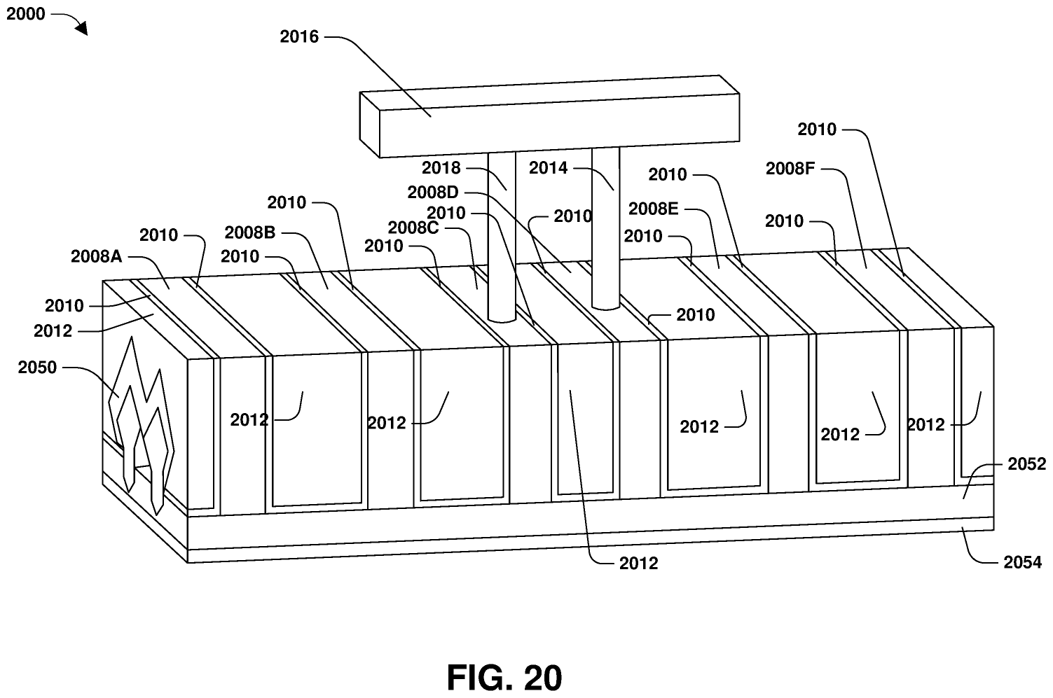

FIG. 20 illustrates a semiconductor device 2000 according to some embodiments. In some embodiments, the semiconductor device 2000 is formed using one or more of the techniques provided herein with respect to forming the semiconductor device 200 (shown in FIGS. 2-15B). In some embodiments, a component of the semiconductor device 2000 includes at least some of the features, characteristics, functions, interrelationships, relationships with other elements, sizes, positions, materials, etc. provided herein with respect to the semiconductor device 200 (shown in FIGS. 2-15B). In some embodiments, the semiconductor device 2000 is formed using the second patterned layer map 157.

In some embodiments, the semiconductor device 2000 comprises at least one of a substrate 2054, a trench isolation structure 2052, such as a STI structure, a dielectric layer 2012, a work function layer 2010, a first structure 2018, a second structure 2014, or a third structure 2016. In some embodiments, the work function layer 2010 comprises at least one of a nitride material, such as silicon nitride, one or more metals, a metal nitride, such as titanium nitride, or one or more other suitable materials. In some embodiments, the dielectric layer 2012 comprises at least one of PSG or other suitable materials. In some embodiments, the substrate 2054 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials.

In some embodiments, the semiconductor device 2000 comprises a plurality of contact structures formed according to the contact structure map 115. In some embodiments, the plurality of contact structures comprises at least one of (i) a set of contact structures (not shown) corresponding to at least one of the first set of contact structures 102A-102L or the fifth set of contact structures 1504A-1504L, (ii) a set of contact structures 2008A-2008F corresponding to at least one of the second set of contact structures 104A-104F or the sixth set of contact structures, (iii) a set of contact structures (not shown) corresponding to at least one of the third set of contact structures 113A-113I or the seventh set of contact structures 1508A-1508I, or (iv) a set of contact structures (not shown) corresponding to at least one of the fourth set of contact structures 117A-117C or the eighth set of contact structures 1510A-1510C.

In some embodiments, at least one of (i) a contact structure 2008A of the set of contact structures 2008A-2008F comprises polysilicon, such as at least one of intrinsic polysilicon, non-doped polysilicon, or doped polysilicon, such as n-doped polysilicon or p-doped polysilicon, (ii) contact structures 2008B-2008E of the set of contact structures 2008A-2008F comprises metal, or (ii) a contact structure 2008F of the set of contact structures 2008A-2008F comprises polysilicon, such as at least one of intrinsic polysilicon, non-doped polysilicon, or doped polysilicon, such as n-doped polysilicon or p-doped polysilicon. In some embodiments, a contact structure comprising doped polysilicon is formed via at least one of doping, epitaxial doping, ion implantation, molecular diffusion, or other suitable techniques.

In some embodiments, at least one of the first structure 2018 or the second structure 2014 resides in a dielectric layer (not shown) of the semiconductor device 2000. In some embodiments, the third structure 2016 resides in a layer (not shown), such as a metal layer, of the semiconductor device 2000. In some embodiments, at least one of the first structure 2018 or the second structure 2014 corresponds to a connection element, an interconnect structure, a contact, a via, a metal line, etc. configured to establish an electrical connection between the third structure 2016 and one or more contact structures of the set of contact structures 2008A-2008F. In some embodiments, the third structure 2016 comprises a metal structure.

In some embodiments, forming the semiconductor device 2000 using the second patterned layer map 157, such as using one or more of the techniques provided herein with respect to forming the semiconductor device 200 using the second patterned layer map 157, provides for a reduced amount of metal residue on the set of contact structures 2008A-2008F as compared to using the first patterned layer map. In some embodiments, the reduced amount of metal residue improves the electrical connection between the third structure 2016 and one or more contact structures of the set of contact structures 2008A-2008F.

In some embodiments, the semiconductor device 2000 comprises a field-effect transistor (FET), such as an epitaxial FET. In some embodiments, the semiconductor device 2000 comprises a FinFET, such as an epitaxial FinFET. In some embodiments, the semiconductor device 2000 comprises a FinFET structure 2050.

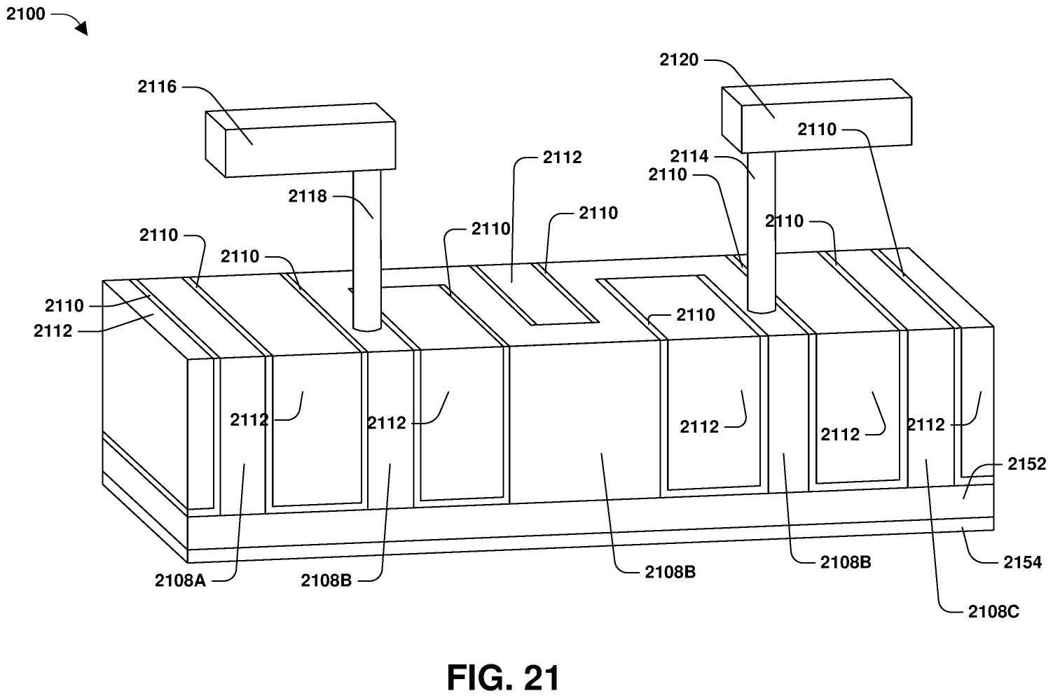

FIG. 21 illustrates a semiconductor device 2100 according to some embodiments. In some embodiments, the semiconductor device 2100 is formed using one or more of the techniques provided herein with respect to forming the semiconductor device 200 (shown in FIGS. 2-15B). In some embodiments, a component of the semiconductor device 2100 includes at least some of the features, characteristics, functions, interrelationships, relationships with other elements, sizes, positions, materials, etc. provided herein with respect to the semiconductor device 200 (shown in FIGS. 2-15B). In some embodiments, the semiconductor device 2100 is formed using the second patterned layer map 157.

In some embodiments, the semiconductor device 2100 comprises at least one of a substrate 2154, a trench isolation structure 2152, such as a STI structure, a dielectric layer 2112, a work function layer 2110, a first structure 2118, a second structure 2114, a third structure 2116, or a fourth structure 2120. In some embodiments, the work function layer 2110 comprises at least one of a nitride material, such as silicon nitride, one or more metals, a metal nitride, such as titanium nitride, or one or more other suitable materials. In some embodiments, the dielectric layer 2112 comprises at least one of PSG or other suitable materials. In some embodiments, the substrate 2154 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials.

In some embodiments, the semiconductor device 2100 comprises a plurality of contact structures formed according to the contact structure map 115. In some embodiments, the plurality of contact structures comprises at least one of (i) a set of contact structures (not shown) corresponding to at least one of the first set of contact structures 102A-102L or the fifth set of contact structures 1504A-1504L, (ii) a set of contact structures 2108A-2108C corresponding to at least one of the second set of contact structures 104A-104F or the sixth set of contact structures, (iii) a set of contact structures (not shown) corresponding to at least one of the third set of contact structures 113A-113I or the seventh set of contact structures 1508A-1508I, or (iv) a set of contact structures (not shown) corresponding to at least one of the fourth set of contact structures 117A-117C or the eighth set of contact structures 1510A-1510C.

In some embodiments, at least one of (i) a contact structure 2108A of the set of contact structures 2108A-2108C comprises polysilicon, such as at least one of intrinsic polysilicon, non-doped polysilicon, or doped polysilicon, such as n-doped polysilicon or p-doped polysilicon, (ii) a contact structure 2108B of the set of contact structures 2108A-2108C comprises polysilicon, such as at least one of intrinsic polysilicon, non-doped polysilicon or doped polysilicon, such as n-doped polysilicon or p-doped polysilicon, or (ii) a contact structure 2108C of the set of contact structures 2108A-2108C comprises polysilicon, such as at least one of intrinsic polysilicon, non-doped polysilicon, or doped polysilicon, such as n-doped polysilicon or p-doped polysilicon. In some embodiments, a contact structure comprising doped polysilicon is formed via at least one of doping, epitaxial doping, ion implantation, molecular diffusion, or other suitable techniques.

In some embodiments, at least one of the first structure 2118 or the second structure 2114 resides in a dielectric layer (not shown) of the semiconductor device 2100. In some embodiments, at least one of the third structure 2116 or the fourth structure 2120 resides in a layer (not shown), such as a metal layer, of the semiconductor device 2100. In some embodiments, at least one of the first structure 2118 or the second structure 2114 corresponds to a connection element, an interconnect structure, a contact, a via, a metal line, etc. configured to establish an electrical connection between the contact structure 2108B and at least one of the third structure 2116 or the fourth structure 2120, respectively. In some embodiments, at least one of the third structure 2116 or the fourth structure 2120 comprises a metal structure. In some embodiments, the semiconductor device 2000 comprises a resistance component, such as a high resistance device. In some embodiments, the semiconductor device 2000 implements electrical resistance in an electrical circuit comprising a connection through at least one of the third structure 2116, the fourth structure 2120 or the contact structure 2108B. In some embodiments, the electrical resistance depends upon one or more characteristics of the contact structure 2108B.

In some embodiments, forming the semiconductor device 2000 using the second patterned layer map 157, such as using one or more of the techniques provided herein with respect to forming the semiconductor device 200 using the second patterned layer map 157, provides for a reduced amount of metal residue on the set of contact structures 2108A-2108C as compared to using the first patterned layer map. In some embodiments, the reduced amount of metal residue improves the electrical connection between the contact structure 2108B and at least one of the third structure 2116 or the fourth structure 2120.

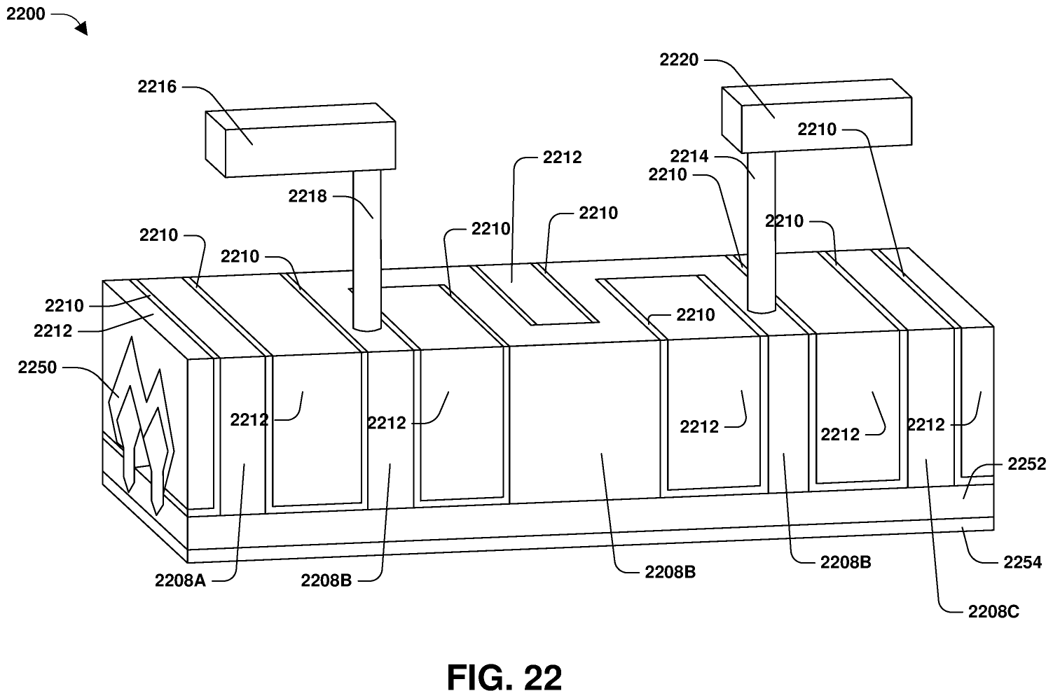

FIG. 22 illustrates a semiconductor device 2200 according to some embodiments. In some embodiments, the semiconductor device 2200 is formed using one or more of the techniques provided herein with respect to forming the semiconductor device 200 (shown in FIGS. 2-15B). In some embodiments, a component of the semiconductor device 2200 includes at least some of the features, characteristics, functions, interrelationships, relationships with other elements, sizes, positions, materials, etc. provided herein with respect to the semiconductor device 200 (shown in FIGS. 2-15B). In some embodiments, the semiconductor device 2200 is formed using the second patterned layer map 157.

In some embodiments, the semiconductor device 2200 comprises at least one of a substrate 2254, a trench isolation structure 2252, such as a STI structure, a dielectric layer 2212, a work function layer 2210, a first structure 2218, a second structure 2214, a third structure 2216, or a fourth structure 2220. In some embodiments, the work function layer 2210 comprises at least one of a nitride material, such as silicon nitride, one or more metals, a metal nitride, such as titanium nitride, or one or more other suitable materials. In some embodiments, the dielectric layer 2212 comprises at least one of PSG or other suitable materials. In some embodiments, the substrate 2254 comprises at least one of silicon, germanium, carbide, arsenide, gallium, arsenic, phosphide, indium, antimonide, SiGe, SiC, GaAs, GaN, GaP, InGaP, InP, InAs, InSb, GaAsP, AlInAs, AlGaAs, GaInAs, GaInP, GaInAsP, or other suitable materials.

In some embodiments, the semiconductor device 2200 comprises a plurality of contact structures formed according to the contact structure map 115. In some embodiments, the plurality of contact structures comprises at least one of (i) a set of contact structures (not shown) corresponding to at least one of the first set of contact structures 102A-102L or the fifth set of contact structures 1504A-1504L, (ii) a set of contact structures 2208A-2208C corresponding to at least one of the second set of contact structures 104A-104F or the sixth set of contact structures, (iii) a set of contact structures (not shown) corresponding to at least one of the third set of contact structures 113A-113I or the seventh set of contact structures 1508A-1508I, or (iv) a set of contact structures (not shown) corresponding to at least one of the fourth set of contact structures 117A-117C or the eighth set of contact structures 1510A-1510C.

In some embodiments, at least one of (i) a contact structure 2208A of the set of contact structures 2208A-2208C comprises polysilicon, such as at least one of intrinsic polysilicon, non-doped polysilicon, or doped polysilicon, such as n-doped polysilicon or p-doped polysilicon, (ii) a contact structure 2208B of the set of contact structures 2208A-2208C comprises polysilicon, such as at least one of intrinsic polysilicon, non-doped polysilicon or doped polysilicon, such as n-doped polysilicon or p-doped polysilicon, or (ii) a contact structure 2208C of the set of contact structures 2208A-2208C comprises polysilicon, such as at least one of intrinsic polysilicon, non-doped polysilicon, or doped polysilicon, such as n-doped polysilicon or p-doped polysilicon. In some embodiments, a contact structure comprising doped polysilicon is formed via at least one of doping, epitaxial doping, ion implantation, molecular diffusion, or other suitable techniques.

In some embodiments, at least one of the first structure 2218 or the second structure 2214 resides in a dielectric layer (not shown) of the semiconductor device 2200. In some embodiments, at least one of the third structure 2216 or the fourth structure 2220 resides in a layer (not shown), such as a metal layer, of the semiconductor device 2200. In some embodiments, at least one of the first structure 2218 or the second structure 2214 corresponds to a connection element, an interconnect structure, a contact, a via, a metal line, etc. configured to establish an electrical connection between the contact structure 2208B and at least one of the third structure 2216 or the fourth structure 2220, respectively. In some embodiments, at least one of the third structure 2216 or the fourth structure 2220 comprises a metal structure. In some embodiments, the semiconductor device 2000 comprises a resistance component, such as a high resistance device. In some embodiments, the semiconductor device 2000 implements electrical resistance in an electrical circuit comprising a connection through at least one of the third structure 2216, the fourth structure 2220 or the contact structure 2208B. In some embodiments, the electrical resistance depends upon one or more characteristics of the contact structure 2208B.

In some embodiments, forming the semiconductor device 2000 using the second patterned layer map 157, such as using one or more of the techniques provided herein with respect to forming the semiconductor device 200 using the second patterned layer map 157, provides for a reduced amount of metal residue on the set of contact structures 2208A-2208C as compared to using the first patterned layer map. In some embodiments, the reduced amount of metal residue improves the electrical connection between the contact structure 2208B and at least one of the third structure 2216 or the fourth structure 2220.

In some embodiments, the semiconductor device 2200 comprises a FET, such as an epitaxial FET. In some embodiments, the semiconductor device 2200 comprises a FinFET, such as an epitaxial FinFET. In some embodiments, the semiconductor device 2200 comprises a FinFET structure 22050.

In some embodiments, a method is provided for forming one, some or all of the features, components, structures, etc. provided herein, such as shown in and/or described with respect to FIGS. 1A-22.

Embodiments are contemplated in which the first layer patterning unit, such as the first photolithography mask 1108, is used for patterning a layer different than the second oxide layer 902, such as at least one of a semiconductor layer, a metal layer, an epitaxial layer, a dielectric layer, or other type of layer. In some embodiments, one, some or all instances of the term “oxide layer” may be supplemented or replaced with at least one of “semiconductor layer”, “metal layer”, “epitaxial layer”, “dielectric layer”, or other type of layer.

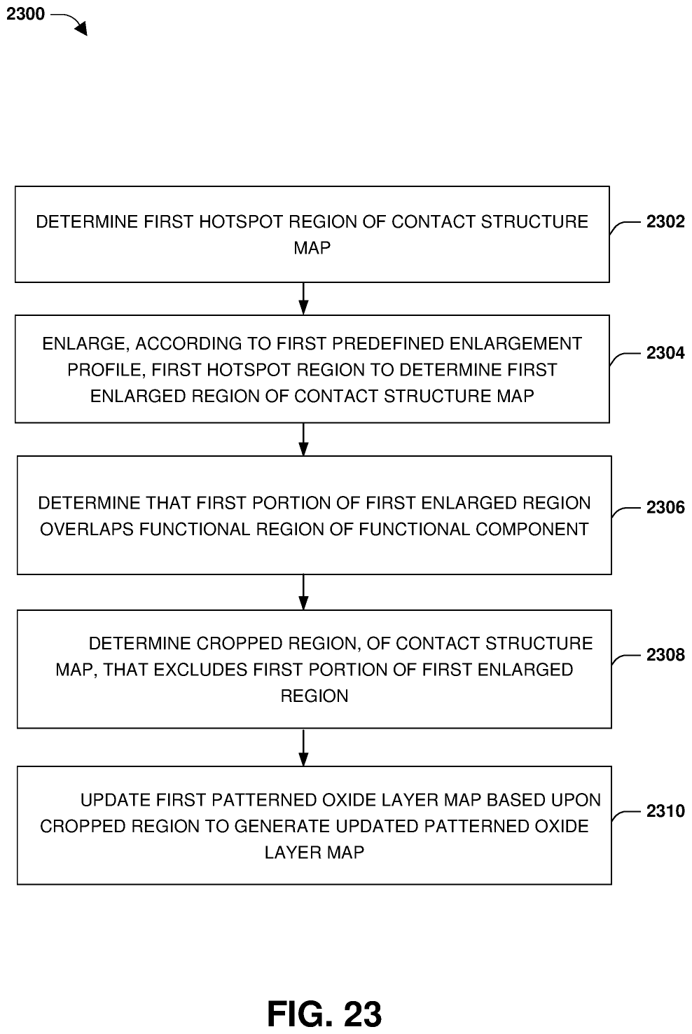

A method 2300 is illustrated in FIG. 23, in accordance with some embodiments. At 2302, a first hotspot region of a contact structure map is determined. In some embodiments, the first hotspot region corresponds to the first hotspot region 120 (shown in FIG. 1B). At 2304, the first hotspot region is enlarged, according to a first predefined enlargement profile, to determine a first enlarged region of the contact structure map. In some embodiments, the first enlarged region corresponds to the first enlarged region 118. At 2306, it is determined that a functional region of a functional component overlaps a first portion of the first enlarged region. In some embodiments, the functional region corresponds to at least one of the functional region 137 or the functional region 139. At 2308, a cropped region, of the contact structure map, that excludes the first portion of the first enlarged region is determined. In some embodiments, the cropped region corresponds to the cropped region 135. At 2310, the first patterned oxide layer map is updated based upon the cropped region to generate an updated patterned oxide layer map. In some embodiments, the first patterned oxide layer map corresponds to the first patterned layer map. In some embodiments, the updated patterned oxide layer map corresponds to the second patterned layer map 157.

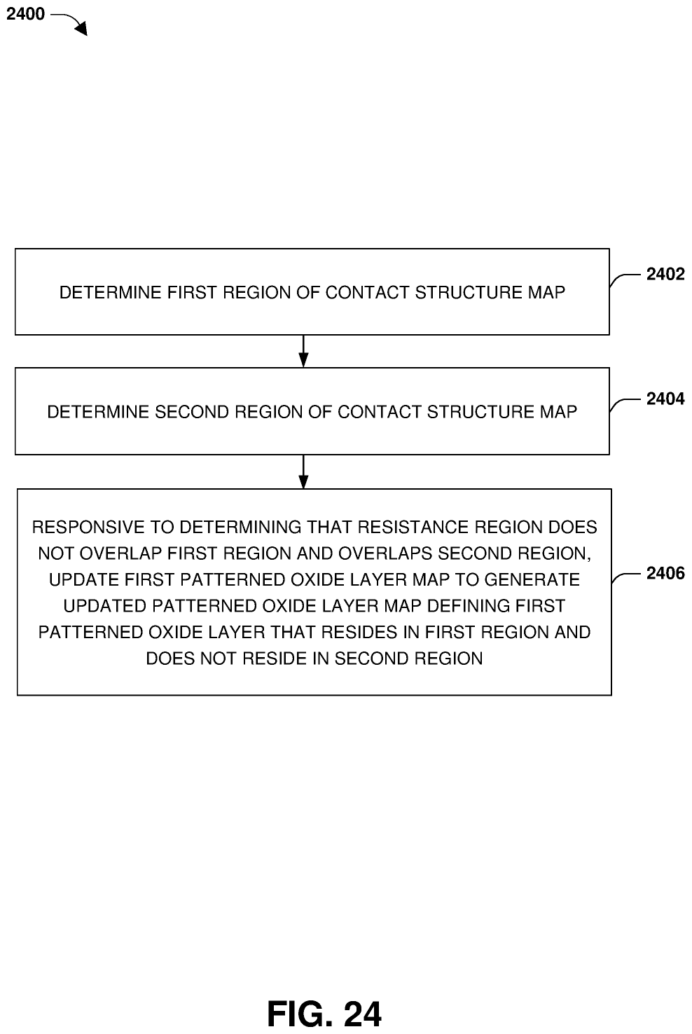

A method 2400 is illustrated in FIG. 24, in accordance with some embodiments. At 2402, a first region of a contact structure map is determined. In some embodiments, the first region corresponds to the cropped region 135. At 2404, a second region of the contact structure map is determined. In some embodiments, the second region corresponds to at least one of the second enlarged region 119 or the fourth enlarged region 183. At 2406, responsive to determining that a resistance region does not overlap the first region and overlaps the second region, updating a first patterned oxide layer map to generate an updated patterned oxide layer map defining a first patterned oxide layer that resides in the first region and does not reside in the second region. In some embodiments, the first patterned oxide layer map corresponds to the first patterned layer map. In some embodiments, the updated patterned oxide layer map corresponds to the second patterned layer map 157. In some embodiments, the first patterned oxide layer corresponds to the second patterned oxide layer 1302.

In some embodiments, the first patterned oxide layer map defines a second patterned oxide layer not residing in the first region. In some embodiments, the second patterned oxide layer corresponds to the third patterned oxide layer associated with the first wafer.

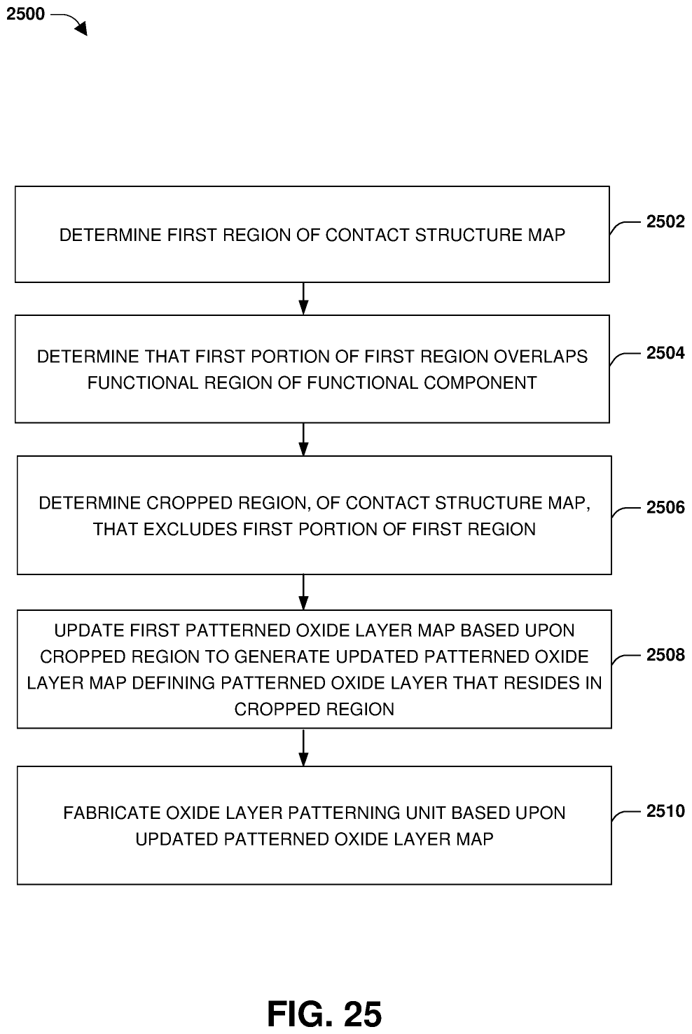

A method 2500 is illustrated in FIG. 25, in accordance with some embodiments. At 2502, a first region of a contact structure map is determined. In some embodiments, the first region corresponds to the first hotspot region 120. At 2504, it is determined that a functional region of a functional component overlaps a first portion of the first region. In some embodiments, the functional region corresponds to at least one of the functional region 137 or the functional region 139. At 2506, a cropped region, of the contact structure map, that excludes the first portion of the first enlarged region is determined. In some embodiments, the cropped region corresponds to the cropped region 135. At 2508, the first patterned oxide layer map is updated based upon the cropped region to generate an updated patterned oxide layer map defining a patterned oxide layer that resides in the cropped region. In some embodiments, the first patterned oxide layer map corresponds to the first patterned layer map. In some embodiments, the updated patterned oxide layer map corresponds to the second patterned layer map 157. In some embodiments, the patterned oxide layer corresponds to the second patterned oxide layer 1302. At 2510, an oxide layer patterning unit is fabricated based upon the updated patterned oxide layer map. In some embodiments, the oxide layer patterning unit comprises the first photolithography mask 1108.

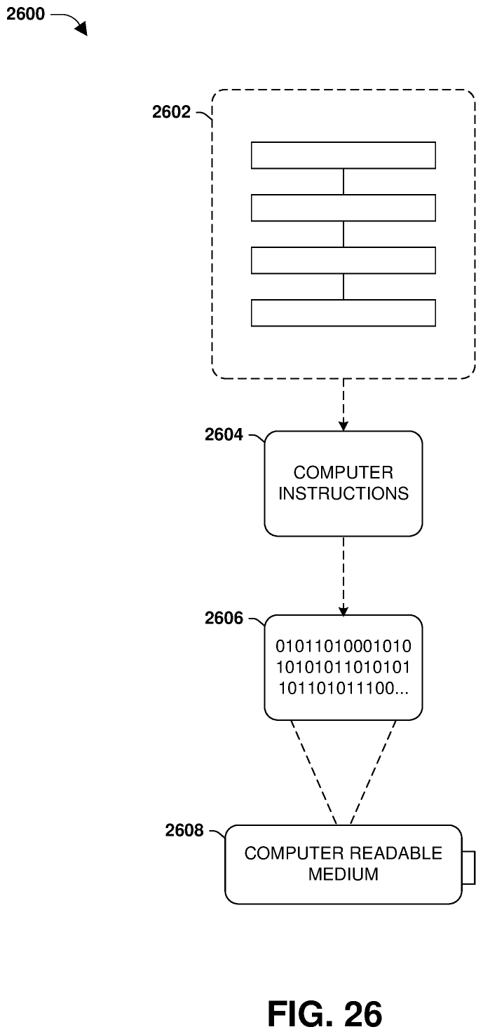

One or more embodiments involve a computer-readable medium comprising processor-executable instructions configured to implement one or more of the techniques presented herein. An exemplary computer-readable medium is illustrated in FIG. 26, wherein the embodiment 2600 comprises a computer-readable medium 2608 (e.g., a CD-R, DVD-R, flash drive, a platter of a hard disk drive, etc.), on which is encoded computer-readable data 2606. This computer-readable data 2606 in turn comprises a set of processor-executable computer instructions 2604 configured to implement one or more of the principles set forth herein when executed by a processor. In some embodiments 2600, the processor-executable computer instructions 2604 are configured to implement a method 2602, such as at least some of the aforementioned method(s) when executed by a processor. In some embodiments, the processor-executable computer instructions 2604 are configured to implement a system, such as at least some of the one or more aforementioned systems when executed by a processor. In some embodiments, the processor-executable computer instructions 2604 are configured to implement an apparatus, such as at least some of the one or more aforementioned apparatuses when executed by a processor. Many such computer-readable media may be devised by those of ordinary skill in the art that are configured to operate in accordance with the techniques presented herein.

In some embodiments, a method is provided. The method includes determining a first hotspot region of a contact structure map. The method includes enlarging, according to a first predefined enlargement profile, the first hotspot region to determine a first enlarged region of the contact structure map. The method includes determining that a first portion of the first enlarged region overlaps a functional region of a functional component. The method includes determining a cropped region, of the contact structure map, that excludes the first portion of the first enlarged region. The method includes updating a first patterned oxide layer map based upon the cropped region to generate an updated patterned oxide layer map.

In some embodiments, a method is provided. The method includes determining a first region of a contact structure map. The method includes determining a second region of the contact structure map. The method includes responsive to determining that a resistance region does not overlap the first region and overlaps the second region, updating a first patterned oxide layer map to generate an updated patterned oxide layer map defining a first patterned oxide layer that resides in the first region and does not reside in the second region.

In some embodiments, a method is provided. The method includes determining a first region of a contact structure map. The method includes determining that a first portion of the first region overlaps a functional region of a functional component. The method includes determining a cropped region, of the contact structure map, that excludes the first portion of the first region. The method includes updating a first patterned oxide layer map based upon the cropped region to generate an updated patterned oxide layer map defining a patterned oxide layer that resides in the cropped region. The method includes fabricating an oxide layer patterning unit based upon the updated patterned oxide layer map.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Although the subject matter has been described in language specific to structural features or methodological acts, it is to be understood that the subject matter of the appended claims is not necessarily limited to the specific features or acts described above. Rather, the specific features and acts described above are disclosed as example forms of implementing at least some of the claims.

Various operations of embodiments are provided herein. The order in which some or all of the operations are described should not be construed to imply that these operations are necessarily order dependent. Alternative ordering will be appreciated having the benefit of this description. Further, it will be understood that not all operations are necessarily present in each embodiment provided herein. Also, it will be understood that not all operations are necessary in some embodiments.

It will be appreciated that layers, features, elements, etc. depicted herein are illustrated with particular dimensions relative to one another, such as structural dimensions or orientations, for example, for purposes of simplicity and ease of understanding and that actual dimensions of the same differ substantially from that illustrated herein, in some embodiments. Additionally, a variety of techniques exist for forming the layers, regions, features, elements, etc. mentioned herein, such as at least one of etching techniques, planarization techniques, implanting techniques, doping techniques, spin-on techniques, sputtering techniques, growth techniques, or deposition techniques such as chemical vapor deposition (CVD), for example.

Moreover, “exemplary” is used herein to mean serving as an example, instance, illustration, etc., and not necessarily as advantageous. As used in this application, “or” is intended to mean an inclusive “or” rather than an exclusive “or”. In addition, “a” and “an” as used in this application and the appended claims are generally be construed to mean “one or more” unless specified otherwise or clear from context to be directed to a singular form. Also, at least one of A and B and/or the like generally means A or B or both A and B. Furthermore, to the extent that “includes”, “having”, “has”, “with”, or variants thereof are used, such terms are intended to be inclusive in a manner similar to the term “comprising”. Also, unless specified otherwise, “first,” “second,” or the like are not intended to imply a temporal aspect, a spatial aspect, an ordering, etc. Rather, such terms are merely used as identifiers, names, etc. for features, elements, items, etc. For example, a first element and a second element generally correspond to element A and element B or two different or two identical elements or the same element.

Also, although the disclosure has been shown and described with respect to one or more implementations, equivalent alterations and modifications will occur to others of ordinary skill in the art based upon a reading and understanding of this specification and the annexed drawings. The disclosure comprises all such modifications and alterations and is limited only by the scope of the following claims. In particular regard to the various functions performed by the above described components (e.g., elements, resources, etc.), the terms used to describe such components are intended to correspond, unless otherwise indicated, to any component which performs the specified function of the described component (e.g., that is functionally equivalent), even though not structurally equivalent to the disclosed structure. In addition, while a particular feature of the disclosure may have been disclosed with respect to only one of several implementations, such feature may be combined with one or more other features of the other implementations as may be desired and advantageous for any given or particular application.

What is claimed is:

1. A method, comprising:
determining a first hotspot region of a contact structure map;
enlarging, according to a first predefined enlargement profile, the first hotspot region to determine a first enlarged region of the contact structure map;
determining that a first portion of the first enlarged region overlaps a functional region of a functional component;
determining a cropped region, of the contact structure map, that excludes the first portion of the first enlarged region; and
updating a first patterned oxide layer map based upon the cropped region to generate an updated patterned oxide layer map.

2. The method of claim 1, wherein determining the first hotspot region comprises:
determining the first hotspot region based upon a location of a defect in a wafer fabricated based upon the first patterned oxide layer map.

3. The method of claim 1, wherein:
the first patterned oxide layer map defines a first patterned oxide layer that does not reside in the cropped region; and
the updated patterned oxide layer map defines a second patterned oxide layer that resides in the cropped region.

4. The method of claim 1, comprising:
fabricating an oxide layer patterning unit based upon the updated patterned oxide layer map.

5. The method of claim 4, comprising:
forming an oxide layer over a semiconductor body; and
patterning, using the oxide layer patterning unit, the oxide layer to form a patterned oxide layer.

6. The method of claim 5, wherein:
the oxide layer patterning unit comprises a photolithography mask; and
patterning the oxide layer comprises patterning the oxide layer using the photolithography mask to form the patterned oxide layer.

7. The method of claim 6, wherein patterning the oxide layer using the photolithography mask comprises:
forming a photoresist over the oxide layer;
directing light from a light source through the photolithography mask to the photoresist to generate an exposed photoresist;
applying a developer to the exposed photoresist to form a patterned photoresist; and
patterning the oxide layer using the patterned photoresist to form the patterned oxide layer.

8. The method of claim 1, wherein:
the first hotspot region comprises at least one of:
a first contact structure comprising metal; or
a second contact structure comprising polysilicon.

9. The method of claim 1, wherein:
the functional component comprises a doped poly structure.

10. The method of claim 1, wherein:
the cropped region excludes a second portion, of the first enlarged region, that does not overlap the functional region.

11. A method, comprising:
determining a first region of a contact structure map;
determining a second region of the contact structure map; and
responsive to determining that a resistance region does not overlap the first region and overlaps the second region, updating a first patterned oxide layer map to generate an updated patterned oxide layer map defining a first patterned oxide layer that resides in the first region and does not reside in the second region.

12. The method of claim 11, wherein:
the first patterned oxide layer map defines a second patterned oxide layer not residing in the first region.

13. The method of claim 11, comprising:
fabricating an oxide layer patterning unit based upon the updated patterned oxide layer map.

14. The method of claim 13, comprising:
forming an oxide layer over a semiconductor body; and
patterning, using the oxide layer patterning unit, the oxide layer to form a patterned oxide layer.

15. The method of claim 14, wherein:
the oxide layer patterning unit comprises a photolithography mask; and
patterning the oxide layer comprises:
forming a photoresist over the oxide layer;
directing light from a light source through the photolithography mask to the photoresist to generate an exposed photoresist;
applying a developer to the exposed photoresist to form a patterned photoresist; and
patterning the oxide layer using the patterned photoresist to form the patterned oxide layer.

16. The method of claim 11, wherein:
the first region comprises at least one of:
a first contact structure comprising metal; or
a second contact structure comprising polysilicon; and
the second region comprises at least one of:
a third contact structure comprising metal; or
a fourth contact structure comprising polysilicon.

17. The method of claim 11, comprising:
detecting a defect in a wafer fabricated based upon the first patterned oxide layer map;
determining a first hotspot region of the contact structure map based upon a location of the defect;
enlarging, according to a first predefined enlargement profile, the first hotspot region to determine a first enlarged region of the contact structure map; and
determining that a first portion of the first enlarged region overlaps a functional region of a functional component, wherein the first region is a cropped region that excludes the first portion of the first enlarged region.

18. A method, comprising:
determining a first region of a contact structure map;
determining that a first portion of the first region overlaps a functional region of a functional component;
determining a cropped region, of the contact structure map, that excludes the first portion of the first region;
updating a first patterned oxide layer map based upon the cropped region to generate an updated patterned oxide layer map defining a patterned oxide layer that resides in the cropped region; and
fabricating an oxide layer patterning unit based upon the updated patterned oxide layer map.

19. The method of claim 18, wherein:
the cropped region excludes a second portion, of the first region, that does not overlap the functional region.

20. The method of claim 18, wherein:
the oxide layer patterning unit comprises a photolithography mask; and
the method comprises:
forming an oxide layer over a semiconductor body;
forming a photoresist over the oxide layer;
directing light from a light source through the photolithography mask to the photoresist to generate an exposed photoresist;
applying a developer to the exposed photoresist to form a patterned photoresist; and
patterning the oxide layer using the patterned photoresist to form the patterned oxide layer.
